(19) United States
(12) Patent Application Publication
(10) Pub. No.: US 2004/0053160 A1
(43) Pub. Date: Mar. 18, 2004

(54) Resist composition

(75) Inventors: Hyou Takahashi, Shizuoka (JP); Kazuyoshi Mizutani, Shizuoka (JP); Koji Shirakawa, Shizuoka (JP); Shoichiro Yasunami, Shizuoka (JP)

Correspondence Address: SUGHRUE MION, PLLC, 2100 PENNSYLVANIA AVENUE, N.W., WASHINGTON, DC, 20037, US

(73) Assignee: FUJI PHOTO FILM CO., LTD.

(21) Appl. No.: 10/613,044

(22) Filed: Jul. 7, 2003

(30) Foreign Application Priority Data
Jul. 4, 2002 (JP) P. 2002-196011
Sep. 6, 2002 (JP) P. 2002-261345
Mar. 26, 2003 (JP) 2003-85831

(51) Int. Cl. G03F 7/00; G03F 7/004

(52) U.S. Cl. 430/270.1; 430/914; 430/921; 430/919; 430/925; 430/966; 430/942; 430/927

(57) ABSTRACT

A resist composition comprising:

(A) a compound capable of generating an active seed upon irradiation with one of an actinic ray and a radiation,

(B) a compound capable of reacting with the active seed generated from the compound (A) and/or performing electron transfer to generate an active seed different from the active seed generated from the compound (A), and

(C) a compound capable of performing electron transfer from the active seed generated from the compound (B) to generate an acid,

wherein supposing that the ½ wave of the oxidation potential of the active seed generated from the compound (B) is Eₚₐ and the ½ wave of the reduction potential of the active seed generated from the compound (C) is E_{pc}, the relationship: E_{pc}−Eₚₐ>0 is satisfied.

### FIELD OF THE INVENTION

The present invention relates to a resist composition that is suitably used for the micro-lithography process such as the manufacture of VLSI and high-capacity microchips and other photo-fabrication processes. More particularly, the invention relates to negative-working and positive-working resist compositions capable of forming superfine patterns using in particular electron ray, X ray or extreme ultraviolet ray (EVU).

### BACKGROUND OF THE INVENTION

Heretofore, the process for the production of semiconductor devices such as IC and LSI has involved fine working using photoresist composition or lithographic process. In recent years, the development of integration of integrated circuits has required the formation of patterns of as ultraminute size as submicron or quatermicron. This requirement has also gave a trend for more exposing light sources to be shorter in wavelength, i.e., g-ray to i-ray, even to KrF excimer laser beam. Further, in addition to technique employing excimer laser beam, lithography employing electron ray or X ray has been under development.

In particular, electron ray lithography has been regarded as next or following generation patterning technique. Thus, a high sensitivity and resolution negative-working resist composition has been desired. The enhancement of sensitivity is a very important task particularly for the purpose of reducing the wafer processing time. However, when the sensitivity of electron ray negative-working resist composition is enhanced, the resolution and pattern profile of the resist are deteriorated Thus, a resist which satisfies these requirements at the same time has been keenly desired. A high sensitivity, a high resolution and a good pattern profile are in a trade-off relationship. It is thus very important how these requirements should be satisfied at the same time.

As a resist suitable for such an electron ray or X-ray lithography there has been mainly used a chemically-sensitized resist utilizing an acid catalyst reaction from the standpoint of enhancement of sensitivity. As the negative-working resist composition there has been effectively used a chemically-sensitized composition mainly composed of an alkali-soluble resin, a crosslinking agent and an acid generator.

Various studies have been made of improvement of properties of chemically-sensitized negative-working resist composition. From the standpoint of acid generator in particular, the following studies have been made. Patent Reference 1 (JP-B-8-3635) discloses organic halides, Patent Reference 2 (JP-A-2-52348) discloses aromatic compounds substituted by Br or Cl, Patent Reference 3 (JP-A-4-367864) and Patent Reference. 4 (JP-A-4-367865) disclose aromatic compounds having alkyl group or alkoxy group substituted by Br or Cl, Patent Reference 5 (JP-A-3-87746) discloses haloalkanesulfonate compounds, Patent Reference 6 (JP-A-6-199770) discloses iodonium and sulfonium compounds, Patent Reference 7 (Japanese Patent 2968055) discloses trifluoromethane sulfonate compounds having phenolic hydroxy group, and Patent Reference 8 (JP-A-2001-142200) discloses specific benzene compounds having phenolic hydroxy group.

However, any combination of these compounds cannot satisfy requirements for high sensitivity, high resolution and good pattern profile within an ultraminute region.

For electron ray or X-ray positive-working resist compositions, on the other hand, resist technique for KrF excimer laser has heretofore been utilized and studied. For example, Patent Reference 9 (JP-A-2000-181065) discloses a combination of a compound capable of generating an acid upon irradiation with electron bean and an amine having a boiling point of not higher than250° C., Patent Reference 10 (European Patent 0919867) discloses the combined use of a polymer having an acid-decomposable group, an acid generator and an electron ray sensitizer, and Patent Reference 11 (JP-T-7-508840) discloses the combined use of a polymer having an acid-decomposable group, an acid generator, an lectron ray sensitizer and an amide compound. Further, Patent Reference 12 (JP-A-3-200968) discloses the use of a maleimide compound, Patent Reference 13 (JP-A-7-92680) discloses the use of a sulfonamide compound, and Patent Reference 14 (JP-A-11-44950) discloses a sulfonimide compound containing -SO₂-NH-SO₂- partial structure. However, none of these attempts for improvement can satisfy requirements for high sensitivity, high resolution and rectangular resist shape at the same time.

In lithography using a short wavelength excimer laser beam such as KrF and ArF as an exposing light source, too, the formation of patterns of size of as ultraminute as not greater than 0.20 μm has been targeted. Like electron ray lithography, this lithographic process cannot satisfy all requirements for sensitivity, resolution and pattern profile at the same time. Thus, a resist composition which can satisfy all these requirements at the same time has been keenly desired.

[Patent Reference 1]

JP-B-8-3635

[Patent Reference 2]

JP-A-2-52348

[Patent Reference 3]

JP-A-4-367864

[Patent Reference 4]

JP-A-4-367865

[Patent Reference 5]

JP-A-3-87746

[Patent Reference 6]

JP-A-6-199770

[Patent Reference 7]

Japanese Patent 2968055

[Patent Reference 8]

JP-A-2001-142200

[Patent Reference 9]

JP-A-2000-181065

[Patent Reference 10]

European Patent 0919867

[Patent Reference 11]

JP-T-7-508840

[Patent Reference 12]

JP-A-3-200968

[Patent Reference 13]

JP-A-7-92680

[Patent Reference 14]

JP-A-11-44950

### SUMMARY OF THE INVENTION

It is therefore an object of the invention to solve the problems with the improvement of properties in fine working of semiconductor elements. More particularly, it is an object of the invention to provide a resist composition which satisfies requirements for high sensitivity, high resolution and good pattern profile in fine working of semiconductor elements using electron ray, X ray or extreme ultraviolet ray (EUV).

The present inventors made further extensive studies. As a result, it was found that the aforementioned objects are accomplished by effectively activating a specific acid generator with a plurality of active seeds to drastically increase the generated amount of acid. Thus, the resist composition of the invention was found.

In other words, the invention has the following constitutions.

(1) A resist composition comprising:

(A) a compound capable of generating an active seed upon irradiation with one of an actinic ray and a radiation,

(B) a compound capable of reacting with the active seed generated from the compound (A) and/or performing electron transfer to generate an active seed different from the active seed generated from the compound (A), and

(C) a compound capable of performing electron transfer from the active seed generated from the compound (B) to generate an acid,

wherein supposing that the ½ wave of the oxidation potential of the active seed generated from the compound (B) is Eₚₐ and the ½ wave of the reduction potential of the active seed generated from the compound (C) is E_{pc}, the relationship: E_{pc}−Eₚₐ>0 is satisfied.

(2) The resist composition according to the above (1), wherein the compound (A) contains a structure represented by the following formula (a):

Ra—Rb—COO⁻ (a)

wherein Ra represents a hydrogen atom, a substituted or unsubstituted C₆-C₁₆ aryl group, a substituted or unsubstituted C₁-C₂₀ straight-chain, branched or cyclic alkyl group, —COO⁻ or —SO₃⁻, and Rb represents a single bond, —C(═O)—, —NH— or —S(═O)₂—.

(3) The resist composition according to the above (1), wherein the compound (A) is at least one selected from the group consisting of compounds represented by the formulae (a) and (I) to (IV) in combination:

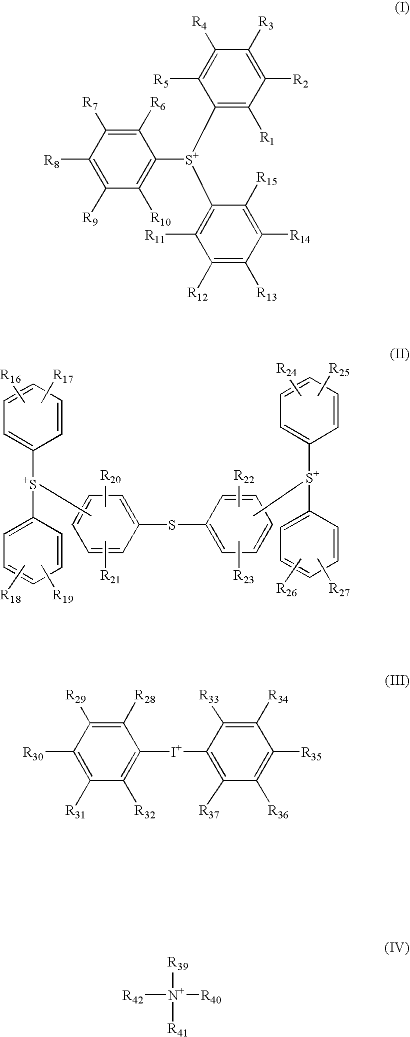

wherein R₁ to R₃₇ each independently represents a hydrogen atom, a straight-chain, branched or cyclic alkyl or alkoxy group, a hydroxyl group, a halogen atom or —S—R₃₈ in which R₃₈ represents a straight-chain, branched or cyclic alkyl or aryl group, with the proviso that two or more of R₁ to R₁₅, R₁₆ to R₂₇ and R₂₈ to R₃₇ may be bonded to each other to form a ring containing one or more selected from the group consisting of a single bond, a carbon atom, an oxygen atom, a sulfur atom and a nitrogen atom, and

R₃₉ to R₄₂ each independently represents a hydrogen atom or a straight-chain, branched or cyclic alkyl or aryl group.

(4) The resist composition according to the above (1), wherein the compound (A) is represented by the following formula (V):

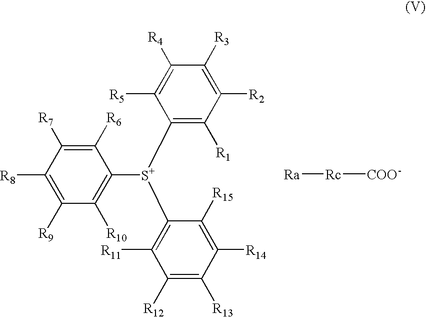

wherein Ra represents a hydrogen atom, a substituted or unsubstituted C₆-C₁₆ aryl group, a substituted or unsubstituted C₁-C₂₀ straight-chain, branched or cyclic alkyl group, —COO⁻ or —SO₃⁻,

Rc represents CH₂, CHRa or C(Ra)₂,

R₁ to R₁₅ each independently represents a hydrogen atom, a straight-chain, branched or cyclic alkyl or alkoxy group, a hydroxyl group, a halogen atom or —S—R₃₈ in which R₃₈ represents a straight-chain, branched or cyclic alkyl or aryl group, with the proviso that two or more of R₁ to R₁₅ may be bonded to each other to form a ring containing one or more selected from the group consisting of a single bond, a carbon atom, an oxygen atom, a sulfur atom and a nitrogen atom.

(5) The resist composition according to the above (1), wherein the compound (A) is represented by the following formula (VI) or (VII):

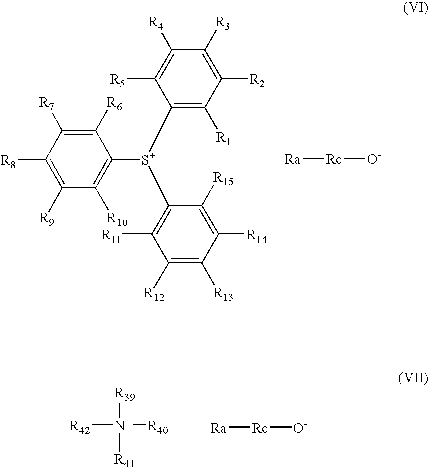

wherein Ra represents a hydrogen atom, a substituted or unsubstituted C₆-C₁₆ aryl group, a substituted or unsubstituted C₁-C₂₀ straight-chain, branched or cyclic alkyl group, —COO⁻ or —SO₃⁻,

Rc represents CH₂, CHRa or C(Ra)₂,

R₁ to R₁₅ each independently represents a hydrogen atom, a straight-chain, branched or cyclic alkyl or alkoxy group, a hydroxyl group, a halogen atom or —S—R₃₈ in which R₃₈ represents a straight-chain, branched or cyclic alkyl or aryl group, with the proviso that two or more of R₁ to R₁₅ may be bonded to each other to form a ring containing one or more selected from the group consisting of a single bond, a carbon atom, an oxygen atom, a sulfur atom and a nitrogen atom, and

R₃₉ to R₄₂ each independently represents a hydrogen atom or a straight-chain, branched or cyclic alkyl or aryl group.

(6) The resist composition according to the above (1), wherein E_{pc} of the compound (C) is higher than −1.15 V.

(7) The resist composition according to the above (1), wherein the compound (C) is a compound having a partial structure represented by the following formula (VIII) and a counter ion capable of generating an acid upon irradiation with one of an actinic ray and a radiation:

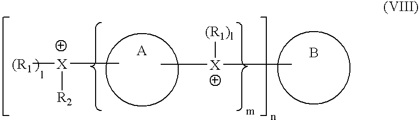

wherein X represents a sulfur atom or an iodine atom, with the proviso that the plurality of X's may be the same or different,

R₁ and R₂ each independently represents an alkyl or an aryl group, with the proviso that the plurality of R₁'s, if any, may be the same or different, the plurality of R₂'s, if any, may be the same or different, and R₁ and R₂, R₁ and A, R₁ and B, R₂ and A, and R₂ and B may be bonded to each other to form a ring,

A and B each independently represents a hydrocarbon structure connecting between X³⁰ 's, with the proviso that at least one of connections of X⁺'s with A or B indicates a structure in which X⁺'s connected are in the same conjugation and the plurality of A's, if any, may be the same or different,

l represents 0 or 1, with the proviso that when X is a sulfur atom, the number l of R¹'s connected to X⁺ represents 1, and when X is an iodine atom, the number l of R¹'s connected to X⁺ represents 0,

m represents an integer of from 0 to 10,

n represents an integer of from 1 to 6, with the proviso that when m is 0, n represents an integer of not smaller than 2.

(8) The resist composition according to the above (1), wherein the compound (B) is a phenol derivative containing from 1 to 10 benzene ring atomic groups per molecule and having at least one hydroxymethyl group and at least one alkoxymethyl group per molecule.

(9) The resist composition according to the above (1), wherein the compound (B) contains a structure represented by the following formula (b):

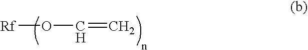

wherein Rf represents a substituted or unsubstituted aryl group, a substituted or unsubstituted straight-chain, branched or alicyclic hydrocarbon group or a combination thereof, which may have a carbonyl group, an oxygen atom or a sulfur atom in the middle portion thereof, and n represents an integer of from 1 to 10.

(10) The resist composition according to the above (1), wherein the compound (B) is a cyclic ether compound.

(11) The resist composition according to the above (1), further comprising (E) a nitrogen-containing basic compound.

(12) The resist composition according to the above (1), wherein the actinic ray or radiation is selected from the group consisting of electron ray, X ray and EUV ray.

(13) A negative-working resist composition comprising:

(A) at least one selected from the group consisting of compounds represented by the formulae (a) and (I) to (IV) in combination,

(B) a crosslinking agent capable of carrying out addition reaction with the alkali-soluble resin which is the component (D1) by the action of an acid,

(C) a compound having a partial structure represented by the following formula (VIII) and a counter ion capable of generating an acid upon irradiation with one of an actinic ray and a radiation, and

(D1) an alkali-soluble resin:

Ra—Rb—COO⁻ (a)

wherein Ra represents a hydrogen atom, a substituted or unsubstituted C₆-C₁₆ aryl group, a substituted or unsubstituted C₁-C₂₀ straight-chain, branched or cyclic alkyl group, —COO⁻ or —SO₃⁻, and Rb represents a single bond, —C(═O)—, —NH— or —S(═O)₂—:

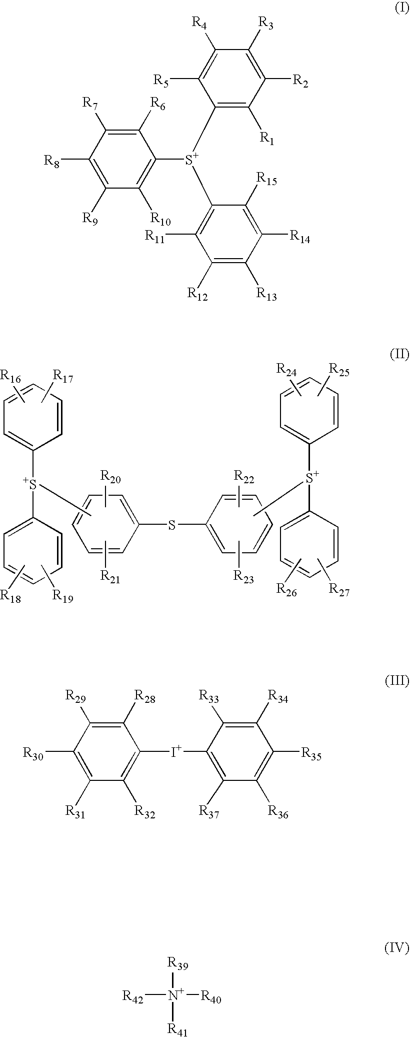

wherein R₁ to R₃₇ each independently represents a hydrogen atom, a straight-chain, branched or cyclic alkyl or alkoxy group, a hydroxyl group, a halogen atom or —S—R₃₈ in which R₃₈ represents a straight-chain, branched or cyclic alkyl or aryl group, with the proviso that two or more of R₁ to R₁₅, R₁₆ to R₂₇ and R₂₈ to R₃₇ may be bonded to each other to form a ring containing one or more selected from the group consisting of a single bond, a carbon atom, an oxygen atom, a sulfur atom and a nitrogen atom, and

R₃₉ to R₄₂ each independently-represents a hydrogen atom or a straight-chain, branched or cyclic alkyl or aryl group:

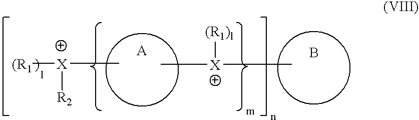

wherein X represents a sulfur atom or an iodine atom, with the proviso that the plurality of X's may be the same or different,

R₁ and R₂ each independently represents an alkyl or an aryl group, with the proviso that the plurality of R₁'s, if any, may be the same or different, the plurality of R₂'s, if any, may be the same or different, and R₁ and R₂, R₁ and A, R₁ and B, R₂ and A, and R₂ and B may be bonded to each other to form a ring,

A and B each independently represents a hydrocarbon structure connecting between X⁺'s, with the proviso that at least one of connections of X⁺'s with A or B indicates a structure in which X⁺'s connected are in the same conjugation and the plurality of A's, if any, may be the same or different,

l represents 0 or 1, with the proviso that when X is a sulfur atom, the number l of R¹'s connected to X⁺ represents 1, and when X is an iodine atom, the number l of R¹'s connected to X⁺ represents 0,

m represents an integer of from 0 to 10,

n represents an integer of from 1 to 6, with the proviso that when m is 0, n represents an integer of not smaller than 2.

(14) A negative-working resist composition comprising:

(A) at least one selected from the group consisting of compounds represented by the formulae (a′) and (I) to (IV) in combination,

(B) a crosslinking agent capable of carrying out addition reaction with the alkali-soluble resin which is the component (D1) by the action of an acid, and

(C) a compound having a partial structure represented by the following formula (VIII) and a counter ion capable of generating an acid upon irradiation with one of an actinic ray. and a radiation,

(D1) an alkali-soluble resin:

Ra—O⁻ (a′)

wherein Ra represents a hydrogen atom, a substituted or unsubstituted C₆-C₁₆ aryl group, a substituted or unsubstituted C₁-C₂₀ straight-chain, branched or cyclic alkyl group, —COO⁻ or —SO₃⁻:

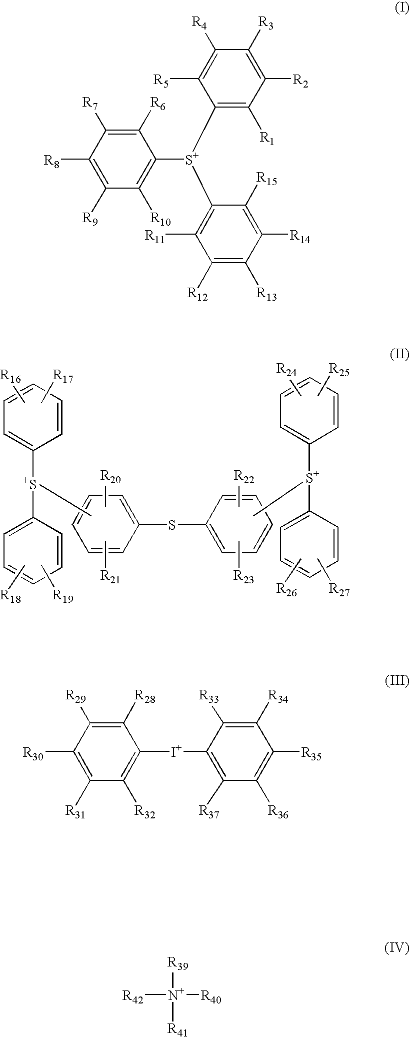

wherein R₁ to R₃₇ each independently represents a hydrogen atom, a straight-chain, branched or cyclic alkyl or alkoxy group, a hydroxyl group, a halogen atom or —S—R₃₈ in which R₃₈ represents a straight-chain, branched or cyclic alkyl or aryl group, with the proviso that two or more of R₁ to R₁₅, R₁₆ to R₂₇ and R₂₈ to R₃₇ may be bonded to each other to form a ring containing one or more selected from the group consisting of a single bond, a carbon atom, an oxygen atom, a sulfur atom and a nitrogen atom, and

R₃₉ to R₄₂ each independently represents a hydrogen atom or a straight-chain, branched or cyclic alkyl or aryl group:

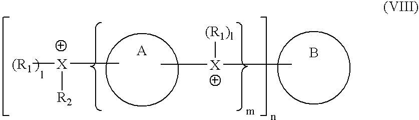

wherein X represents a sulfur atom or an iodine atom, with the proviso that the plurality of X's may be the same or different,

R₁ and R₂ each independently represents an alkyl or an aryl group, with the proviso that the plurality of R₁'s, if any, may be the same or different, the plurality of R₂'s, if any, may be the same or different, and R₁ and R₂, R₁ and A, R₁ and B, R₂ and A, and R₂ and B may be bonded to each other to form a ring,

A and B each independently represents a hydrocarbon structure connecting between X⁺'s, with the proviso that at least one of connections of X⁺'s with A or B indicates a structure in which X⁺'s connected are in the same conjugation and the plurality of A's, if any, may be the same or different,

l represents 0 or 1, with the proviso that when X is a sulfur atom, the number 1 of R¹'s connected to X⁺ represents 1, and when X is an iodine atom, the number l of R¹'s connected to X⁺ represents 0,

m represents an integer of from 0 to 10,

n represents an integer of from 1 to 6, with the proviso that when m is 0, n represents an integer of not smaller than 2.

(15) The negative-working resist composition according to the above (13), wherein the component (A) is at least one selected from the compounds represented by the formula (a) and the formula (I) or (II) in combination.

(16) The positive-working resist composition according to the above (13), further comprising (E) anitrogen-containing basic compound.

(17) A positive-working resist composition comprising:

(A) at least one selected from the group consisting of compounds represented by the formulae (a) and (I) to (IV) in combination,

(C) a compound having a partial structure represented by the following formula (VIII) and a counter ion capable of generating an acid upon irradiation with one of an actinic ray and a radiation, and

(D2) a resin increasing the solubility in an alkali developer by the action of an acid:

Ra—Rb—COO⁻ (a)

wherein Ra represents a hydrogen atom, a substituted or unsubstituted C₆-C₁₆ aryl group, a substituted or unsubstituted C₁-C₂₀ straight-chain, branched or cyclic alkyl group, —COO⁻ or —SO₃⁻, and Rb represents a single bond, —C(═O)—, —NH— or —S(═O)₂—:

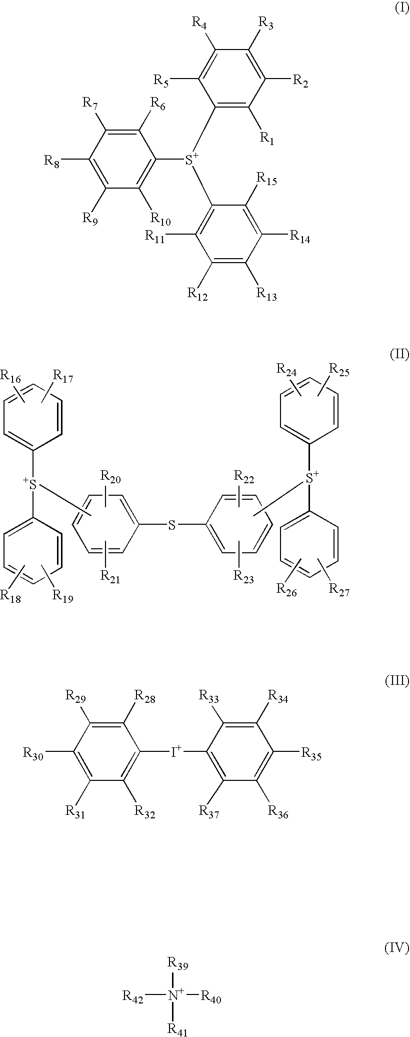

wherein R₁ to R₃₇ each independently represents a hydrogen atom, a straight-chain, branched or cyclic alkyl or alkoxy group, a hydroxyl group, a halogen atom or —S—R₃₈ in which R₃₈ represents a straight-chain, branched or cyclic alkyl or aryl group, with the proviso that two or more of R₁ to R₁₅, R₁₆ to R₂₇ and R₂₈ to R₃₇ may be bonded to each other to form a ring containing one or more selected from the group consisting of a single bond, a carbon atom, an oxygen atom, a sulfur atom and a nitrogen atom, and

R₃₉ to R₄₂ each independently represents a hydrogen atom or a straight-chain, branched or cyclic alkyl or aryl group:

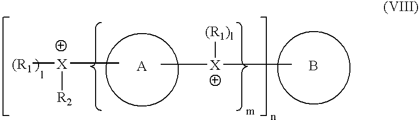

wherein X represents a sulfur atom or an iodine atom, with the proviso that the plurality of X's may be the same or different,

R₁ and R₂ each independently represents an alkyl or an aryl group, with the proviso that the plurality of R₁'s, if any, may be the same or different, the plurality of R₂'s, if any, may be the same or different, and R₁ and R₂, R₁ and A, R₁ and B, R₂ and A, and R₂ and B may be bonded to each other to form a ring,

A and B each independently represents a hydrocarbon structure connecting between X⁺'s, with the proviso that at least one of connections of X⁺'s with A or B indicates a structure in which X⁺'s connected are in the same conjugation and the plurality of A's, if any, may be the same or different,

l represents 0 or 1, with the proviso that when X is a sulfur atom, the number 1 of R¹'s connected to X⁺ represents 1, and when X is an iodine atom, the number l of R¹'s connected to X⁺ represents 0,

m represents an integer of from 0 to 10,

n represents an integer of from 1 to 6, with the proviso that when m is 0, n represents an integer of not smaller than 2.

(18) A positive-working resist composition comprising:

(A) at least one selected from the group consisting of compounds represented by the formulae (a′) and (I) to (IV) in combination,

(C) a compound having a partial structure represented by the following formula (VIII) and a counter ion capable of generating an acid upon irradiation with one of an actinic ray and a radiation, and

(D2) a resin increasing the solubility in an alkali developer by the action of an acid:

Ra—O⁻ (a′)

wherein Ra represents a hydrogen atom, a substituted or unsubstituted C₆-C₁₆ aryl group, a substituted or unsubstituted C₁-C₂₀ straight-chain, branched or cyclic alkyl group, —COO⁻ or —SO₃⁻:

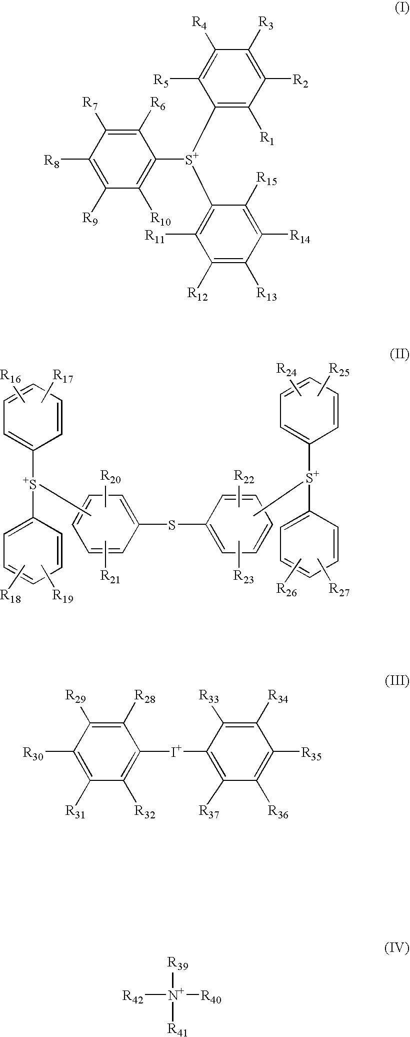

wherein R₁ to R₃₇ each independently represents a hydrogen atom, a straight-chain, branched or cyclic alkyl or alkoxy group, a hydroxyl group, a halogen atom or —S—R₃₈ in which R₃₈ represents a straight-chain, branched or cyclic alkyl or aryl group, with the proviso that two or more of R₁ to R₁₅, R₁₆ to R₂₇ and R₂₈ to R₃₇ may be bonded to each other to form a ring containing one or more selected from the group consisting of a single bond, a carbon atom, an oxygen atom, a sulfur atom and a nitrogen atom, and

R₃₉ to R₄₂ each independently represents a hydrogen atom or a straight-chain, branched or cyclic alkyl or aryl group:

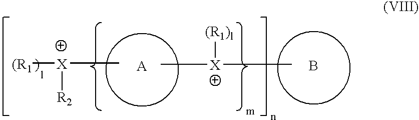

wherein X represents a sulfur atom or an iodine atom, with the proviso that the plurality of X's may be the same or different,

R₁ and R₂ each independently represents an alkyl or an aryl group, with the proviso that the plurality of R₁'s, if any, may be the same or different, the plurality of R₂'s, if any, may be the same or different, and R₁ and R₂, R₁ and A, R₁ and B, R₂ and A, and R₂ and B may be bonded to each other to form a ring,

A and B each independently represents a hydrocarbon structure connecting between X⁺'s, with the proviso that at least one of connections of X⁺'s with A or B indicates a structure in which X⁺'s connected are in the same conjugation and the plurality of A's, if any, may be the same or different,

l represents 0 or 1, with the proviso that when X is a sulfur atom, the number 1 of R¹'s connected to X⁺ represents 1, and when X is an iodine atom, the number l of R¹'s connected to X⁺ represents 0,

m represents an integer of from 0 to 10,

n represents an integer of from 1 to 6, with the proviso that when m is 0, n represents an integer of not smaller than 2.

(19) The positive-working resist composition according to the above (17), wherein the component (A) is at least one selected from the compounds represented by the formula (a) and the formula (I) or (II) in combination.

(20) The positive-working resist composition according to the above (17), further comprising (E) anitrogen-containing basic compound.

(21) The resist composition according to claim 13, wherein the actinic ray or radiation is selected from the group consisting of electron ray, X ray and EUV ray.

### DETAILED DESCRIPTION OF THE INVENTION

The mechanism of multiplication of acid in the presence of exo-Norborneol as a secondary alcohol and diphenyliodonium triphtalate as an acid generator is reported in “SPIE”, 3999, pp. 386 (2000). However, this report has a description that no acids are not multiplied in a phenolic resin, particularly in PHS (polyhydroxystyrene) and novolak.

In the invention, the compounds (A), (B) and (C) are referred to as “initiator”, “mediator” and “acid generator”, respectively. In the invention, the addition of an initiator causes drastic enhancement of the efficiency of acid multiplication, making it possible to overcome the aforementioned problem that the multiplication of acid is inhibited in a phenolic resin. It is particularly important that a proper mediator (B) is selected and an initiator (A) is added. In this arrangement, the invention can apply to not only positive-working resist composition but also negative-working resist composition. In particular, the invention is very useful with negative-working resist compositions because most of them are made of phenolic resin.

The mechanism of the invention is presumed as follows.

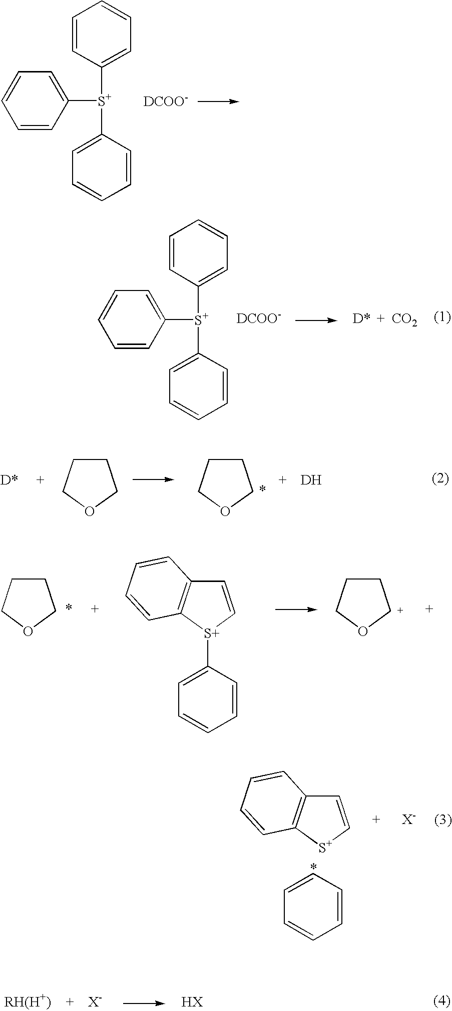

In the foregoing formulae, resist compositions obtained with electron ray as radiation are exemplified. As the mediator (B) there is used a cyclic ether in the foregoing formulae. A phenolic crosslinking agent having a hydroxymethyl group and an alkoxymethyl group in its molecule is particularly useful for negative-working resist composition.

The role of the compound (B) of the invention will be presumed below. The compounds (A) to (C) of the invention will be occasionally referred simply to as “(A)” to “(C)”, respectively.

It is presumed that (B) plays a role of carrying an active seed such as radical generated from (A) to (C) (acid generator). It is also presumed that when (B) is absent, the active seed generated from (A) is deactivated before reaching (C) because it has a short life. It is thus presumed that the invention makes the use of the mechanism that the radical (B) is somewhat stabilized but is instable enough to perform electron transfer to (C).

The compounds to be used in the invention will be further described hereinafter.

[1] Compound (A)

The compound (A) capable of generating an active seed that reacts with (B) and/or performs electron transfer upon irradiation with one of an actinic ray and a radiation is preferably a compound capable of generating an active radical upon irradiation with one of an actinic ray and a radiation.

One of preferred examples of the compound (A) is a compound having a carboxylate incorporated therein, particularly a compound having a structure represented by the following formula (a) incorporated therein.

Ra—Rb—COO⁻ (a)

In the formula (a), Ra represents a hydrogen atom, a substituted or unsubstituted aryl group, a substituted or unsubstituted straight-chain, branched or cyclic alkyl group, —COO⁻ or —SO₃⁻. Ra may have a sulfur atom, an oxygen atom, a nitrogen atom, —C(═O)— or —NHC(—O)— interposed between the elements thereof. Rb represents a single bond, —C(═O)—, —NH— or —S(═O)₂—.

The aryl group represented by Ra is preferably a C₆-C₁₆ aryl group. Examples of the aryl group include phenyl group, naphthyl group, anthranyl group, phenanthrenyl group, and pyrenyl group.

Examples of the substitutent on the aryl group include fluorine atom, chlorine atom, bromine atom, iodine atom, C₁-C₅ straight-chain or branched alkyl group, C₁-C₃ straight-chain or branched fluorine-substituted alkyl group, hydroxyl group, thiol group, C₁-C₅ alkyloxy group, nitro group, cyano group, formyl group, —COO⁻, and —SO₃⁻.

The straight-chain, branched or cyclic alkyl group represented by Ra is preferably a C₁-C₂₀ straight-chain, branched or cyclic alkyl group such as methyl group, ethyl group, propyl group, isopropyl group, butyl group, isobutyl group, t-butyl group, pentyl group, neopentyl group, hexyl group, heptyl group, octyl group, nonyl group, lauryl group, cyclopropyl group, cyclopentyl group, cyclohexyl group, norbornyl group, and adamanthyl group.

Examples of the substituent on the straight-chain or branched alkyl group include fluorine atom, chlorine atom, bromine atom, iodine atom, hydroxyl group, C₁-C₅ alkyloxy group, thiol group, cyano group, nitro group, formyl group, —COO⁻, —SO₃⁻, vinyl group, amide group, phenyl group, naphthyl group, anthranyl group, cyclohexyl group, and norbornyl group.

Examples of the substituent on the cyclic alkyl group include fluorine atom, chlorine atom, bromine atom, iodine atom, hydroxyl group, thiol group, methyl group, ethyl group, propyl group, isopropyl group, butyl group, isobutyl group, and t-butyl group.

In the formulae (I) to (IV), R₁ to R₃₇ each independently represent a hydrogen atom, straight-chain, branched or cyclic alkyl group, straight-chain, branched or cyclic alkoxy group, hydroxyl group, halogen atom or —S—R₃₈.

R₃₈ represents a straight-chain, branched or cyclic alkyl or aryl group. Two or more of R₁ to R₁₅, R₁₆ to R₂₇ and R₂₈ to R₃₇ may be bonded to each other to form a ring containing one or more selected from the group consisting of a single bond, a carbon atom, an oxygen atom, a sulfur atom and a nitrogen atom.

R₃₉ to R₄₂ each independently represents a hydrogen atom or straight-chain, branched or cyclic alkyl or aryl group.

Examples of the straight-chain or branched alkyl group represented by R₁ to R₃₈ and R₃₉ to R₄₂ in the formulae (X) to (IV) include C₁-C₂₀ alkyl group such as methyl group, ethyl group, propyl group, n-butyl group, sec-butyl group and-t-butyl group which may have substituents. Examples of the cyclic alkyl group include C₃-C₈ alkyl group such as cyclopropyl group, cyclopentyl group and cyclohexyl group, which may have substituents.

Examples of the straight-chain or branched alkoxy group represented by R₁ to R₃₇ include C₁-C₄ alkoxy group such as methoxy group, ethoxy group, hydroxyethoxy group, propoxy group, n-butoxy group, isobutoxy group, sec-butoxy group and t-butoxy group.

Examples of the cyclic alkoxy group include cyclopentyloxy group such as cyclopentyloxy group and cyclohexyloxy group.

Examples of the halogen atom represented by R₁ to R₃₇ include a fluorine atom, a chlorine atom, a bromine atom, and an iodine atom.

Examples of the aryl group represented by R₃₉ and R₃₉ to R₄₂ include C₆-C₁₄ aryl group such as phenyl group, tolyl group, methoxyphenyl group and naphthyl group.

Preferred examples of these substituents include C₁-C₄ alkoxy group, halogen atom (e.g., fluorine atom, chlorine atom, iodine atom), C₆-C₁₅ aryl group, C₂-C₆ alkenyl group, cyano group, hydroxyl group, carboxy group, alkoxycarbonyl group, and nitro group.

In particular, the straight-chain, branched or cyclic alkyl group represented by R₃₉ to R₄₂ may have oxygen atom, sulfur atom, nitrogen atom, —C(═O)— and composite thereof interposed between the elements thereof or maybe substituted by aryl group, cyclic alkyl group, halogen atom, etc. In particular, the aryl group represented by R₃₉ to R₄₂ may be substituted by a straight-chain, branched or cyclic alkyl group, straight-chain, branched or cyclic alkoxy group, hydroxyl group, halogen atom, etc.

Examples of the ring containing one or more selected from the group consisting of a single bond, a carbon atom, an oxygen atom, a sulfur atom and a nitrogen atom formed by the connection of two or more of R₁ to R₁₅, R₁₆ to R₂₇ and R₂₈ to R₃₇ include furane ring, dihydrofurane ring, pyran ring, trihydropyran ring, thiophene ring, and pyrrole ring.

In the invention, the compound (A) is preferably represented by the following formula (V).

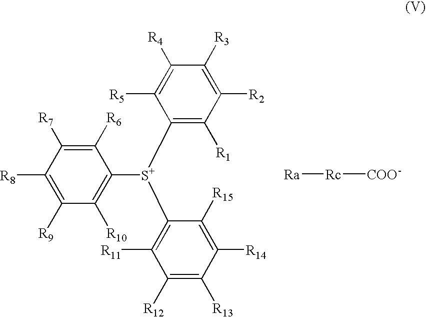

In the formula (V), Ra is same meaning as that defined in the formula (a).

Rc represents CH₂, CHRa or C(Ra)₂. R₁ to R₁₅ are same meaning as those defined in the formula (I).

The compound (A) is also preferably a compound represented by the following formula (VI) or (VII).

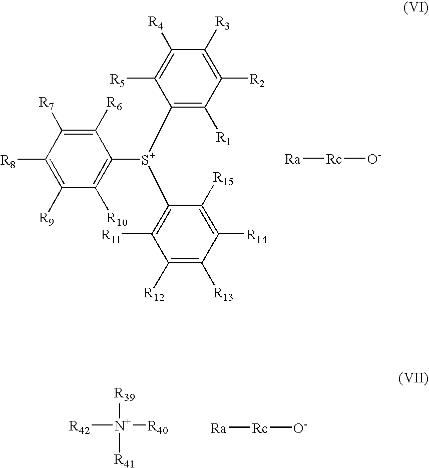

In the formula (VI), Ra is same meaning as that defined in the formula (a).

Rc represents CH₂, CHRa or C(Ra)₂. R₁ to R₁₅ are same meaning as those defined in the formula (I).

In the formula (VII) Ra is same meaning as that defined in the formula (a).

Rc represents CH₂, CHRa or C(Ra)₂. R₃₉ to R₄₁ are same meaning as those defined in the formula (IV).

Specific examples of the compound (A) will be given below, but the invention is not limited thereto.

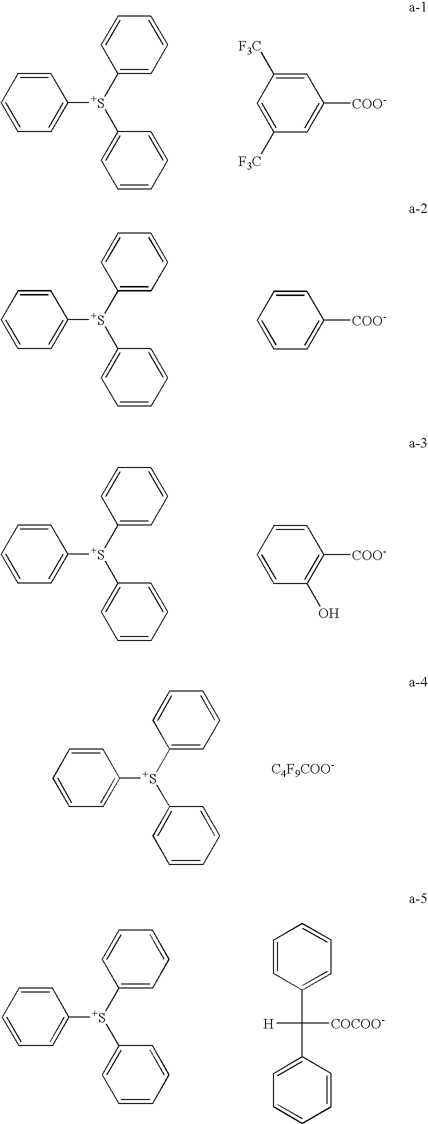

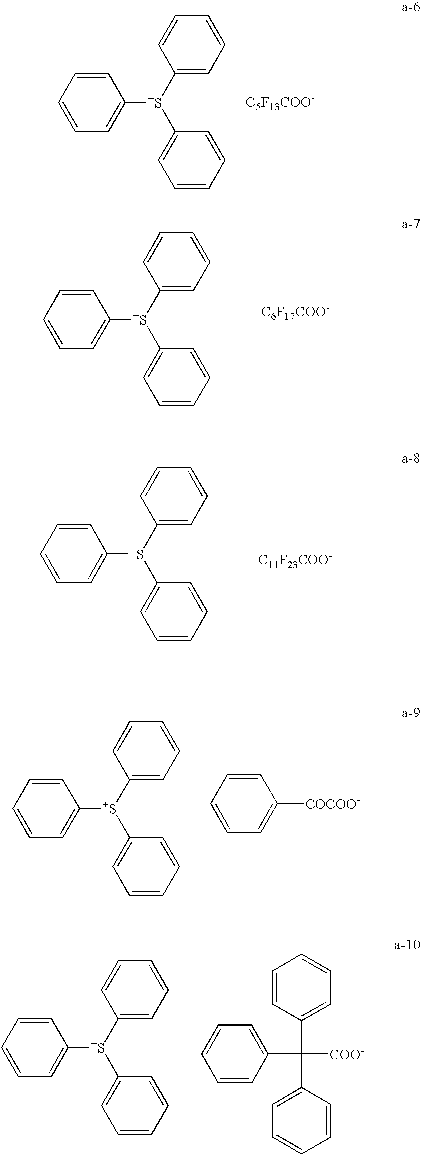

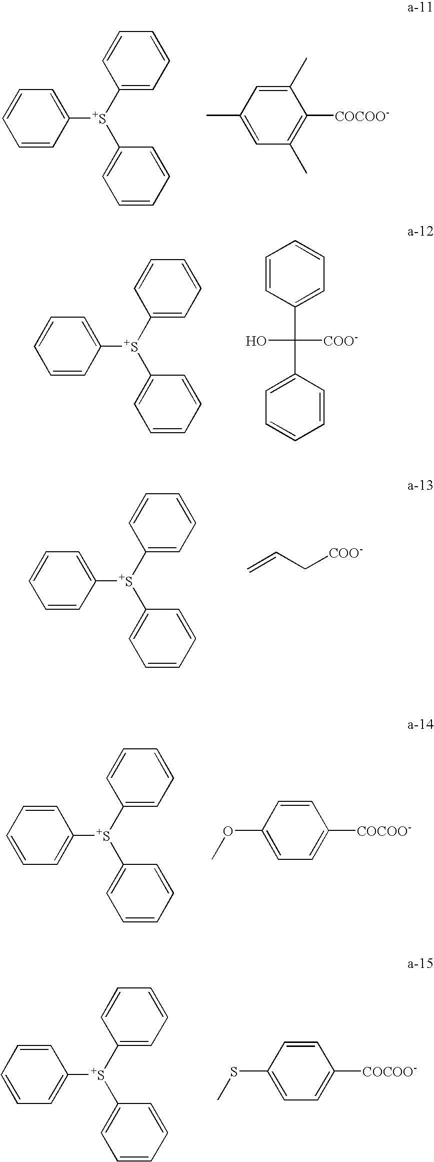

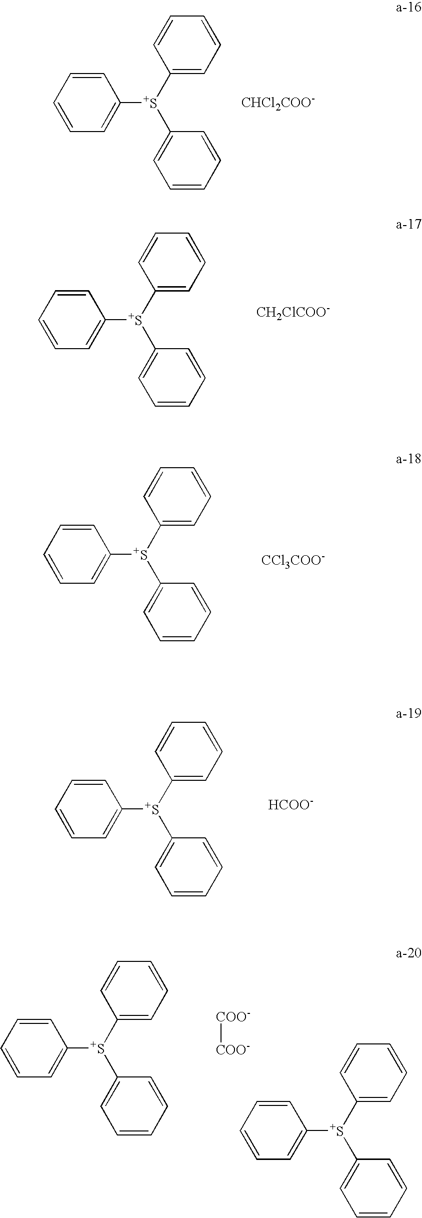

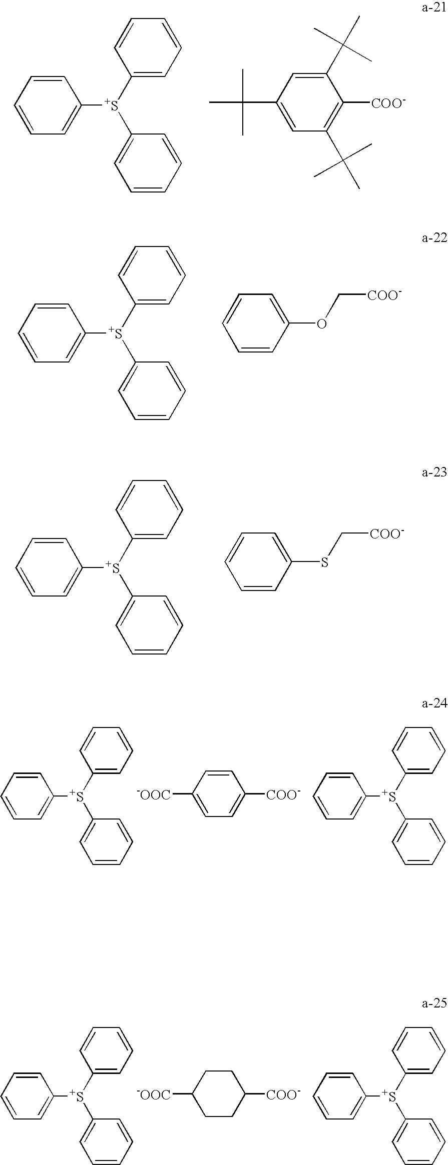

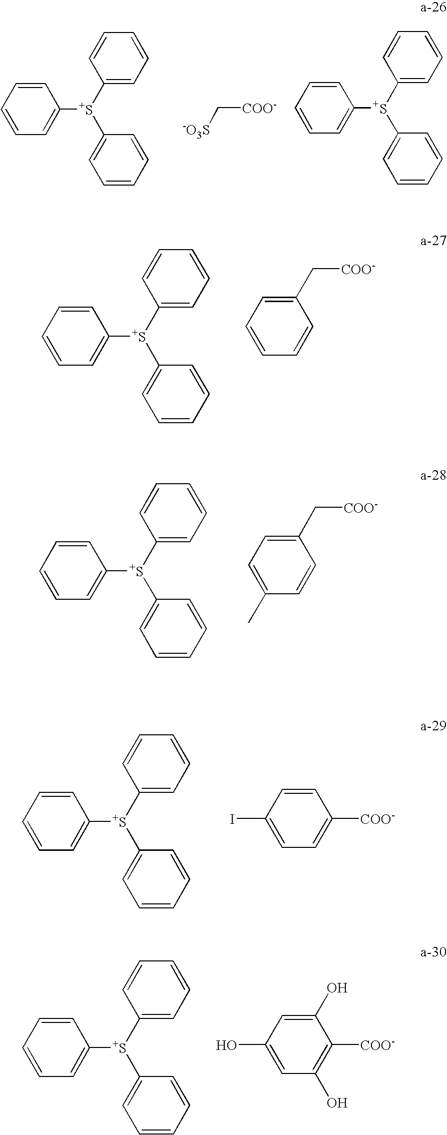

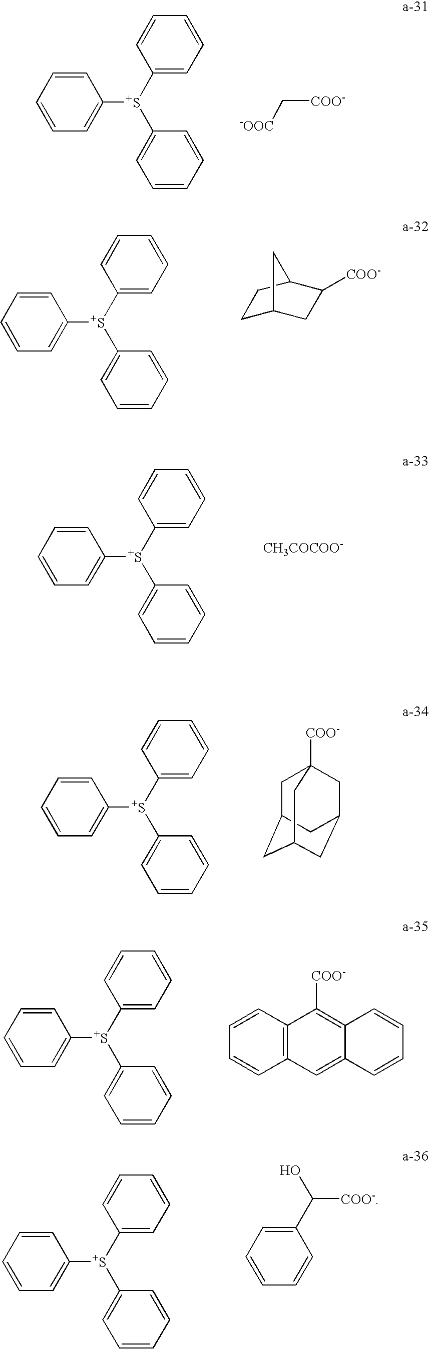

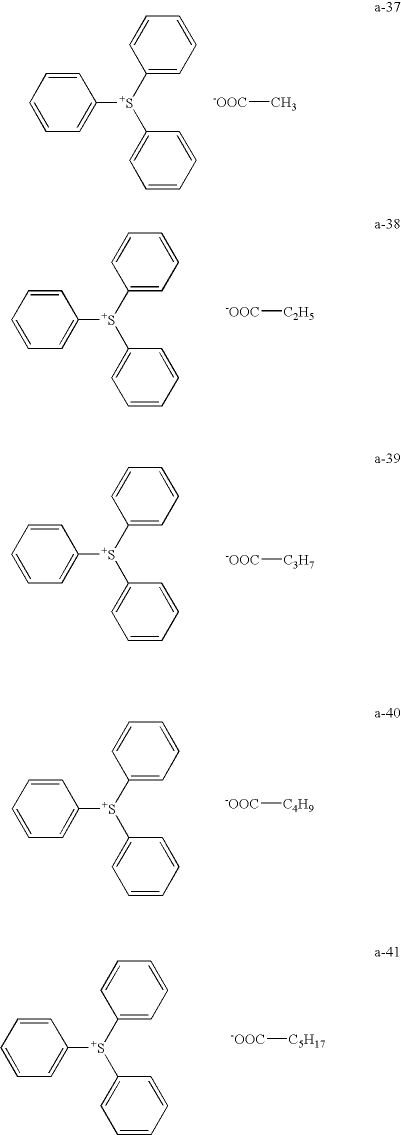

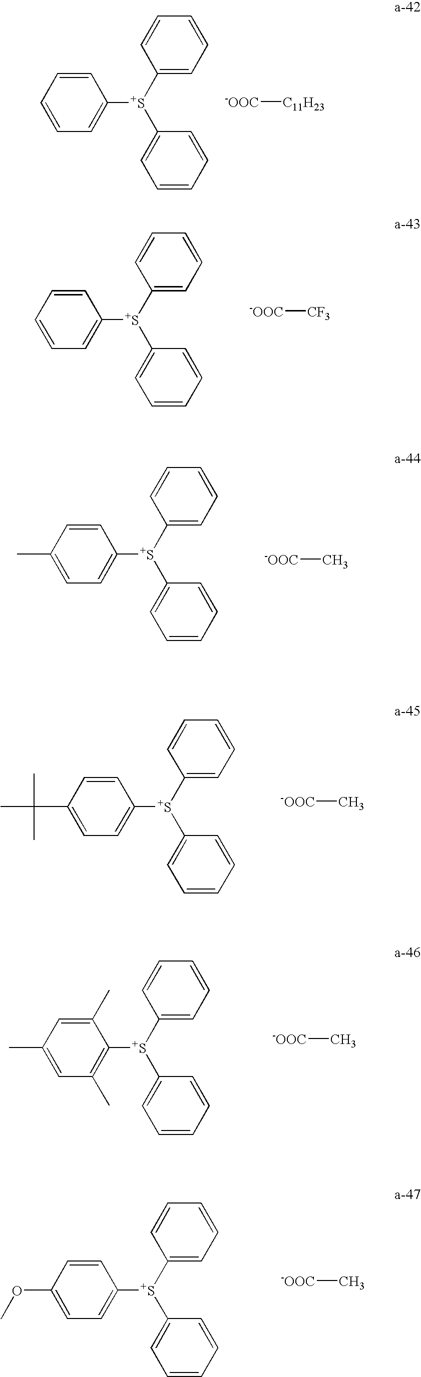

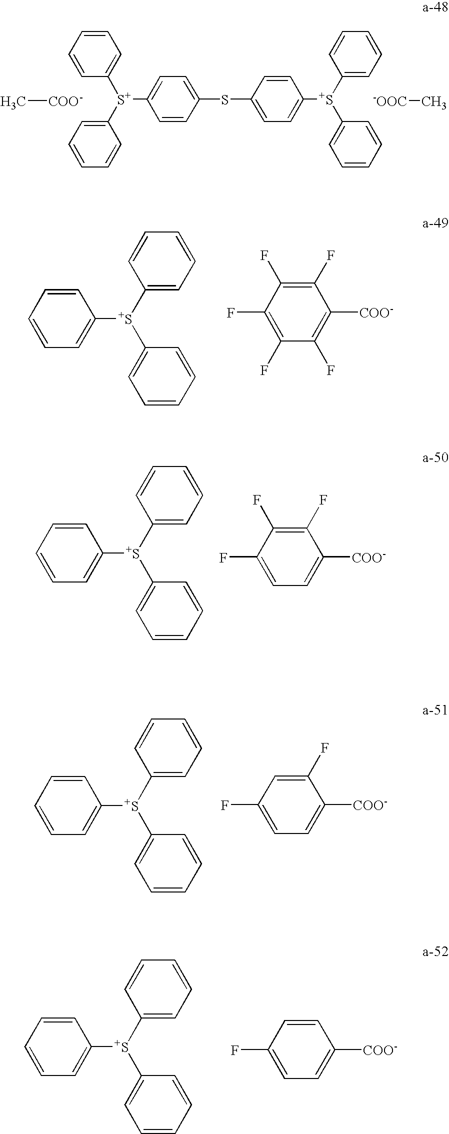

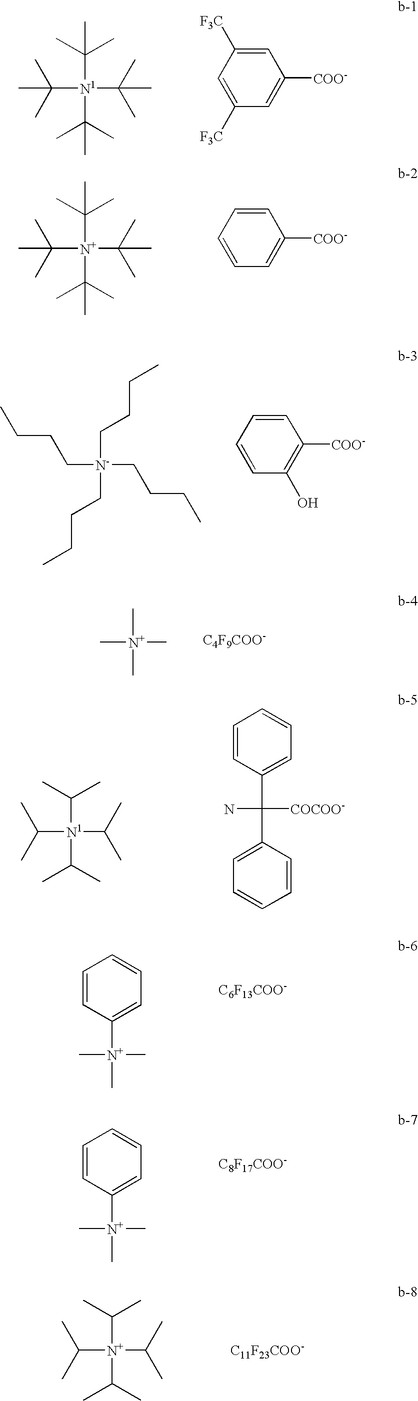

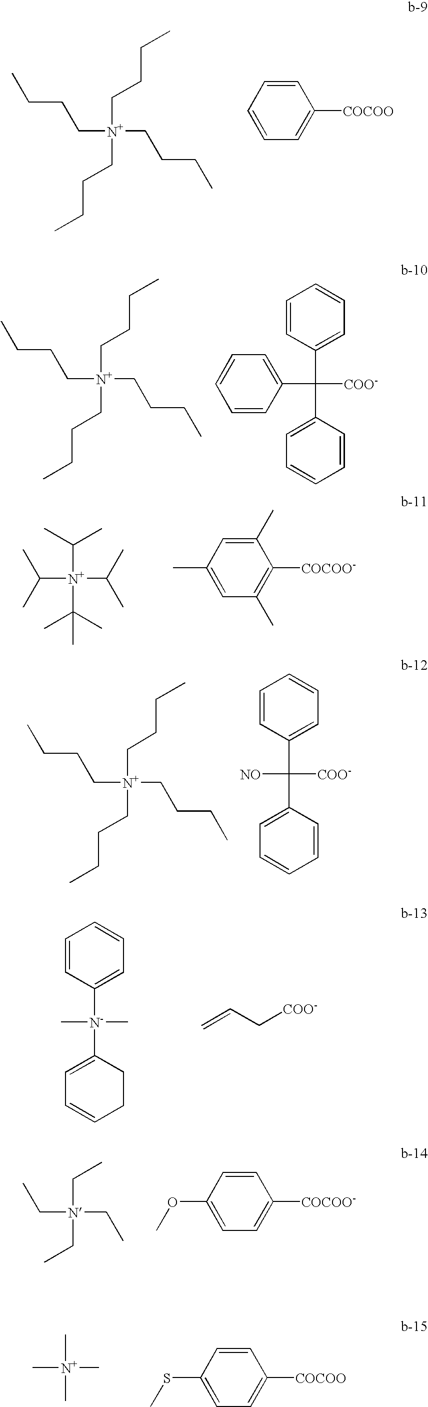

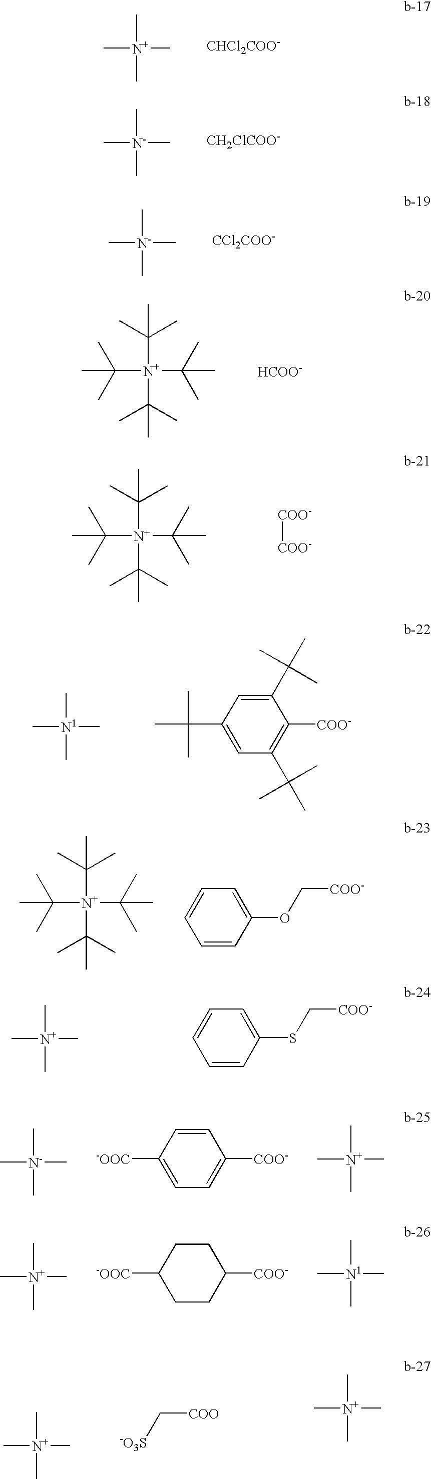

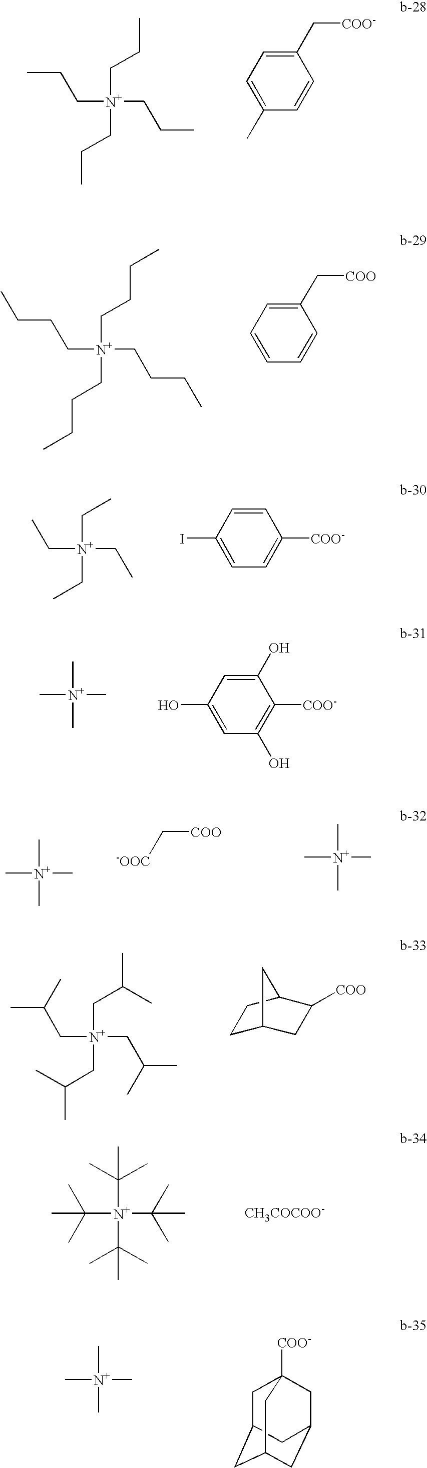

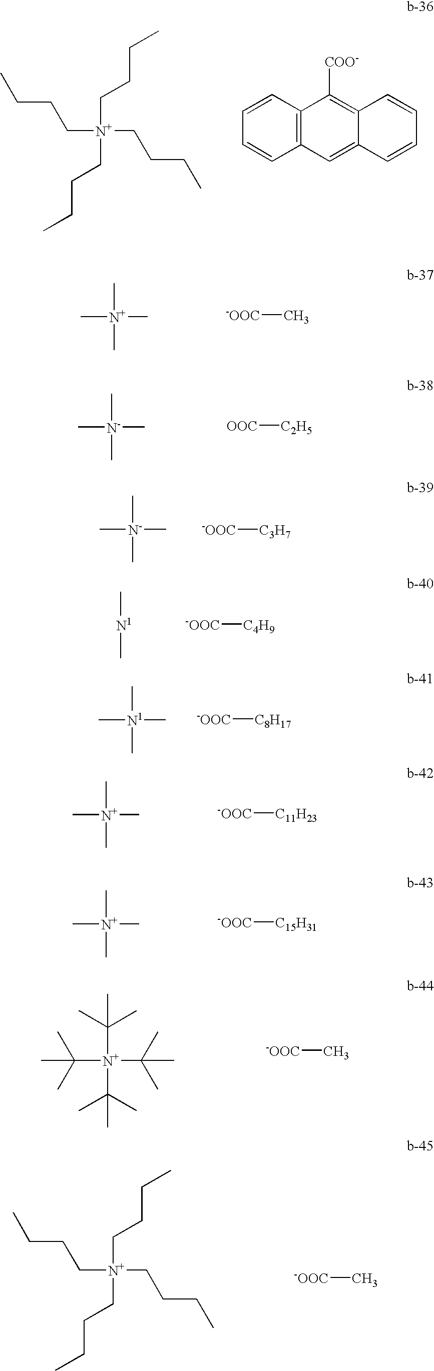

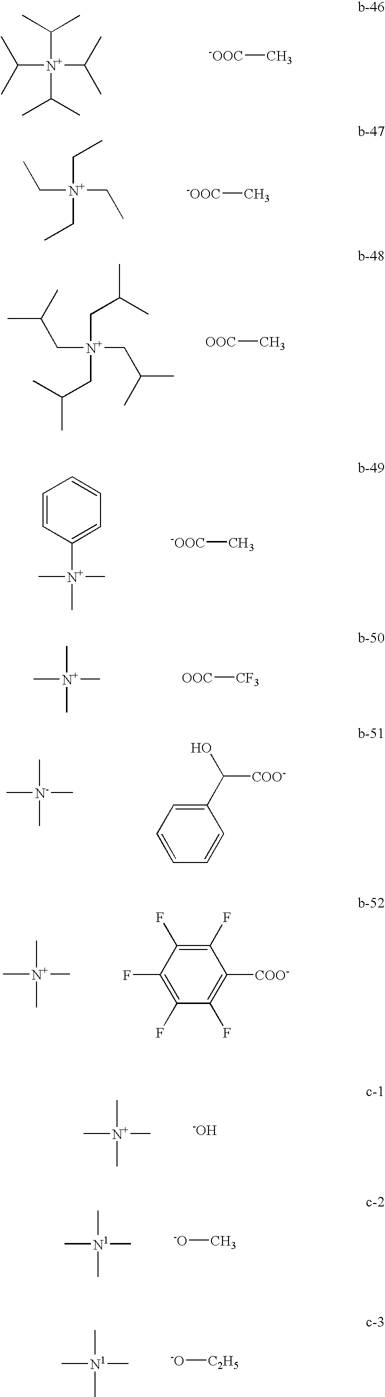

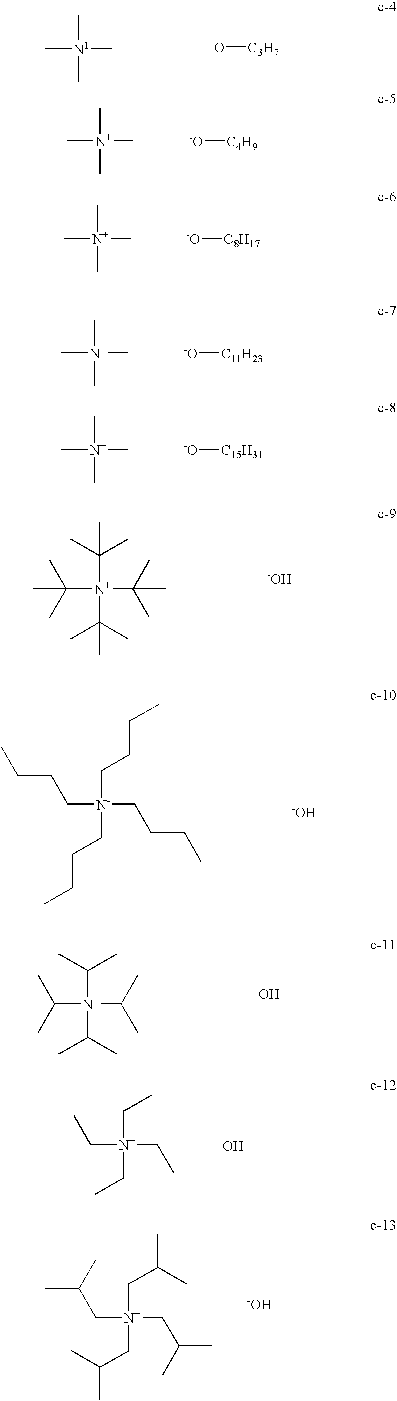

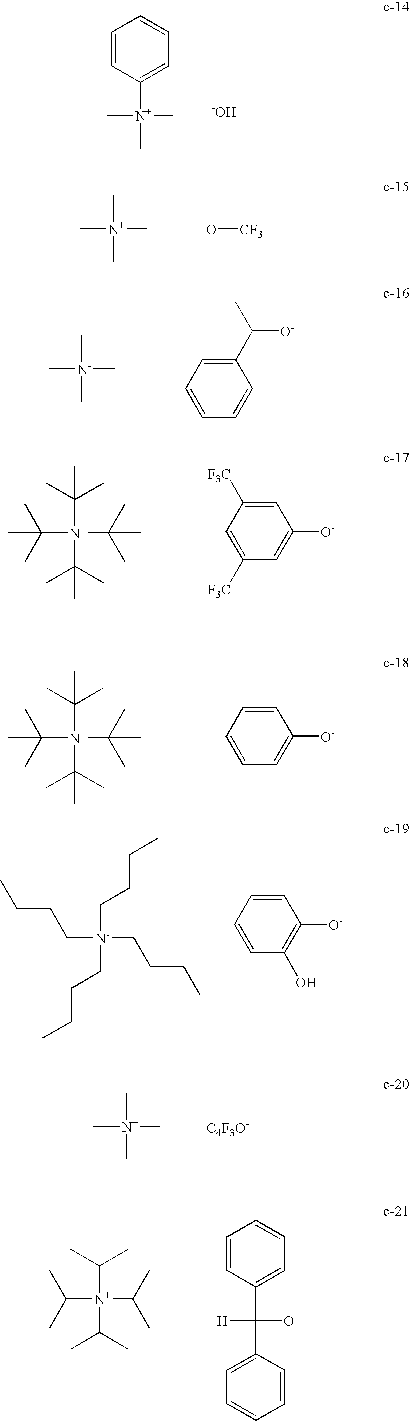

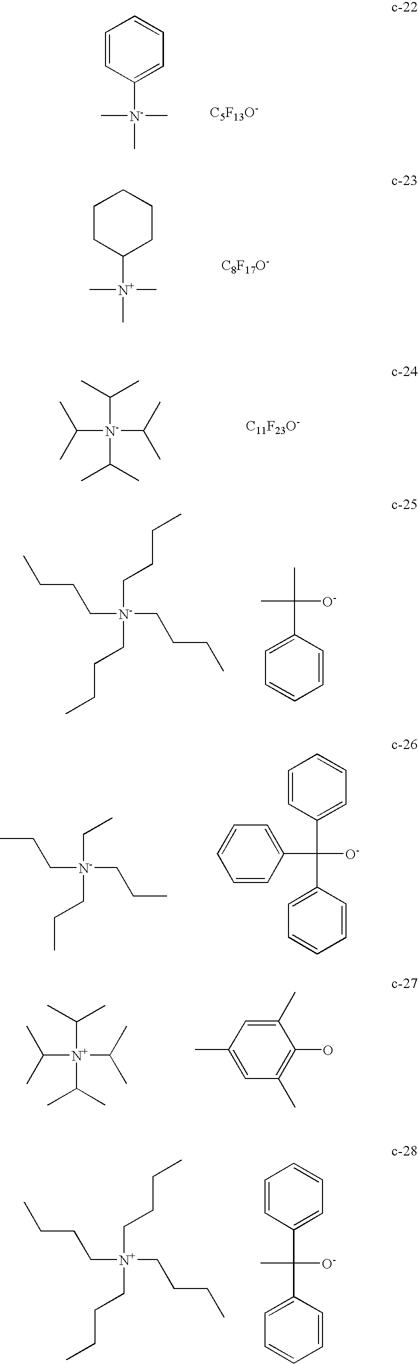

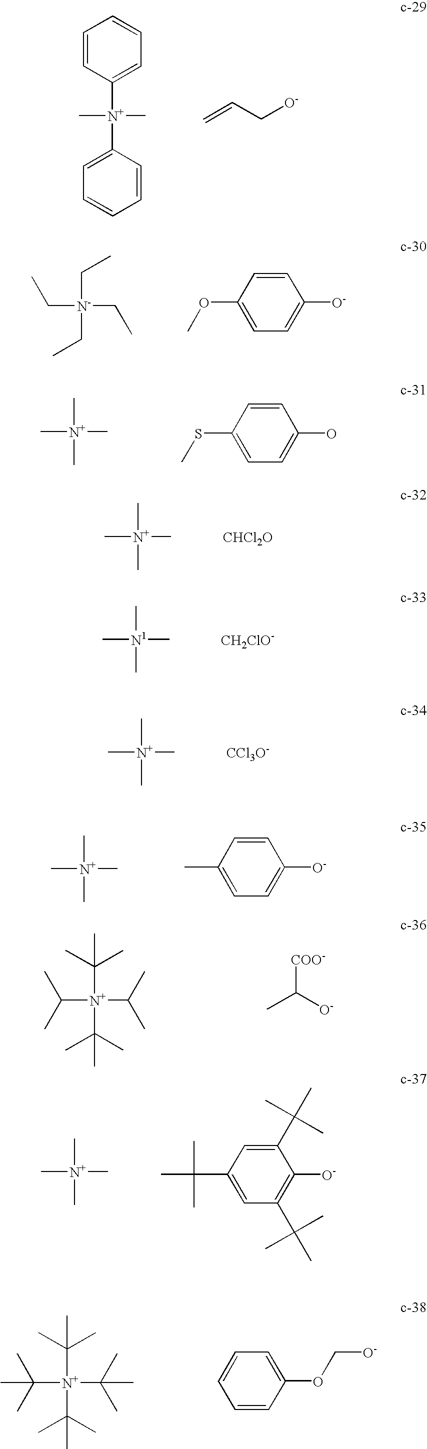

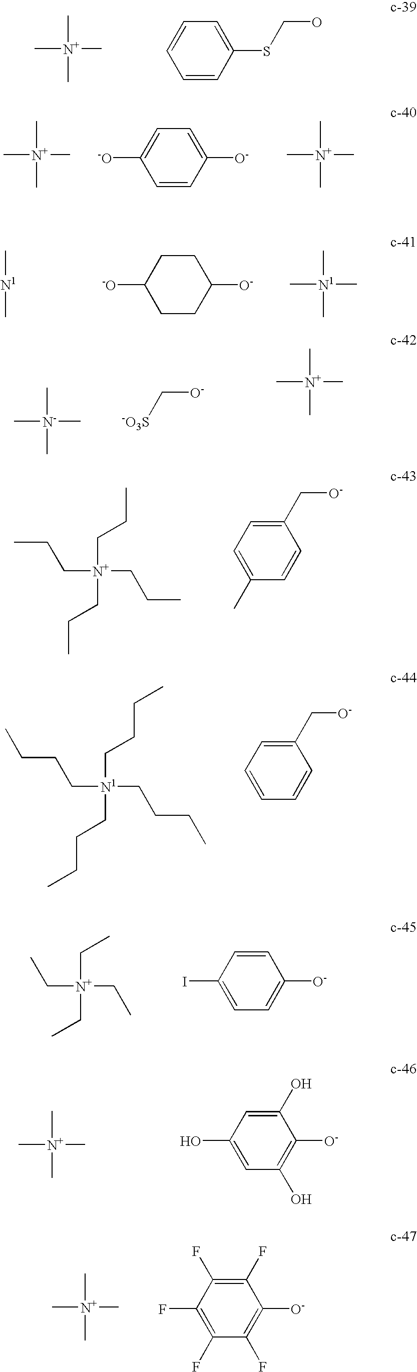

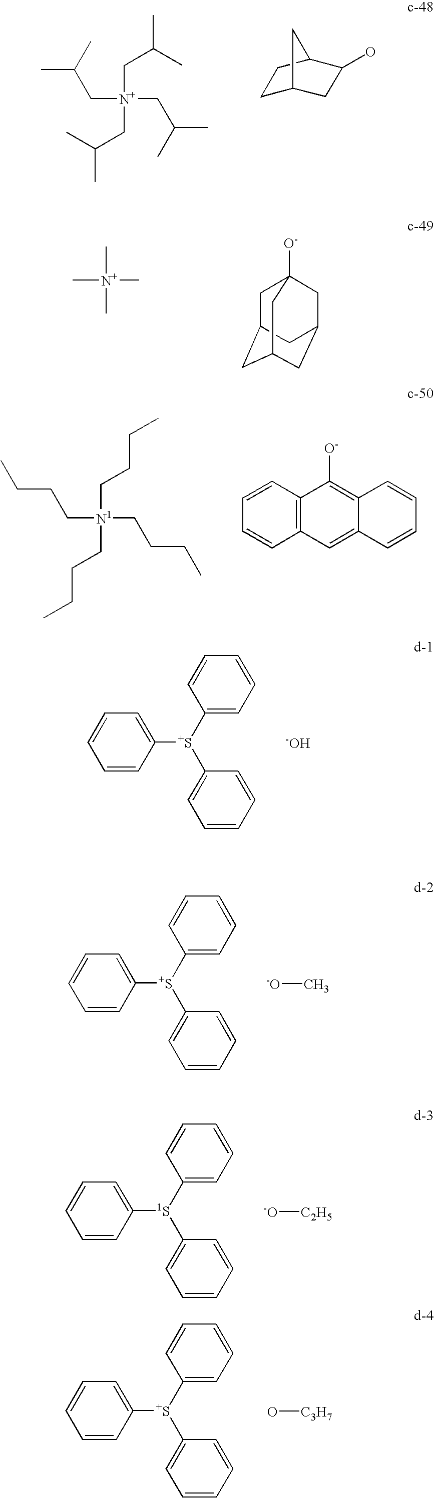

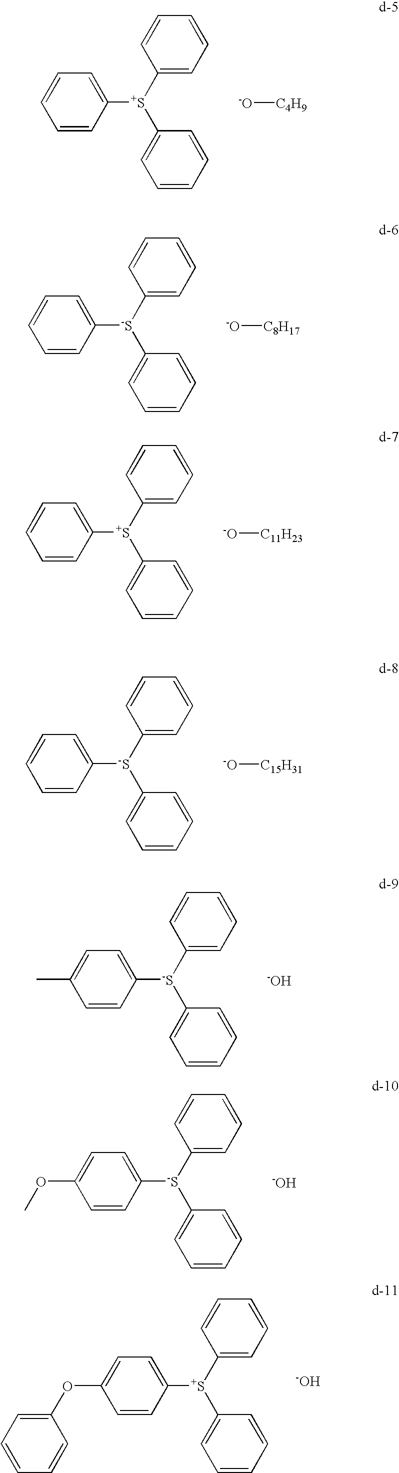

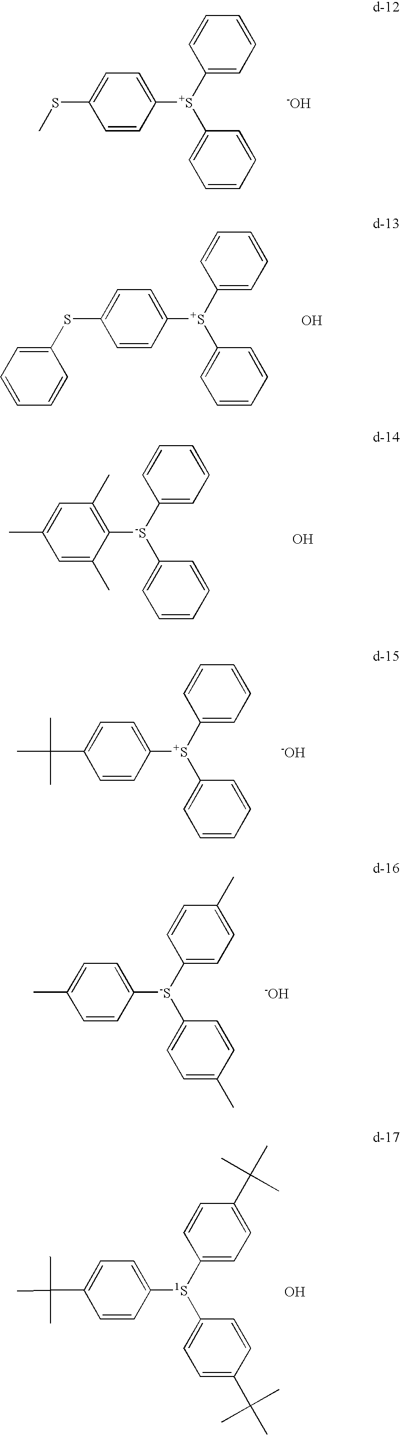

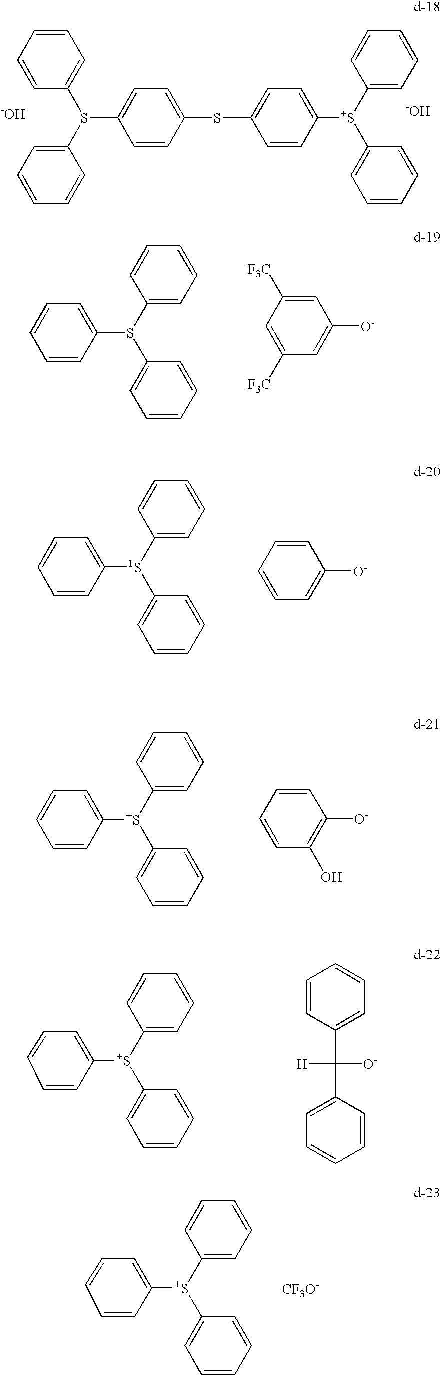

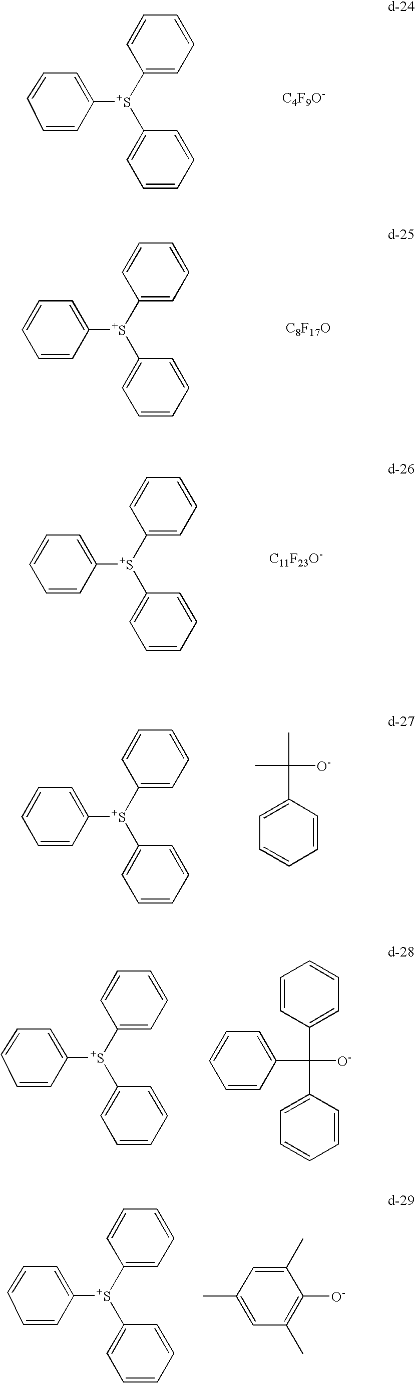

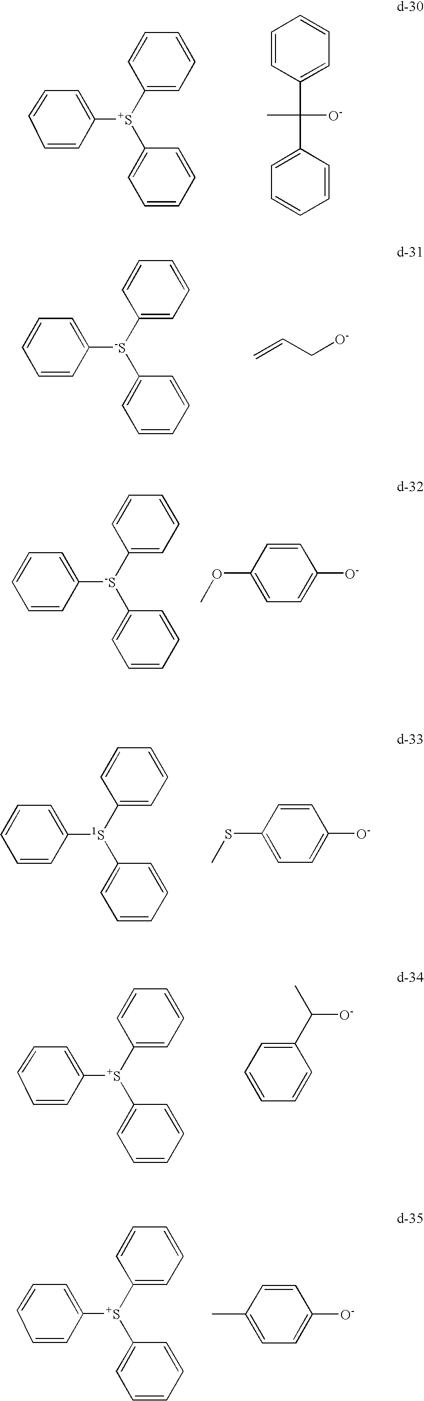

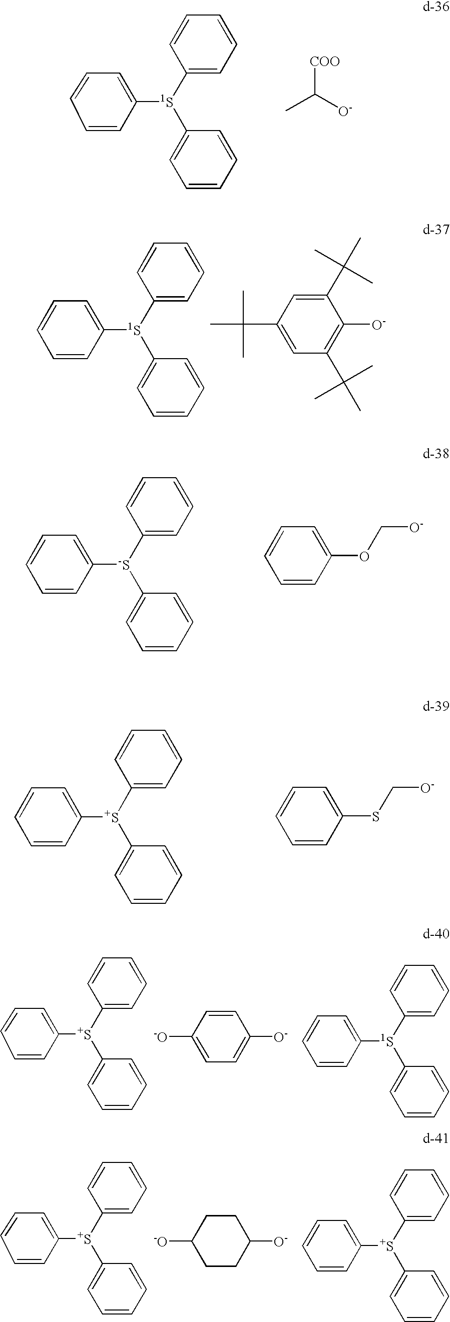

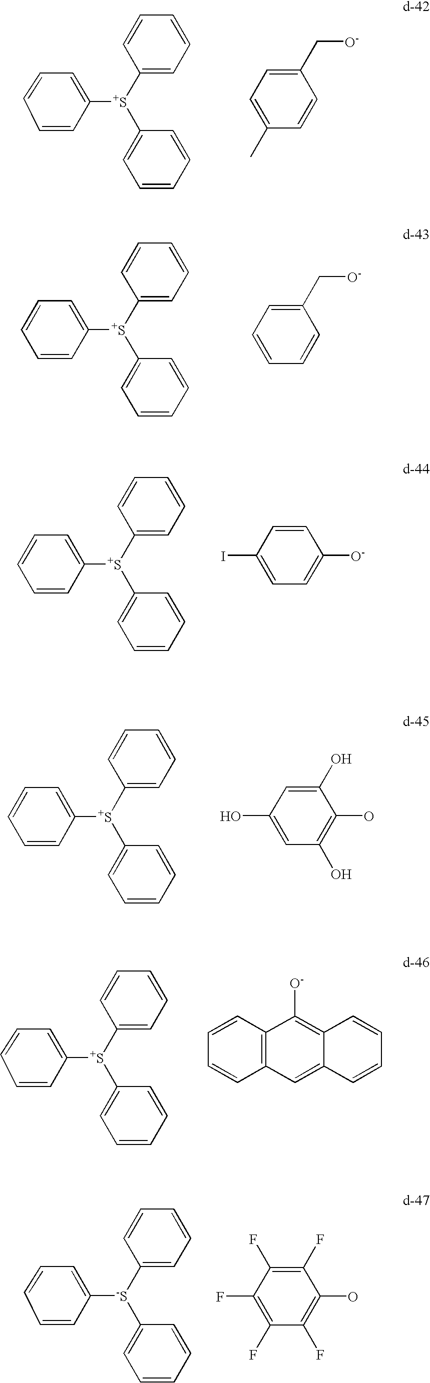

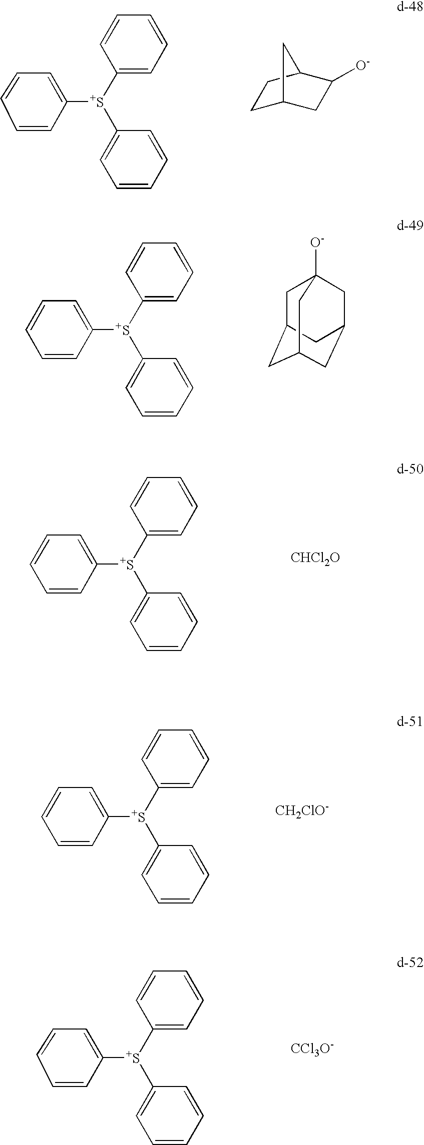

The content of the component (A) in the resist composition is preferably from 0.01 to 20% by weight, more preferably from 0.02 to 10% by weight, even more preferably from 0.3 to 5% by weight based on the solid content of the composition.

[2] Compound (B)

The compound (B) of the invention is a compound capable of reacting with the active seed generated from the compound (A) and/or performing electron transfer to generate an active seed different from the active seed generated from the compound (A). This reaction essentially indicates a redox reaction. Examples of this reaction will be given below.

In the case where the active seed generated from (A) is a radical, the aforementioned radical withdraws a hydrogen atom from the compound (B) and generates a new radical in the compound (B). During this process, the compound (A) is converted to a neutral compound. The aforementioned reaction is not limited to this mode of reaction. The hydrogen atom to be withdrawn may be replaced by another organic group.

The radical generated from (A), if it is reducing, can release an electron and gives it to the compound (B). This is an example of electron transfer. It is preferred that the compound (B) which has been monoelectronically reduced decompose to generate a new active seed such as radical. In this case, the aforementioned reaction is a reduction reaction of the compound (B). However, it may be an oxidation reaction of the compound (B).

In addition, the term “compound capable of generating an active seed different from the active seed generated from (A)” as used herein is meant to indicate a compound capable of generating an active seed that reacts with (C) and/or perform electron transfer. A compound capable of generating a reducing radical can be used.

Examples of partial structure of reducing radical will be given below.

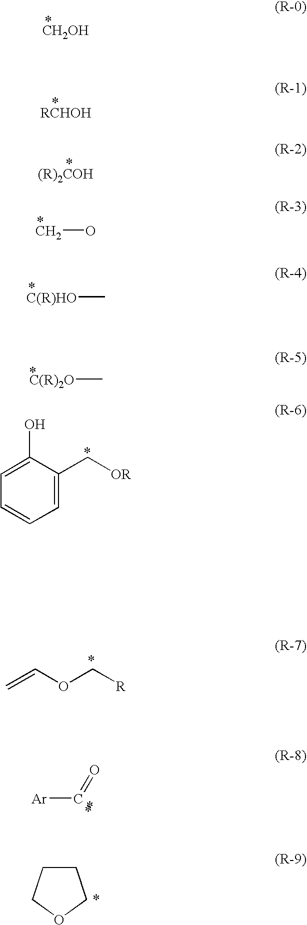

In the foregoing formulae, R represents an alkyl group. When there are two or more R's, they may be bonded to each other to form a ring. Ar represents an aryl group.

In the foregoing formulae, Epa of reducing radical of (R-0), (R-1), (R-3), (R-6), (R-7) and (R-9) are as follows.

(R-0): −0.98 V, (R-1): −1.20 V, (R-3): −1.30 V, (R-6): −1.10 V, (R-7): −0.80 V, (R-9): −1.05 V

Specific preferred examples of (B) include secondary alcohol compounds, alicyclic secondary alcohol compounds, cyclic ether compounds, vinyl ether compounds, and phenol derivatives containing hydroxymethyl group and alkoxymethyl group in its molecule.

Particularly, the negative-working resist composition of the invention comprises a crosslinking agent capable of carrying out addition reaction with an alkali-soluble resin by the action of an acid (hereinafter occasionally referred to as “crosslinking agent”) together with the alkali-soluble resin. Known crosslinking agents can be used in the invention.

Preferred examples of the crosslinking agents employable herein include compounds or resins having two or more hydroxymethyl groups, alkoxymethyl groups, acyloxymethyl groups or alkoxymethylether groups, and epoxy compounds.

More preferably, alkoxymethylated or acyloxymethylated melamine compounds or resins, alkoxymethylated or acyloxymethylated urea compounds or resins, hydroxymethylated or alkoxymethylated phenol compounds or resins, and alkoxymethyletherified phenol compounds or resins are used.

Further preferred examples of compound (B) include phenol derivatives having a molecular weight of not greater than 1,200 containing from 3 to 5 benzene rings and two or more hydroxymethyl or alkoxymethyl groups in total per molecule wherein the hydroxymethyl or alkoxymethyl groups are bonded concentratedly to at least any of the benzene rings or bonded dispersedly to the benzene rings. The use of such a phenol derivative makes it possible to remarkably exert the effect of the invention.

The alkoxymethyl group to be bonded to the benzene ring preferably has not greater than 6 carbon atoms. Specific preferred examples of such an alkoxymethyl group include methoxymethyl group, ethoxymethyl group, n-propoxymethl group, i-propoxymethyl group, n-butoxymethyl group, i-butoxymethyl group, sec-butoxymethyl group, and t-butoxymethyl group. Further preferred examples of the alkoxymethyl group include alkoxy-substituted alkoxy groups such as 2-methoxyethoxy group and 2-methoxy-1-propyl group.

Particularly preferred among these phenol derivatives are the following compounds.

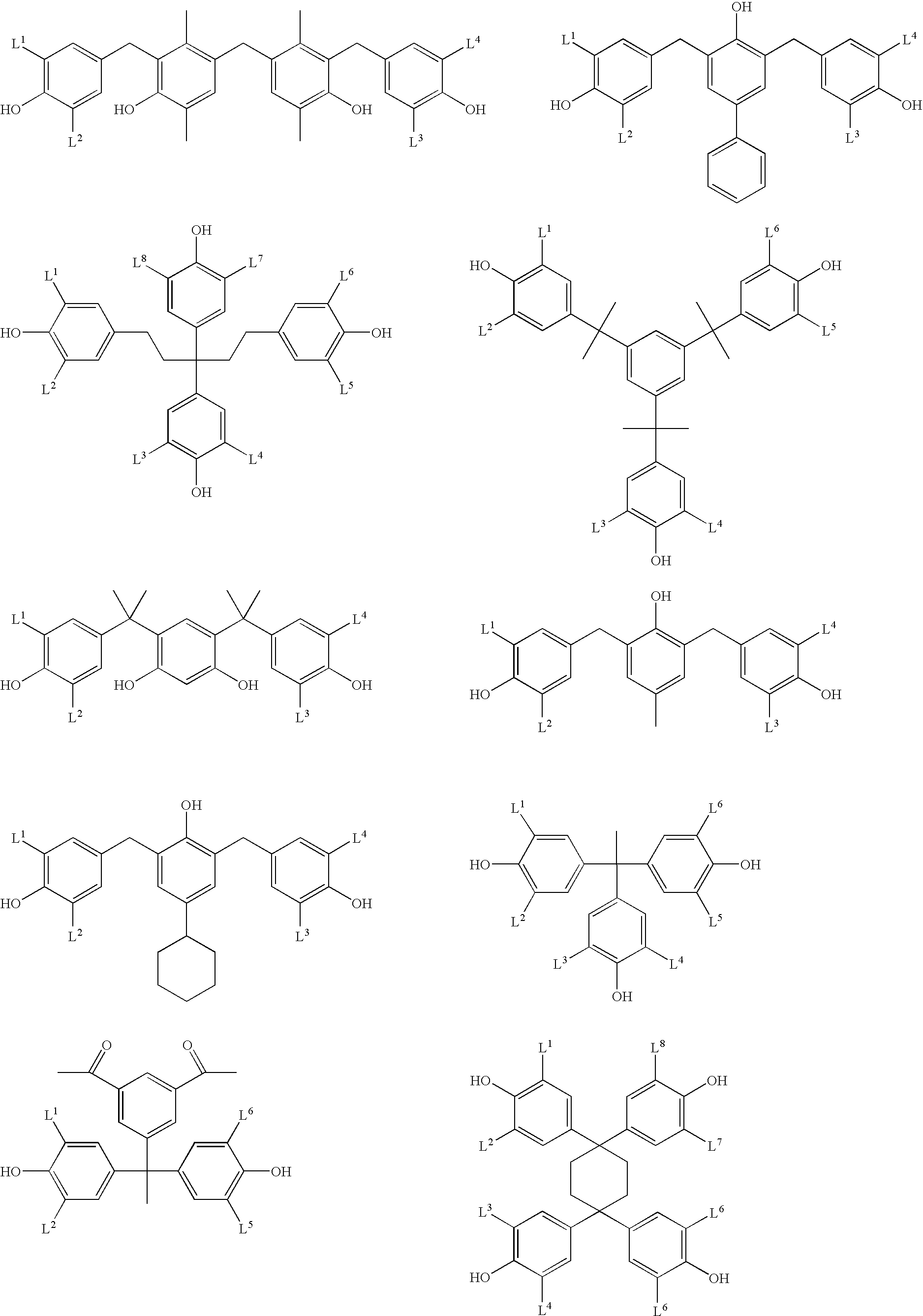

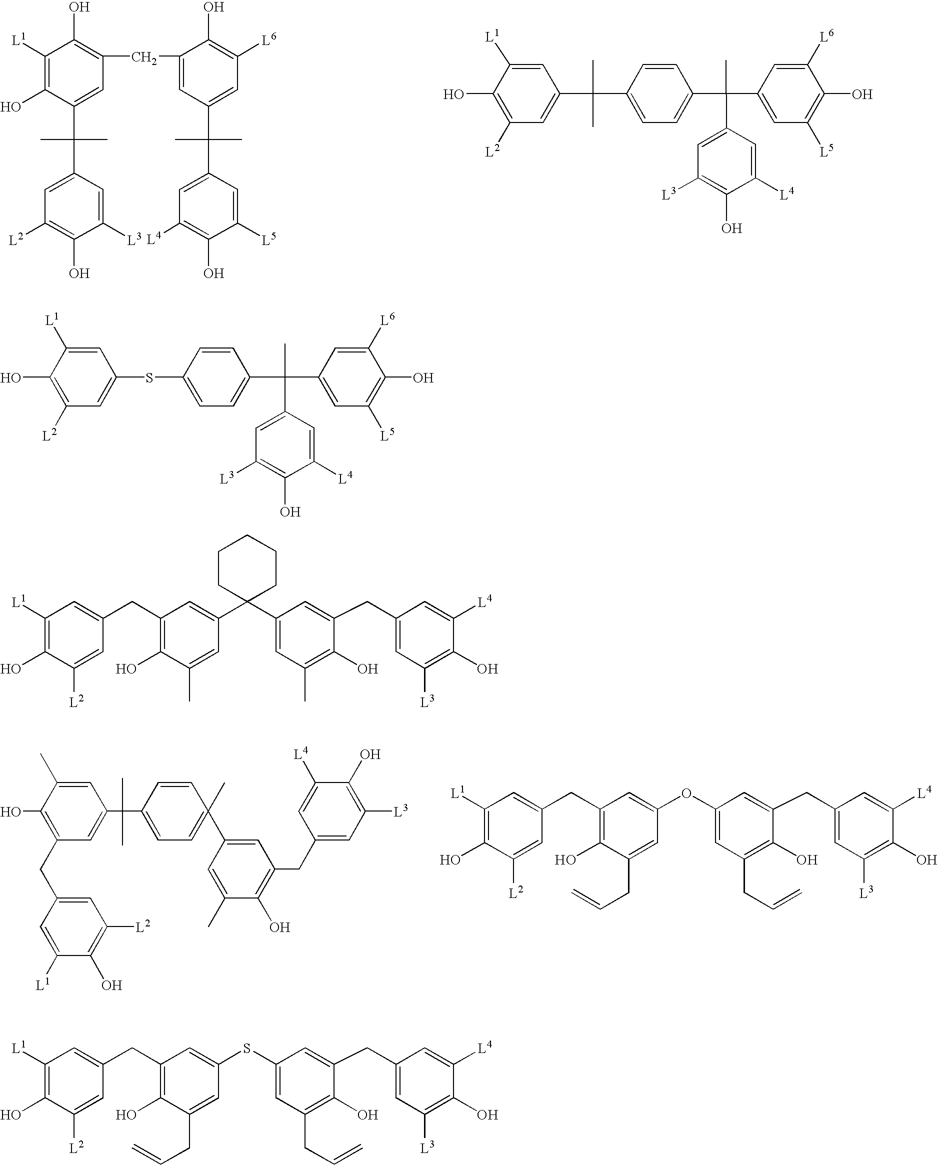

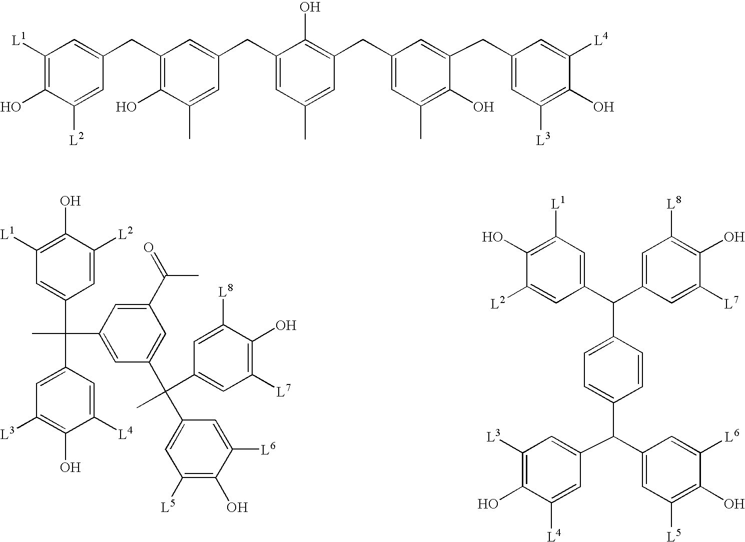

In the formulae, L¹ to L⁸ may be the same or different and each represents a hydroxymethyl group, a methoxymethyl group or an ethoxymethyl group.

The phenol derivative containing hydroxymethyl group can be obtained by reacting a corresponding phenol compound free of hydroxymethyl group (compound of the aforementioned formula wherein L¹ to L⁸ each represents a hydrogen atom) with formaldehyde in the presence of a basic catalyst. This reaction may be effected at a temperature of not higher than 60° C. to inhibit resinification or gelation. In some detail, synthesis may be carried out by any method as disclosed in JP-A-6-282067 and JP-A-7-64285.

The phenol derivative containing alkoxymethyl group can be obtained by reacting a corresponding phenol derivative having a hydroxymethyl group with an alcohol in the presence of an acid catalyst. This reaction may be effected at a temperature of not higher than 100° C. to inhibit resinification or gelation. In some detail, synthesis may be carried out by any method as disclosed-in European Patent EP 632003 A1.

The phenol derivative containing hydroxymethyl group or alkoxymethyl group thus synthesized is preferred from the standpoint of stability during storage. The phenol derivative containing alkoxymethyl group is particularly preferred from the standpoint of stability during storage.

These phenol derivatives having two or more hydroxymethyl or alkoxymethyl groups in total wherein these hydroxymethyl or alkoxymethyl groups are bonded concentratedly to any of these hydroxymethyl or alkoxymethyl groups or bonded dispersedly to these hydroxymethyl or alkoxymethyl groups may be used singly or in combination of two or more thereof.

The compound (B) is used in an amount of from 3 to 65% by weight, preferably from 5 to 50% by weight based on the total solid content in the resist composition. When the amount of the crosslinking agent to be incorporated falls below 3% by weight, the percent film retention is reduced. On the contrary, when the amount of the crosslinking agent to be incorporated exceeds65% by weight, the resulting resist composition exhibits a deteriorated resolution. This is not too advantageous from the standpoint of stability during storage.

The most desirable example of the compound (B) in the invention is a phenol derivative having any of the following structures.

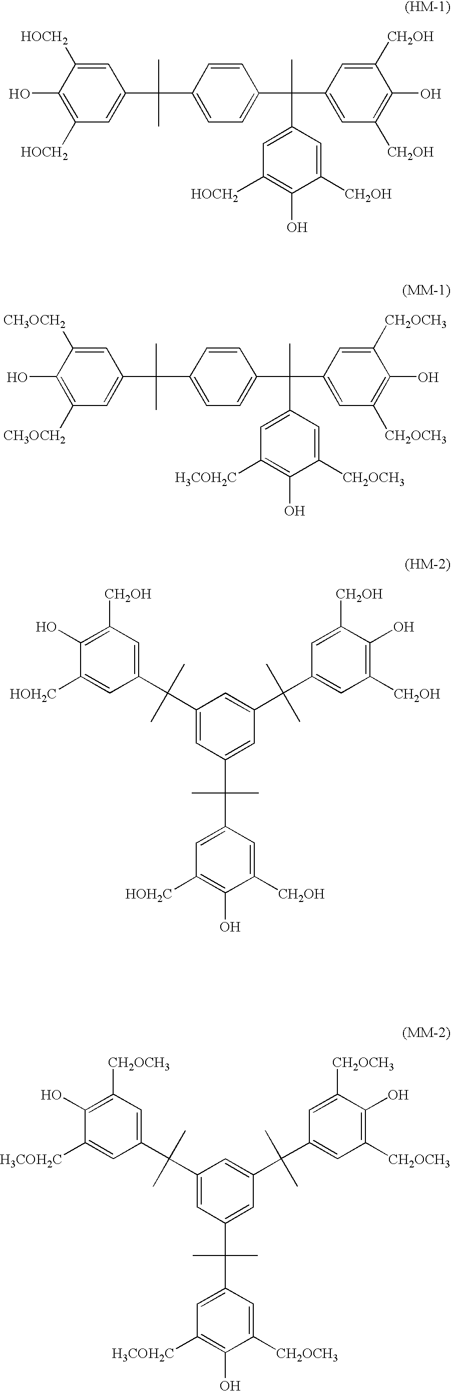

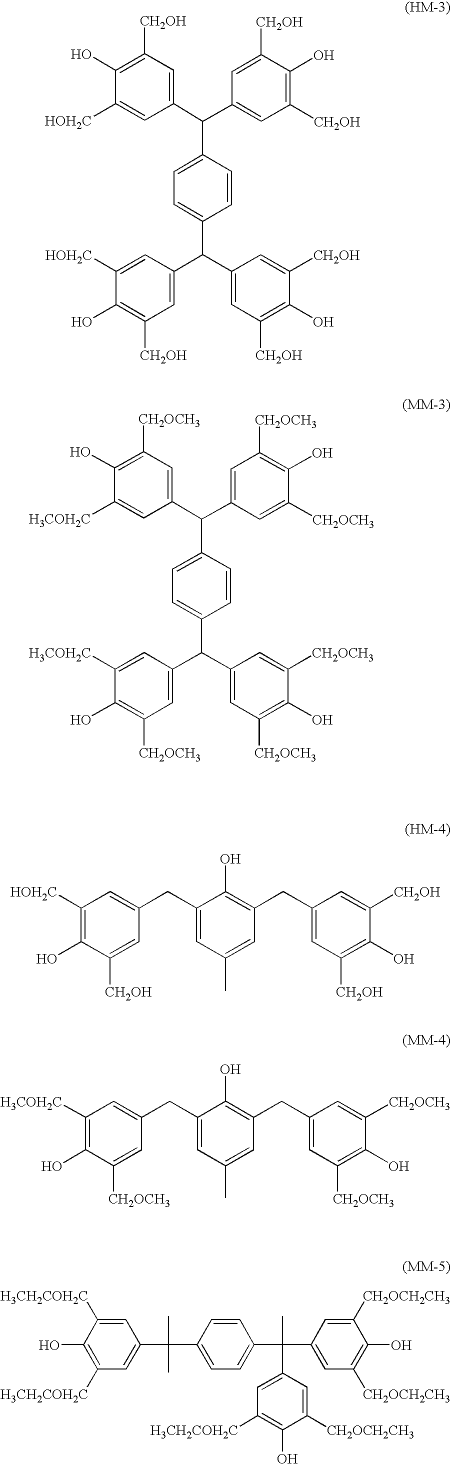

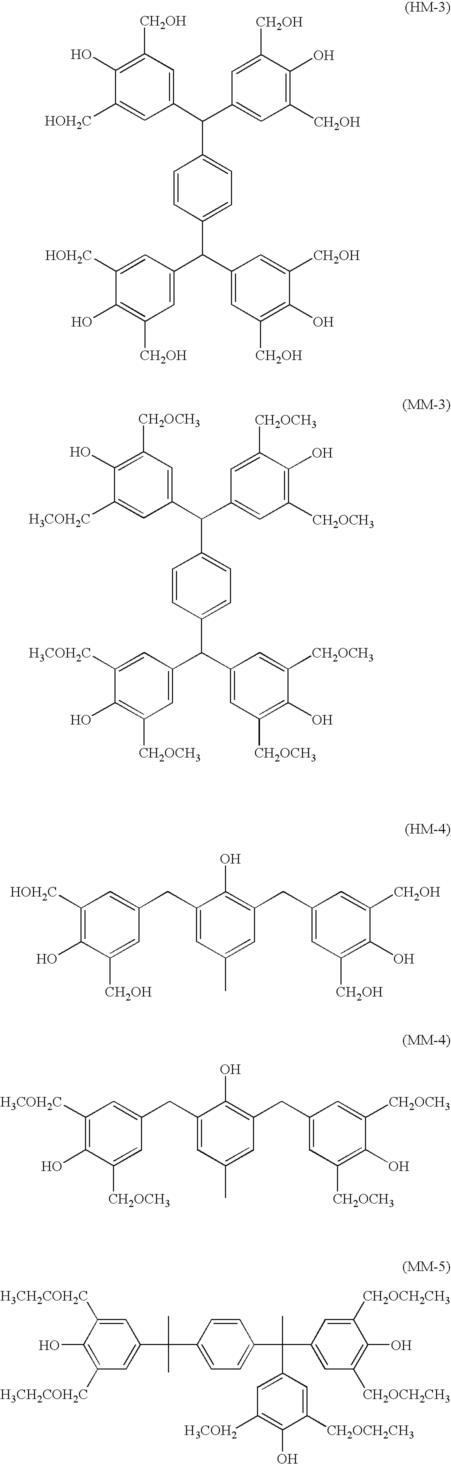

Besides the foregoing phenol derivative, a compound having a structure represented by the following formula (b), can be used as the compound (B).

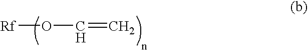

In the formula (b), Rf represents a substituted or unsubstituted aryl group, substituted or unsubstituted straight-chain, branched or alicyclic hydrocarbon group or combination thereof and may have a carbonyl group, an oxygen atom or a sulfur atom interposed between the elements thereof, and n represents an integer of from 1 to 10.

The aryl group represented by Ra is preferably a C₆-C₁₆ aryl group such as phenyl group, naphthyl group, anthranyl group, phenanthrenyl group and pyrenyl group.

Examples of the substituents on the aryl group include a fluorine atom, a chlorine atom, a bromine atom, an iodine atom, C₁-C₅ straight-chain and branched alkyl group, C₁-C₃ straight-chain or branched fluorine-substituted alkyl group, hydroxyl group, thiol group, C₁-C₅ alkyloxy group, nitro group and cyano group.

The straight-chain, branched or alicyclic hydrocarbon group is preferably a C₁-C₈ straight-chain, branched or alicyclic hydrocarbon group such as methyl group, ethyl group, propyl group, isopropyl group, butyl group, isobutyl group, t-butyl group, pentyl group, neopentyl group, hexyl group, heptyl group, octyl group, nonyl group, lauryl group, cyclopropyl group, cyclopentyl group, cyclohexyl group, norbornyl group and adamanthyl group.

Examples of the substituents on the straight-chain and branched hydrocarbon group include fluorine atom, chlorine atom, bromine atom, iodine atom, hydroxyl group, C₁-C₅ alkyloxy group, thiol group, cyano group, nitro group, vinyl group, vinylether group, amide group, phenyl group, naphthyl group, anthranyl group, cyclohexyl group and norbornyl group.

Examples of the substituents on the alicyclic hydrocarbon group include fluorine atom, chlorine atom, bromine atom, iodine atom, hydroxyl group, thiol group, methyl group, ethyl group, propyl group, isopropyl group, butyl group, isobutyl group and t-butyl group.

This compound (B) is preferably incorporated in a positive-working resist composition.

Specific examples of the compound (B) represented by the formula (b) will be given below, but the invention is not limited thereto.

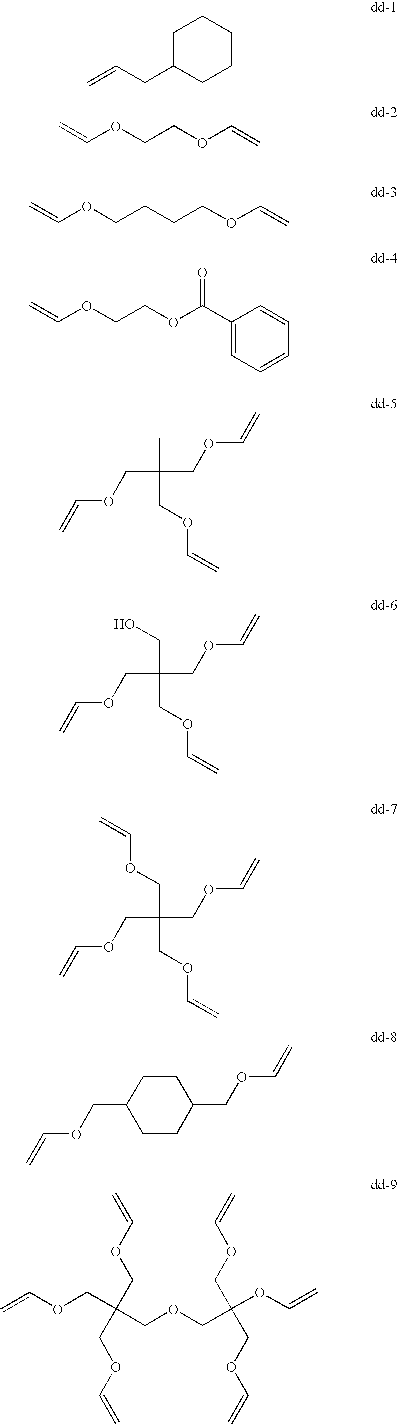

The compound (B) is also preferably a cyclic ether compound.

The cyclic ether compound preferably has a boiling point of not lower than 100° C., more preferably not lower than 120° C. at room temperature and atmospheric pressure.

Specific examples of the cyclic ether compound will be given below, but the invention is not limited thereto.

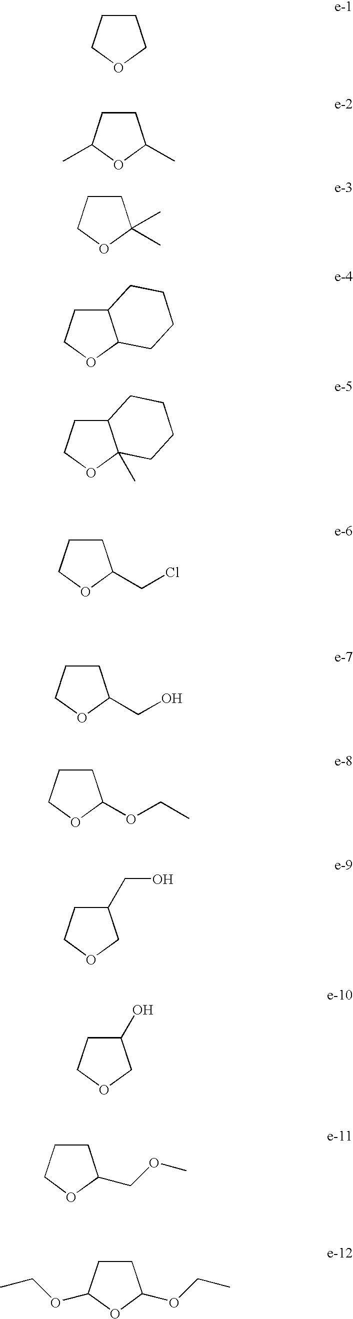

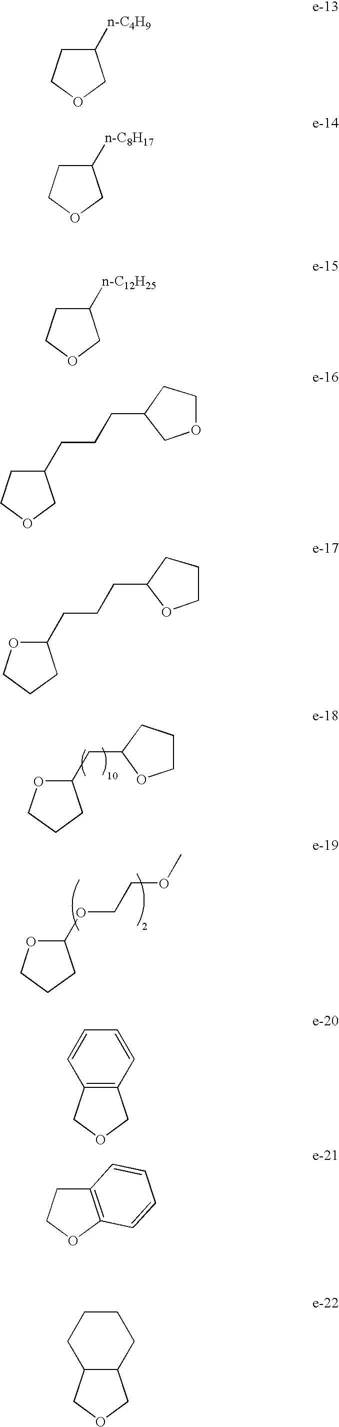

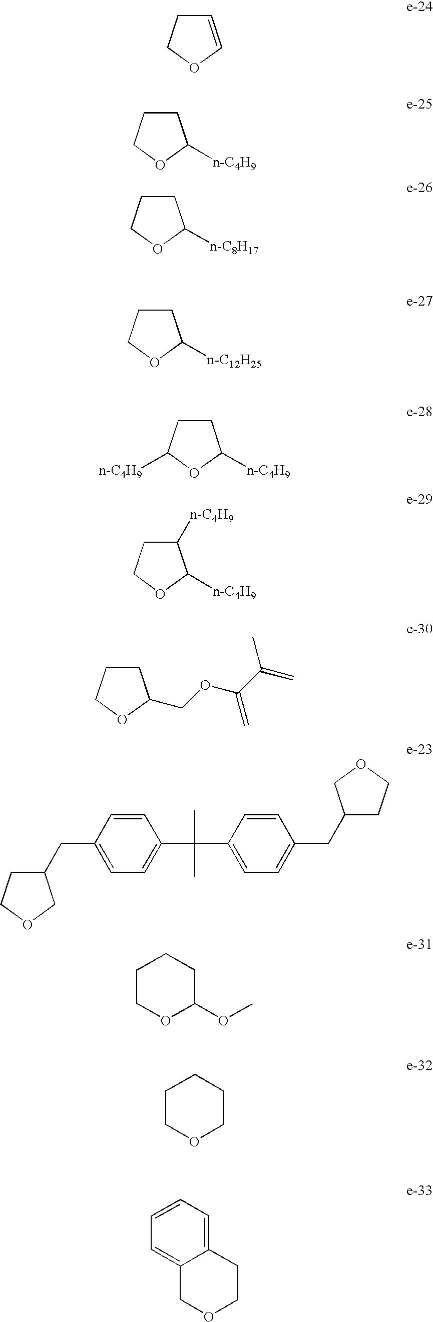

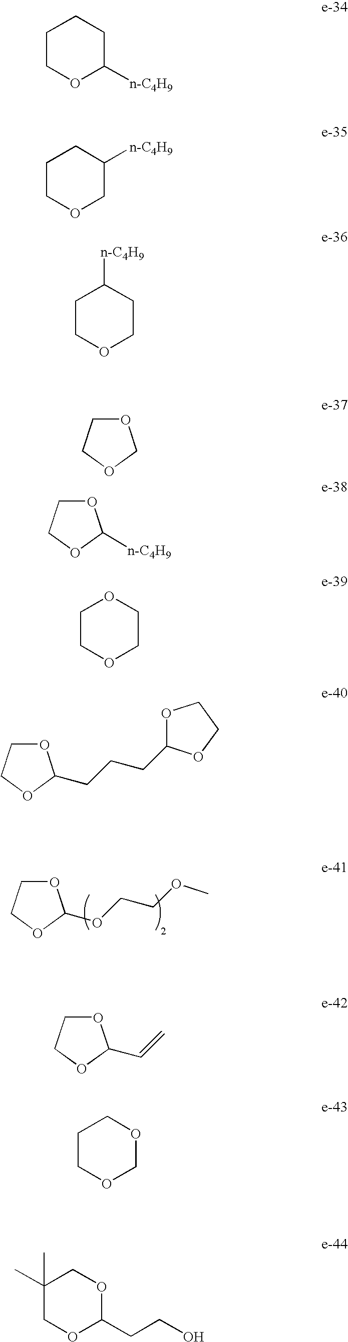

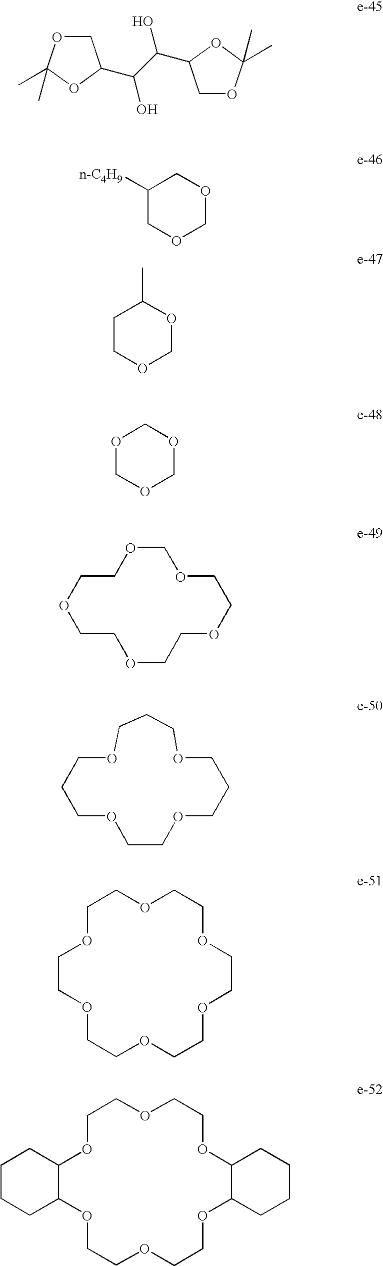

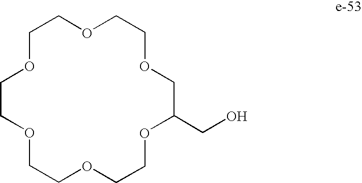

Compound (C)

The compound (C) of the invention is a compound capable of performing electron transfer from the active seed generated from (B) to generate an acid. The invention has a requirement that Eₚₐ (½ wave of oxidation potential) of active seed generated from (B) and E_{pc} (½ wave of reduction potential) of (C) satisfy the relationship (D): E_{pc}−Eₚₐ>0. In particular, it is preferred that E_{pc} of (C) be higher than −1.15 V.

In order to determine the oxidation potential, sweeping is initiated such that the potential rises toward positive side (ex. ±0V→+2.0 V). When oxidation occurs, an oxidation wave is measured. In general, the measurements of oxidation and reduction potentials are plotted with potential as abscissa and electric current flowing through electrode as ordinate. In other words, oxidation wave means a waveform having a peak (top) swinging above a base line showing a state of no current flowing. This waveform is represented by ½ wave of oxidation potential. The potential of the peak (top) of waveform is represented by Eₚₐ.

This can apply to reduction potential. Sweeping is initiated such that the potential rises toward negative side (ex. 0V→−2.0 V). When reduction occurs, a reduction wave is measured. The waveform having a peak (top) swinging above a base line showing a state of no current flowing is represented by ½ wave of reduction potential. The potential of the peak (top) of waveform is represented by E_{pc}.

In order to cause electron transfer between donor (hereinafter abbreviated as “D”) and acceptor (hereinafter abbreviated as “A”), it is necessary that the relationship ΔGₑₗ<0 be satisfied in Rehm-Weller's equation shown below.

ΔGₑₗ(kcal/mol⁻¹)=23.06[E⁰(D⁺/D)−E⁰(A/A⁻)]−wₚ

ΔGₑₗ: Change of free energy of electron transfer reaction E⁰(D⁺/D): Oxidation potential at which donor is monoelectrically oxidized

E⁰(A/D⁻): Reduction potential at which acceptor is monoelectrically reduced

wₚ: Work done by attraction caused by electrostatic interaction between two ions

The symbol wₚ represents work done by attraction caused by electrostatic interaction between two ions but has a small contribution to ΔGₑₗ. Therefore, ΔGₑₗ<0 may be approximated to [E⁰(D⁺/D)−E⁰(A/A⁻)]<0. E⁰(D⁺/D) represents the oxidation potential at which a donor is monoelectrically oxidized and corresponds to Eₚₐ. E⁰(A/A⁻) represents the reduction potential at which an acceptor is monoelectrically reduced and corresponds to E_{pc}. In other words, in order to cause electron transfer between donor and acceptor, it is necessary that the relationship Eₚₐ−E_{pc}<0 (same as E_{pc}−Eₚₐ>0) be satisfied. For the details of the aforementioned equation, reference can be made to George J. Kavarmos, “Hikari Denshi Ido (Photo-electron transfer)”, Chapter 1.6.

The invention features acid multiplication utilizing the mechanism that the satisfaction of the aforementioned equation allows the active seed generated from the compound (B), mainly a radical-containing compound, to act as a donor that performs electron transfer to the compound (C), which is an acceptor.

The compound (C) to be used in the invention preferably has E_{pc} (½ wave of reduction potential) of higher than −1.15 V (E/V vs Ag/AgCl in acetonitrile). Epc of −1.15 V is a measure of oxidation potential of highly reducing radical seed generated from (B). Specific examples of the radical-containing compound having an oxidation potential of lower than −1.15 V include the aforementioned compounds (R-2) to (R-7). These compounds are considered to have a high reducing power. On the other hand, an example of the radical-containing compound having an oxidation potential of higher than −1.15 V is (R-0). In the case where the oxidation potential of the radical seed generated from (B) is higher than −1.15 V, it can be easily presumed that the corresponding radical seed is stable and thus can difficultly perform electron transfer to the acceptor.

In the invention, as the compound which is the component (C) that performs electron transfer from the active seed generated from the compound (B) to generate an acid there is preferably used a sulfonium salt.

E_{pc} and Eₚₐ in the invention are measured by the following methods.

A measuring instrument having an arbitrary function generator, a potentiostat and a measuring vessel connected thereto was used. A solution of 0.1 M n-Bu₄N.ClO₄ (electrolyte for polarography produced by Nakai Co., Ltd.) as a supporting electrolyte in acetonitrile (produced by Kanto Kagaku) as a measuring solvent was charged in the measuring vessel. As a work electrode there was used a Pt electrode. As a reference electrode there was used Ag/AgCl (saturated KCl). As a salt bridge for connecting the reference electrode to the measuring vessel there was used a tube filled with agar-agar containing 1M KNO₃ as a supporting salt. Under these conditions, a sample was dissolved in a concentration of 1×10⁻⁴ M in the measuring vessel. Measurement was then conducted at 25° C. and a sweeping rate of from 50 mV/cm² to 1 V/cm².

For supplementation, the experiment and measurement on Eₚₐ of the compound (B) can be carried out by the method described in Ber. Bunsenges., “Phys. Chem.”, 75, 458 (1971). For further supplementation, reference can be made to “J. Chem. Phys.”, 44, 2297 (1966), “Radiant. Phys. Chem.”, 15, 603 (1980), etc.

In the case where measurement was conducted under the aforementioned conditions, ferrocene (Fe(CSHS)₂/[Fe (C₅H₅)₂]+), which is a reference compound, showed Epa of +0.52 V and Epc of +0.30 V.

Preferred examples of the compound (C) employable herein include acid generators having structures represented by the following formulae (3) and (4) and (5).

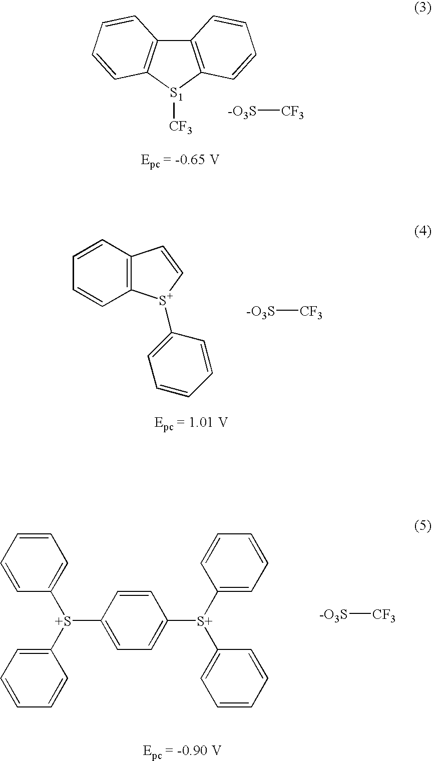

The term “E_{pc} is on the positive side” as used herein is meant to indicate “E_{pc}−Eₚₐ>0”. For example, in the formula (3), the relationship E_{pc}−Eₚₐ>0 means−0.65−(−1.15)>0, which satisfies the aforementioned requirements.

Specific examples of the compound (C) will be given below, but the invention is not limited thereto.

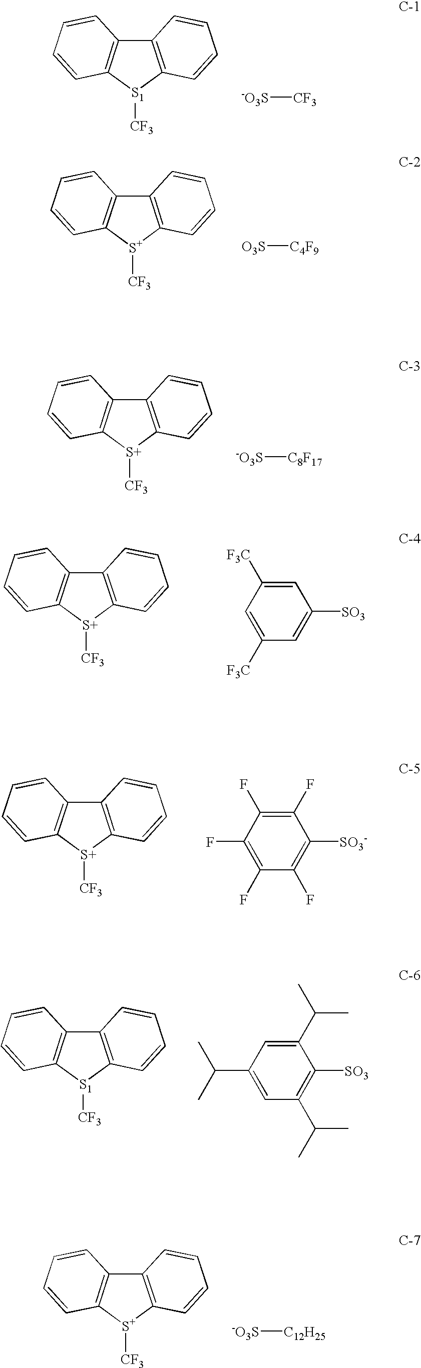

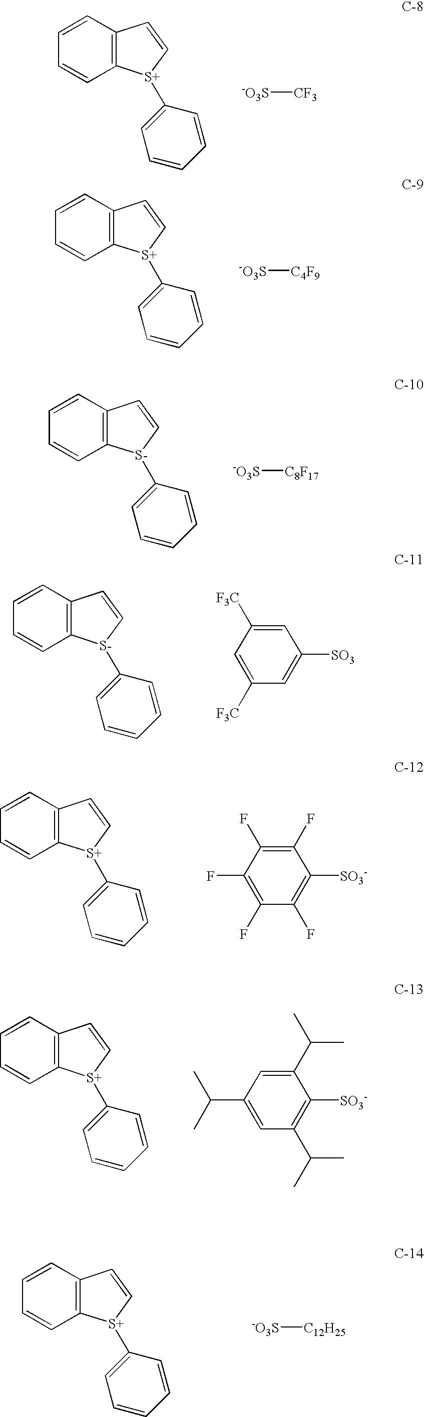

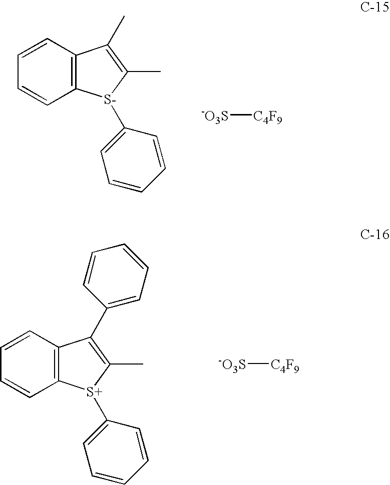

In the resist composition of the invention, a compound having a partial structure represented by the formula (VIII) and a counter ion capable of generating an acid upon irradiation with one of an actinic ray and a radiation (hereinafter occasionally referred to as “acid generator”) can be preferably used.

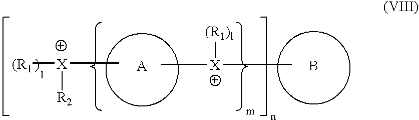

In the formula (VIII), X represents a sulfur atom or an iodine atom. The plurality of X's may be the same or different. R₁ and R₂ each independently represents an alkyl or aryl group. When there are a plurality of R₁'s, the plurality of R₁'s may be the same or different. When there are a plurality of R₂'s, the plurality of R₂'s may be the same or different. R₁ and R₂, R₁ and A, R₁ and B, R₂ and A, and R₂ and B may be bonded to each other to form a ring.

A and B each independently represents a hydrocarbon structure connecting between X⁺'s, with the proviso that at least one of connections of X⁺'s with A or B indicates a structure in which X⁺'s connected are in the same conjugation. When there are a plurality of A's, the plurality of A's may be the same or different. The suffix 1 represents 0 or 1, with the proviso that when X is a sulfur atom, the number 1 of R¹'s connected to X⁺ represents 1, and when X is an iodine atom, the number 1 of R¹'s connected to X⁺ represents 0.

The suffix m represents an integer of from 0 to 10. The suffix n represents an integer of from 1 to 6, with the proviso that when m is 0, n represents an integer of not smaller than 2.

The alkyl group represented by R₁ or R₂ is preferably a C₁-C₈ alkyl group. The alkyl group may be a straight-chain, branched or cyclic alkyl group. Examples of such an alkyl group include methyl group, ethyl group, propyl group, isopropyl group, butyl group, isobutyl group, t-butyl group, pentyl group, neopentyl group, hexyl group, heptyl group, octyl group, cyclopropyl group, cyclobutyl group, cyclopentyl group, cyclohexyl group, norbornyl group, and adamanthyl group.

The aryl group represented by R₁ or R₂ is preferably a C₆-C₁₆aryl group. Examples of such an aryl group include phenyl group, naphthyl group, anthranyl group, phenanthrenyl group, and pyrenyl group.

The hydrocarbon structure connecting between X⁺ of A and B is preferably a C₄-C₁₆ hydrocarbon structure having a conjugated bond comprising single bond and double or triple bond which may have oxygen and sulfur atoms. Specific preferred examples of such a hydrocarbon structure include hydrocarbon structures having benzene ring, naphthalene ring, thiophene ring, furane ring and the following conjugated bonds.

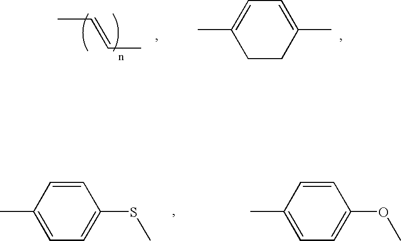

The alkyl group and aryl group represented by R₁ and R₂ and the hydrocarbon structures represented by A and B may or may not have substituents. Examples of the substituents which may be on the alkyl group and aryl group represented by R₁ and R₂ and the hydrocarbon structures represented by A and B include fluorine atom, chlorine atom, bromine atom, iodine atom, C₁-C₅ straight-chain or branched alkyl group, C₃-C₈ cyclic alkyl group, C₁-C₃ straight-chain or branched fluorine-substituted alkyl group, hydroxyl group, thiol group, C₁-C₅ alkyloxy group, nitro group, cyano group, formyl group, phenyl group, naphthyl group, phenylthio group, and phenoxy group.

In a partial structure represented by the formula (VIII), at least one of connections of X⁺'s with A or B indicates a structure in which X⁺'s connected are in the same conjugation.

Examples of the structure in which X⁺'s connected are in the same conjugation include the following structures.

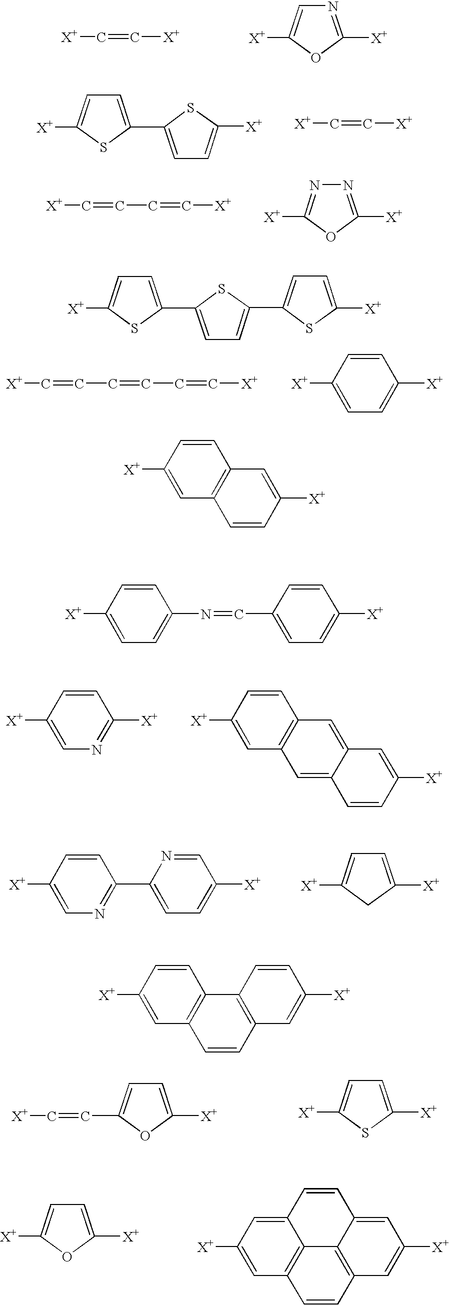

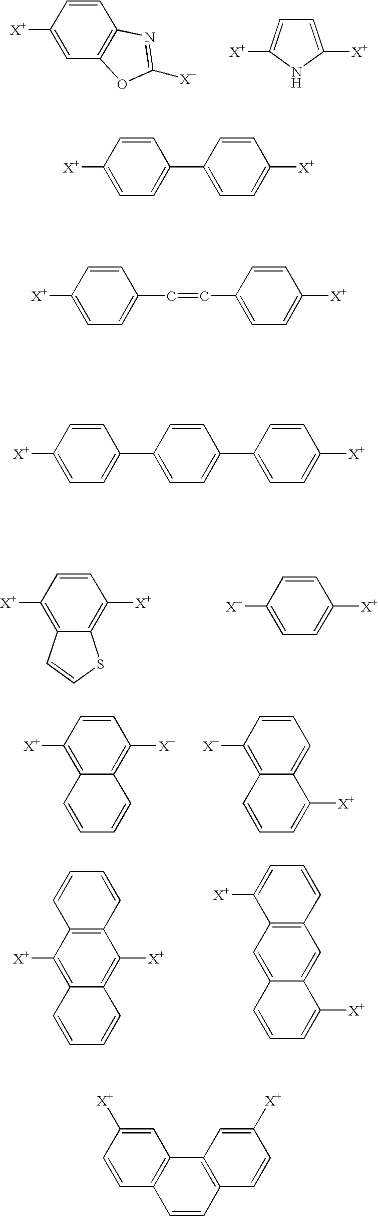

The compound having a partial structure represented by the formula (VIII) capable of generating an acid upon irradiation with one of an actinic ray and a radiation has counter ions besides the partial structure.

Examples of the counter ions include aliphatic sulfonate ions, aromatic sulfonate anions, aliphatic carboxylate anions, and aromatic carboxylate anions.

The aliphatic moiety in the aliphatic sulfonate anion and aliphatic carboxylate anion is preferably a C₁-C₃₀ aliphatic group such as methyl group, ethyl group, propyl group, isopropyl group, n-butyl group, isobutyl group, sec-butyl group, pentyl group, neopentyl group, hexyl group, heptyl group, octyl group, nonyl group, decyl group, undecyl group, dodecyl group, tridecyl group, tetradecyl group, pentadecyl group, hexadecyl group, heptadecyl group, octadecyl group, nonadecyl group, eicosil group, cyclopropyl group, cyclopentyl group, cyclohexyl group, adamanthyl group, norbornyl group, and boronyl group.

The aromatic moiety in the aromatic sulfonate anion and aromatic carboxylate anion is preferably a C₆-C₃₀ aromatic group such as phenyl group, tolyl group and naphthyl group.

The aforementioned aliphatic sulfonate anions, aromatic sulfonate anions, aliphatic carboxylate anions and aromatic carboxylate anions may or may not have substituents.

Examples of the substituents which may be on the aliphatic sulfonate anions, aromatic sulfonate anions, aliphatic carboxylate anions and aromatic carboxylate anions include halogen atom such as fluorine atom, alkyl group, alkoxy group, and alkylthio group.

The aliphatic sulfonate anions, aromatic sulfonate anions, aliphatic carboxylate anions and aromatic carboxylate anions preferably have fluorine atom as substituent.

In the partial structure represented by the formula (VIII), it is preferred that R₁ and R₂ each be an aryl group and A and B each be an aromatic ring. It is more desirable that R1 and R2 each be a phenyl group, B be a benzene ring, n be 2 and m be 0.

Specific examples of the compound having a partial structure represented by the formula (VIII) capable of generating an acid upon irradiation with one of an actinic ray and a radiation will be given below, but the invention is not limited thereto.

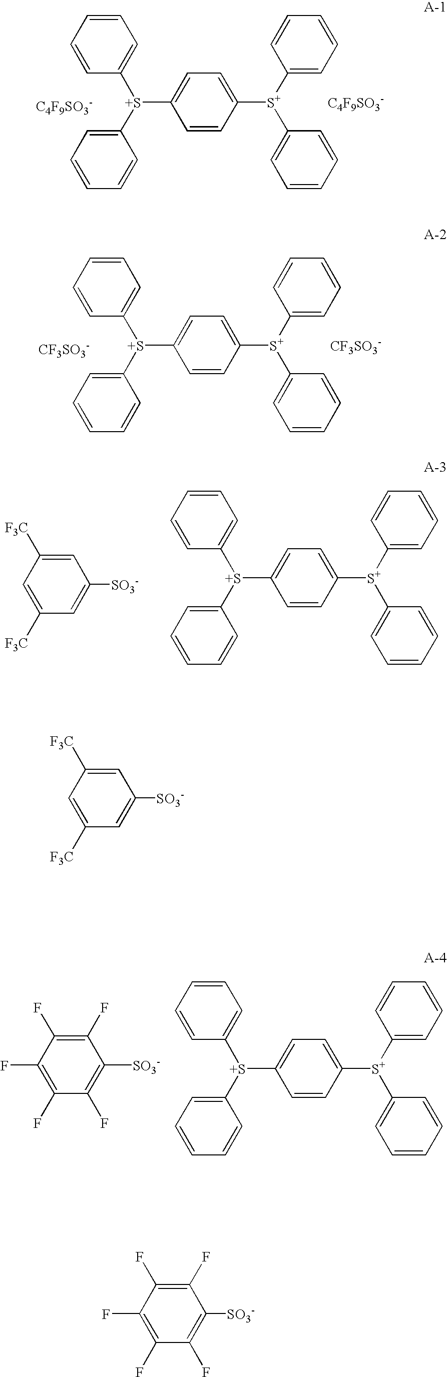

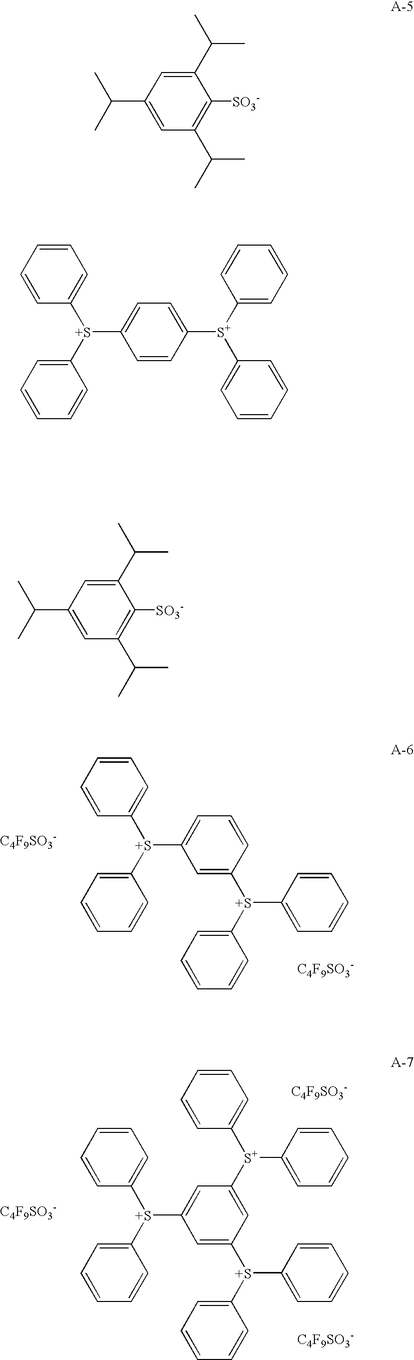

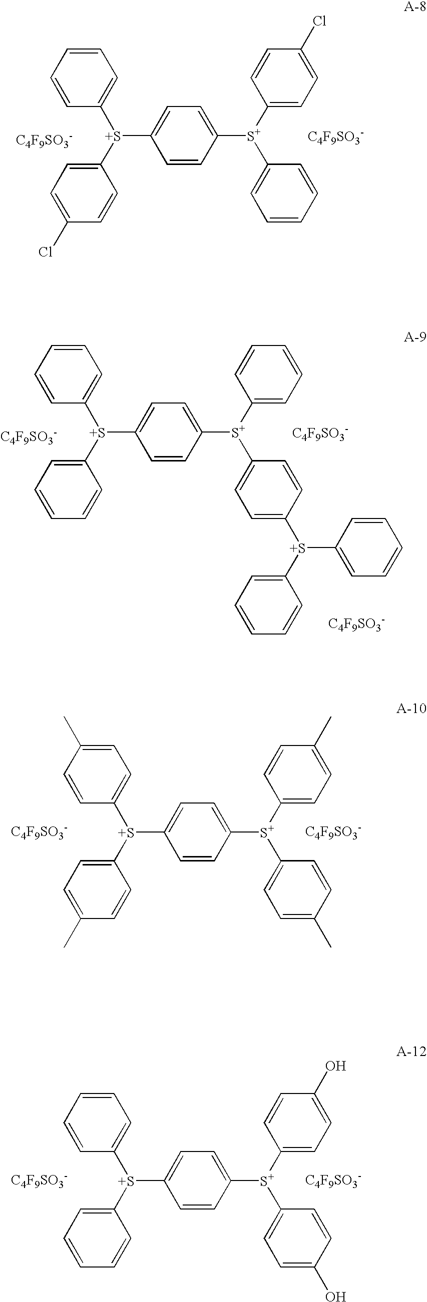

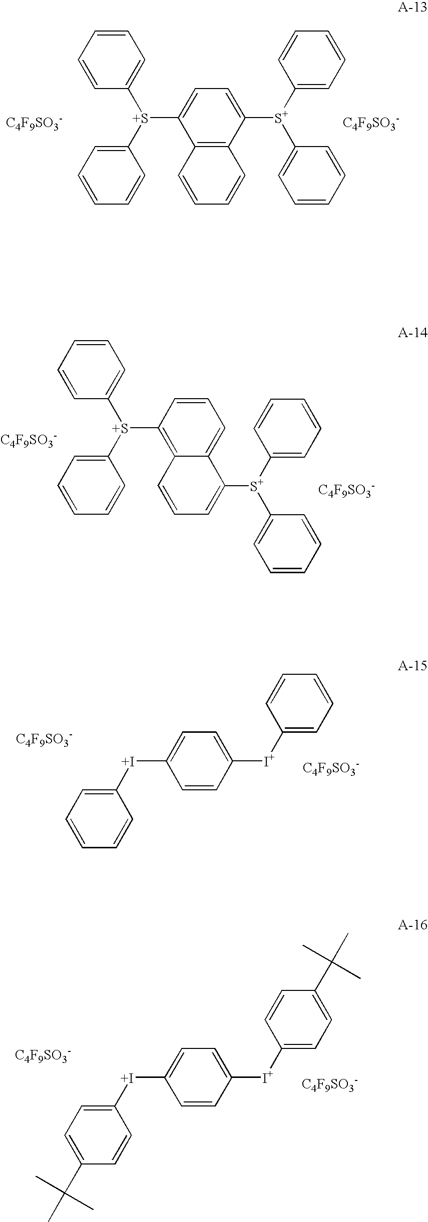

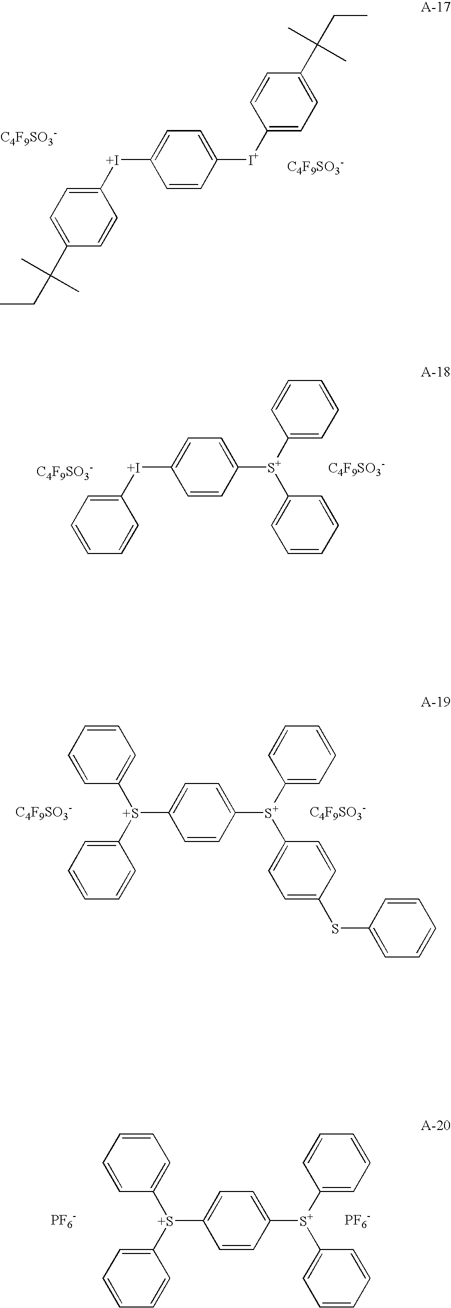

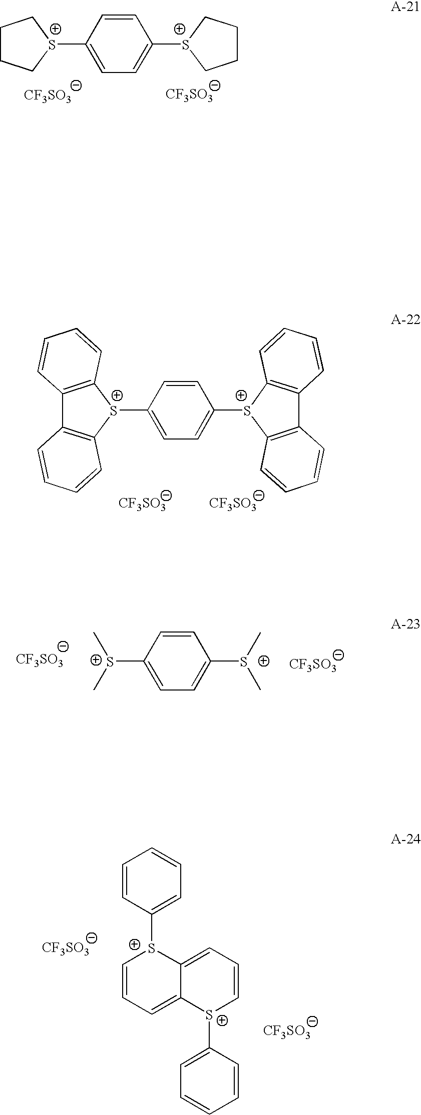

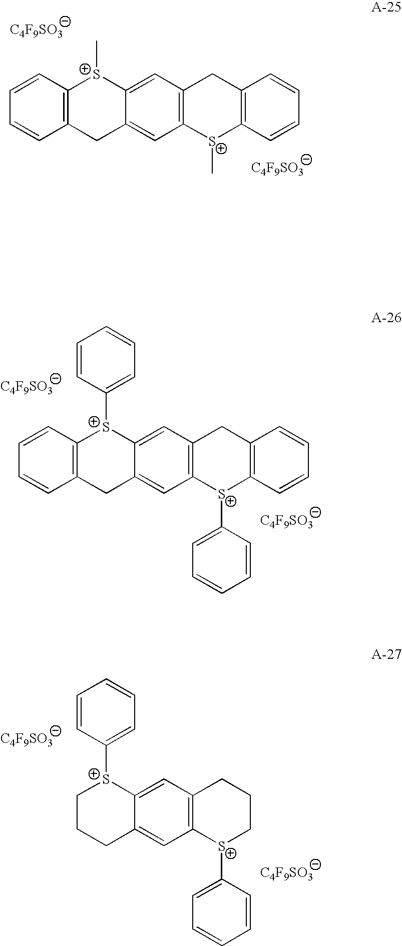

These acid generators (C) may be used singly or in combination of two or more thereof.

The content of the acid generator (C) in the resist composition is preferably from 0.1 to 20% by weight, more preferably from 0.2 to 15% by weight, even more preferably from 0.3to 15% by weight based on the solid content of the composition.

When the content of the acid generator (C) is not smaller than 0.3% by weight, the deterioration of sensitivity and resolution can be prevented. On the contrary, when the content of the acid generator (C) is not greater than 15% by weight, the occurrence of development defect can be eliminated.

Acid-generating compound usable besides the component (C)

In the invention, a compound capable of decomposing to generate an acid upon irradiation with one of an actinic ray and a radiation may be additionally used besides the component (C).

The amount of the photo-acid generator usable with the component (C) of the invention to be used is normally from 20/80 to 100/0, preferably from 40/60 to 100/0, more preferably from 50/50 to 100/0 as calculated in terms of molar ratio (component (C)/other acid-generator).

As other usable photo-generators there may be properly selected from the group consisting of photo-initiator for cationic photopplymerization, photo-initiator for radical photopolymerization, photodecoloring agent for dyes, photodiscoloring agent for dyes, known compound for microresist capable of generating an acid upon irradiation with one of an actinic ray and a radiation and mixture thereof.

Examples of these photo-generators include diazonium salts, phosphonium salts, sulfonium salts, imidosulfonates, oxymsulfonates, diazodisulfone, disulfone, and o-nitrobenzyl sulfonate.

Alternatively, compounds having in its polymer main chain or side chain these groups or compounds capable of generating an acid upon irradiation with one of an actinic ray and a radiation as disclosed in U.S. Pat. No. 3,849,137, German Patent 3914497, JP-A-63-26653, JP-A-55-164824, JP-A-62-59263, JP-A-63-146038, JP-A-63-163452, JP-A-62-153853and JP-A-63-146029may be used.

Further, compounds capable of generating an acid upon irradiation with light as disclosed in U.S. Pat. No. 3,779,778 and European Patent 126,712 may be used.

Particularly preferred examples of the compound capable of decomposing to generate an acid upon irradiation with one of an actinic ray and a radiation will be given below.

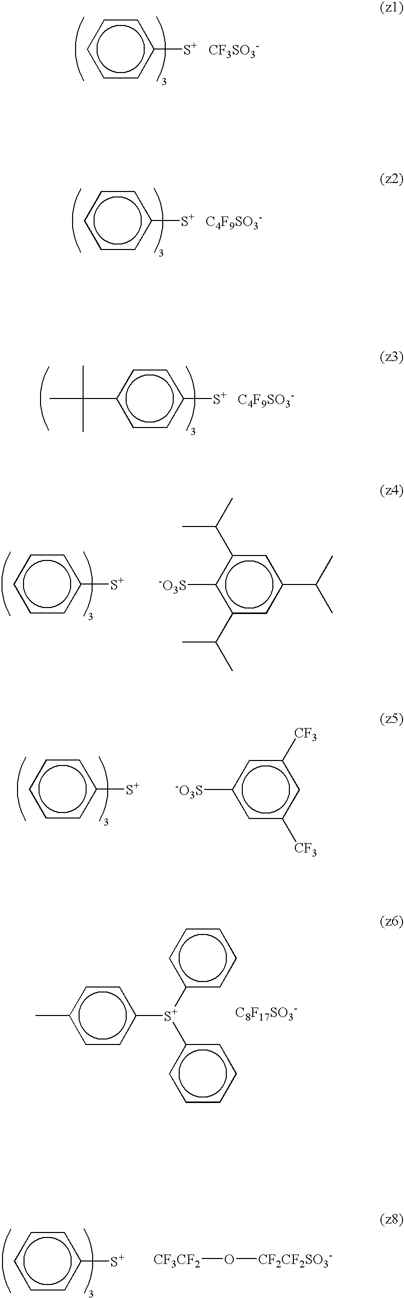

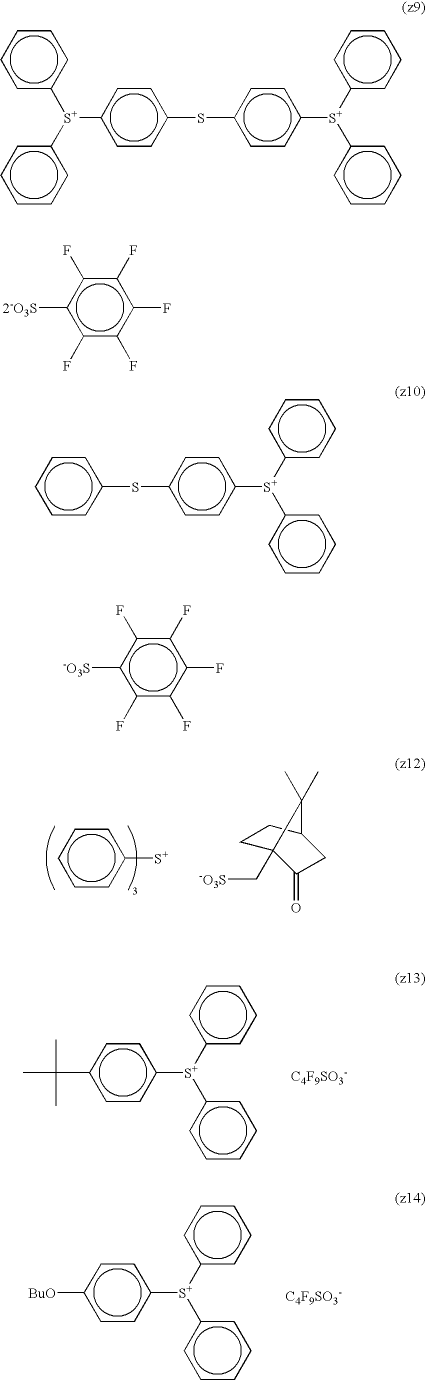

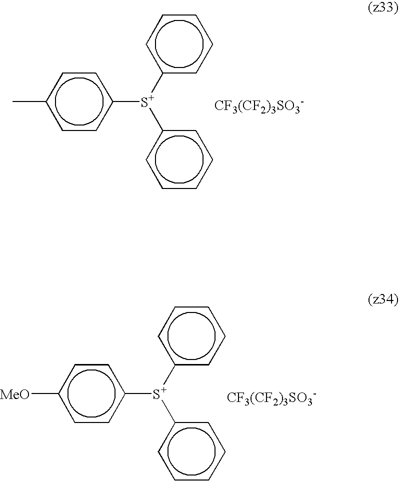

In the foregoing compounds, E_{pc} of z1 and z10 are −1.51 V and −1.40 V, respectively.

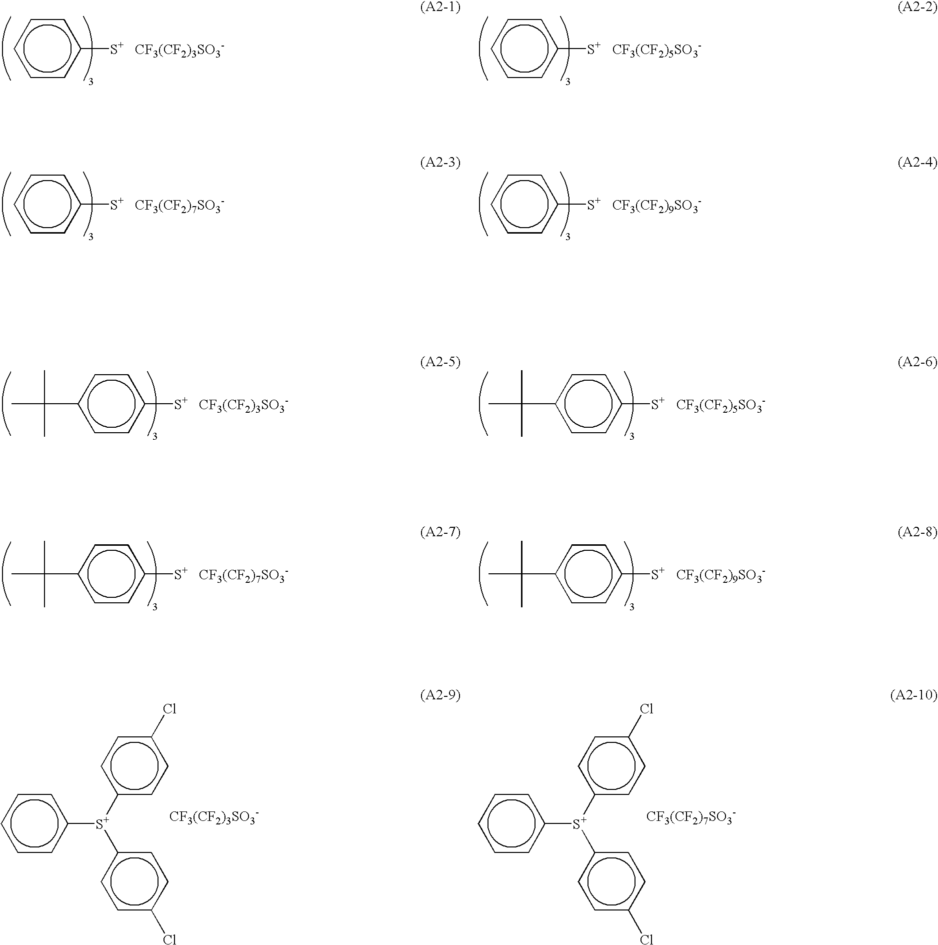

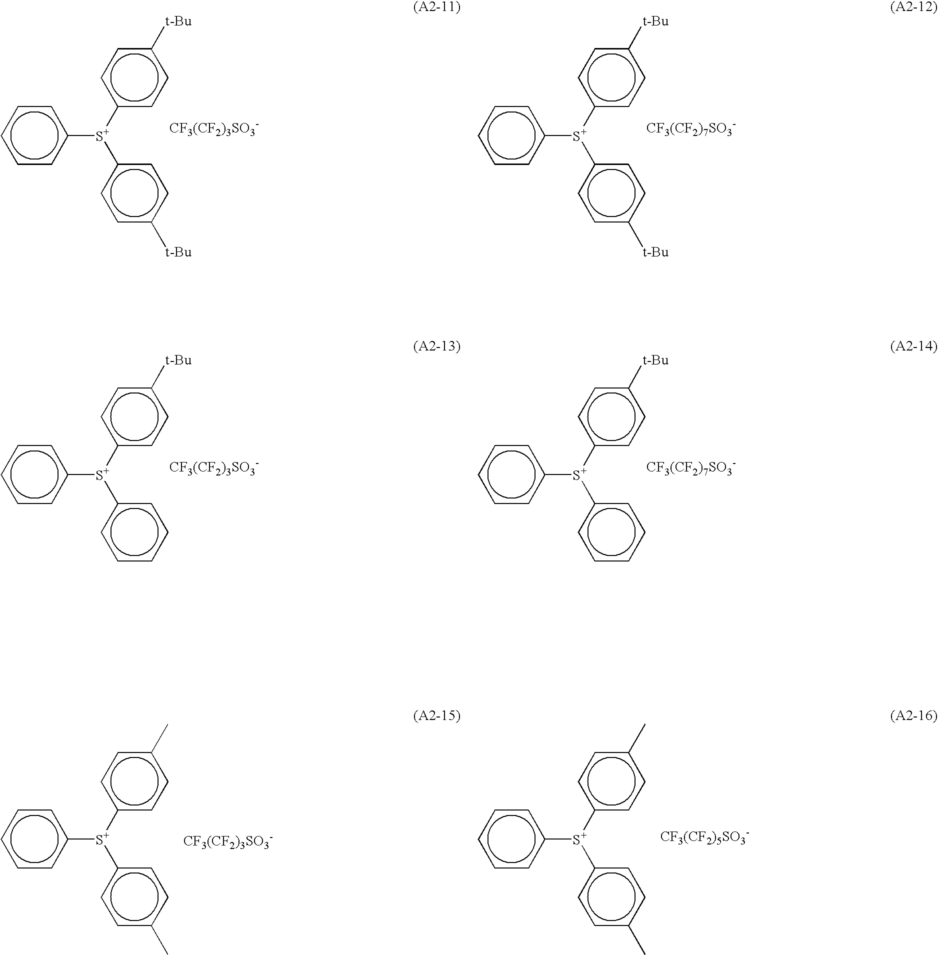

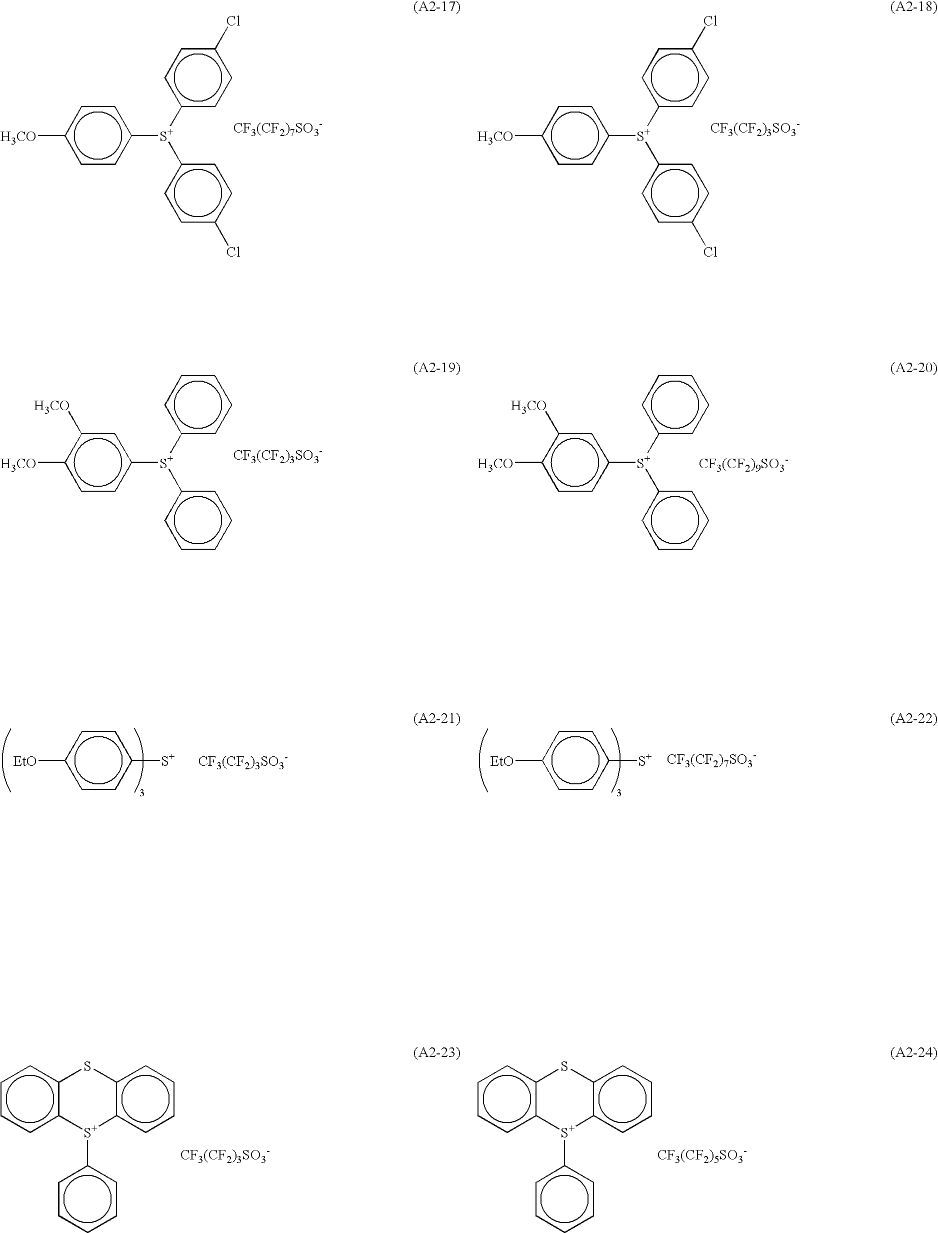

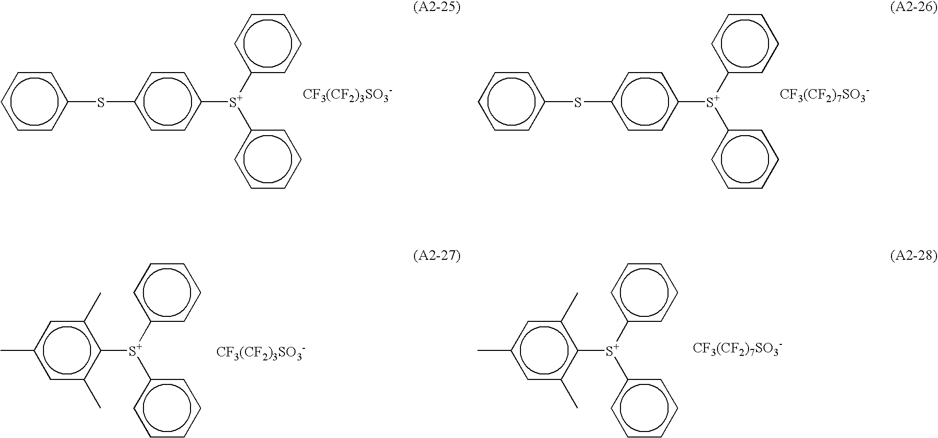

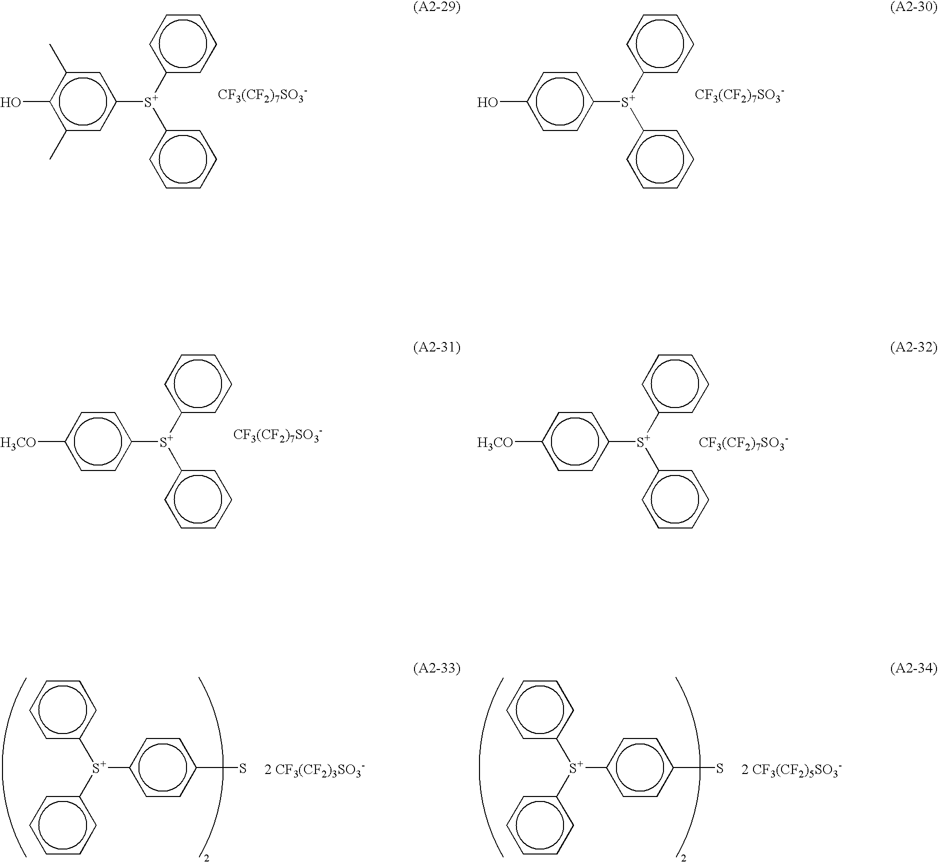

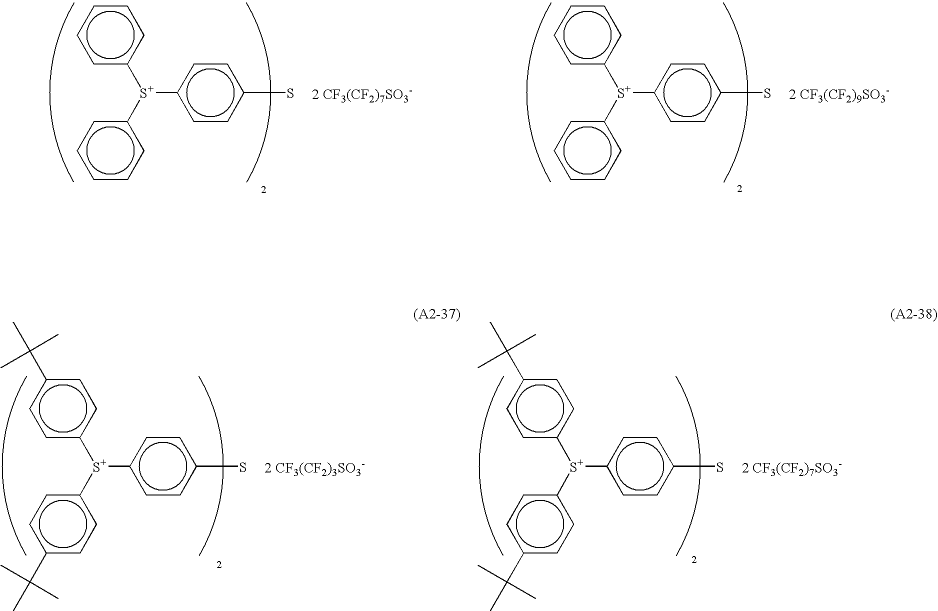

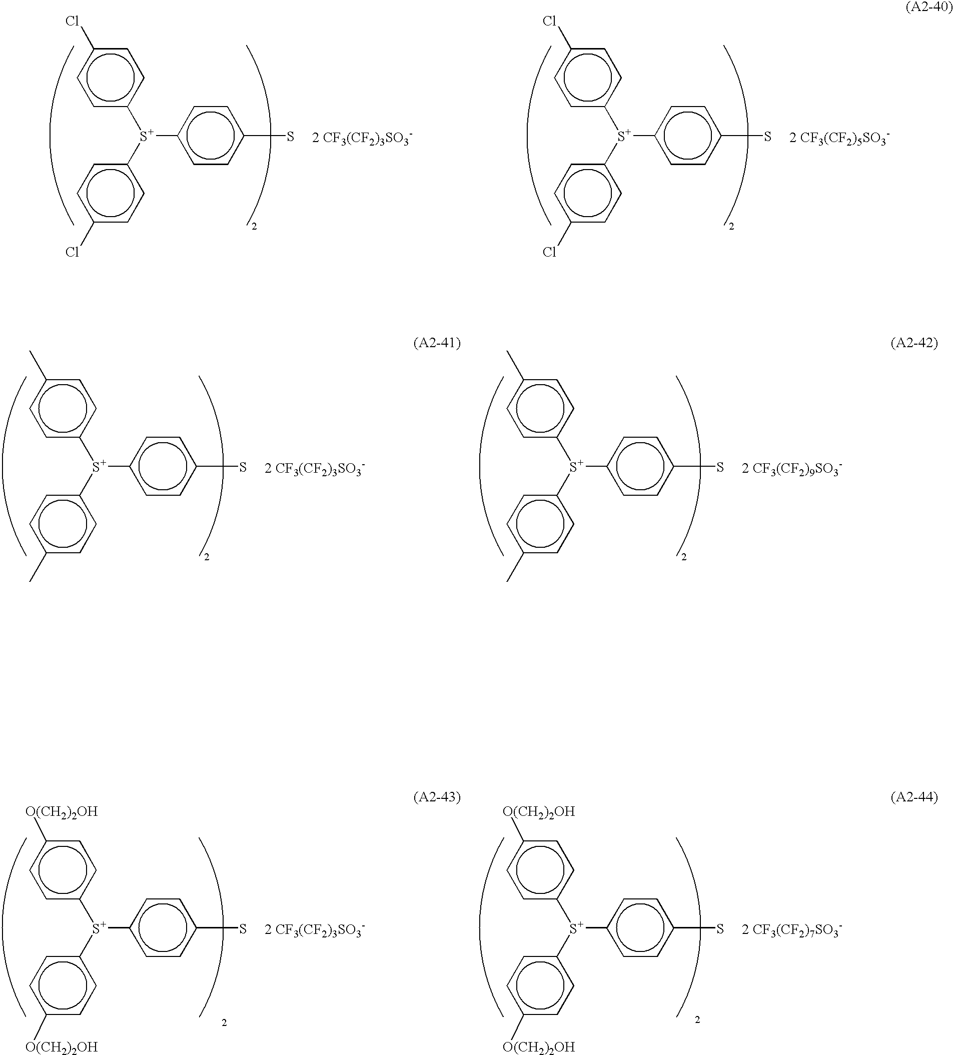

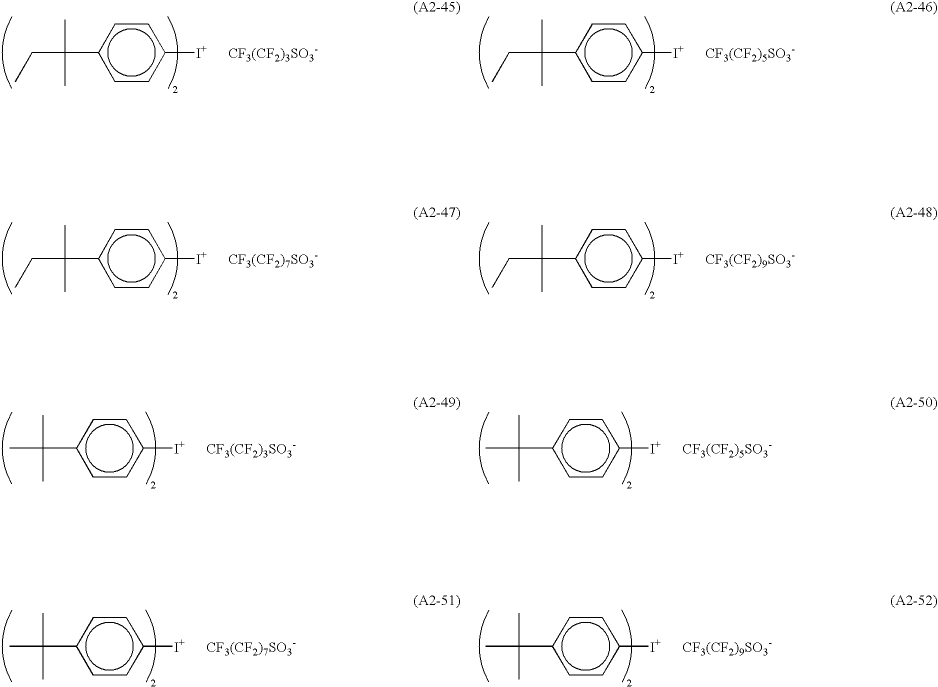

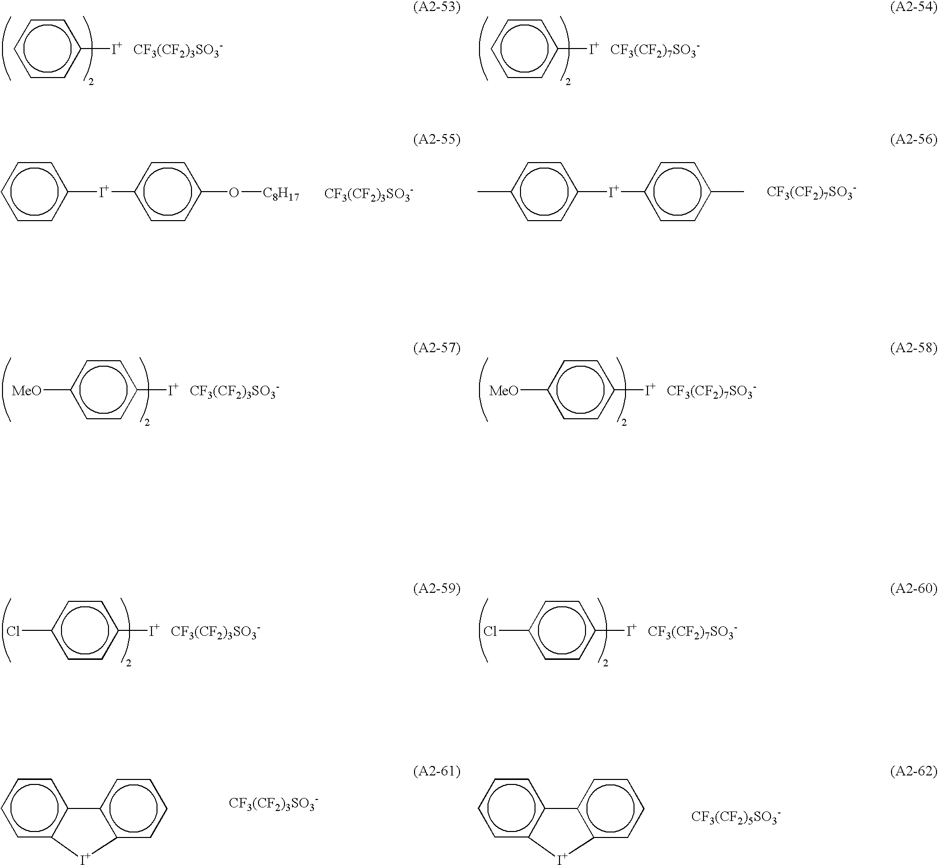

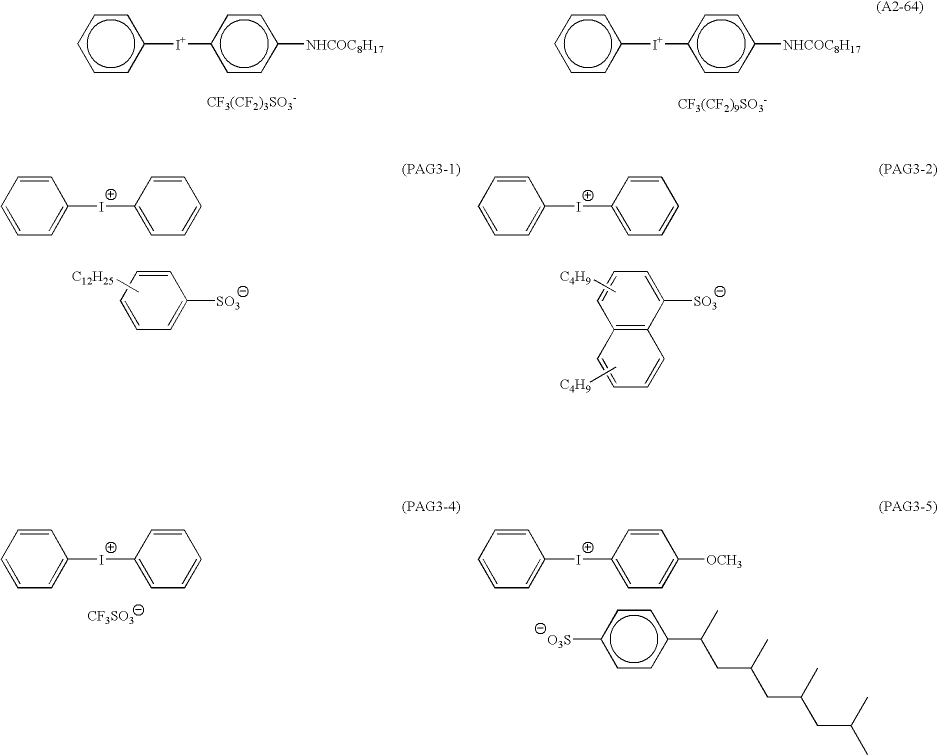

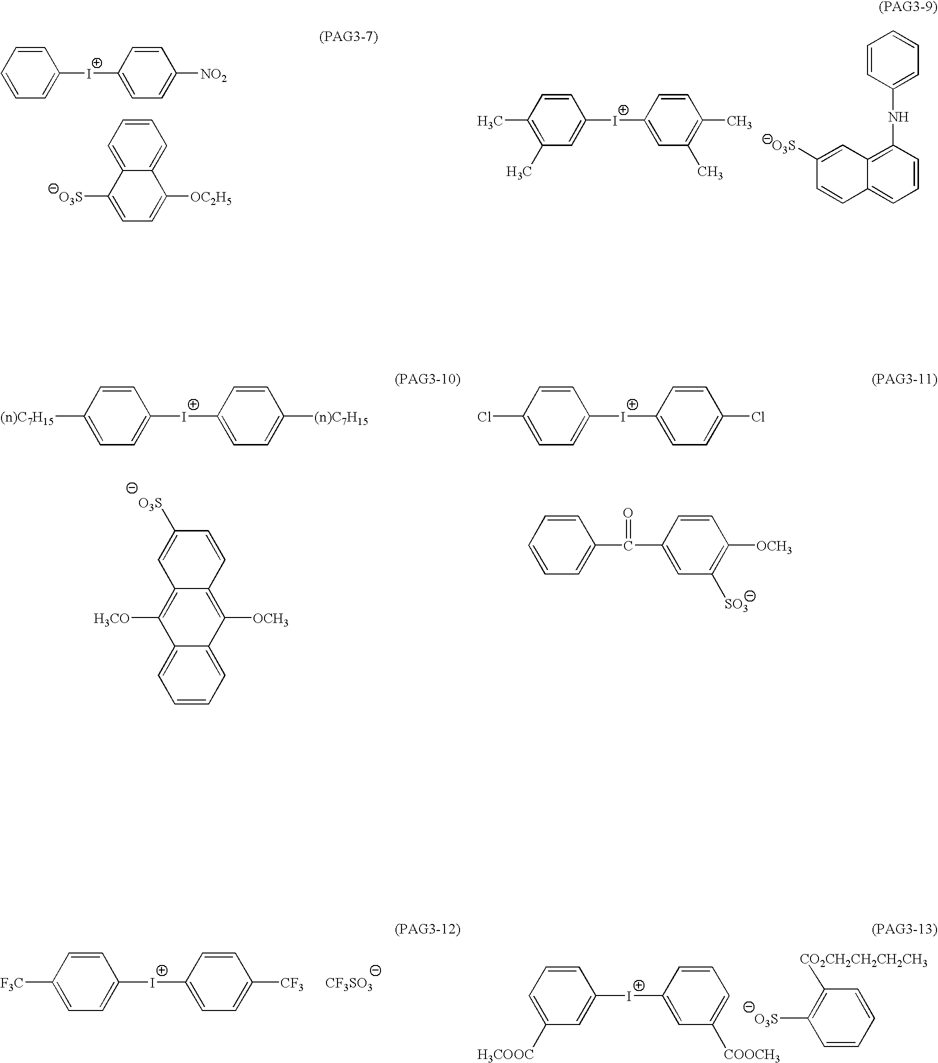

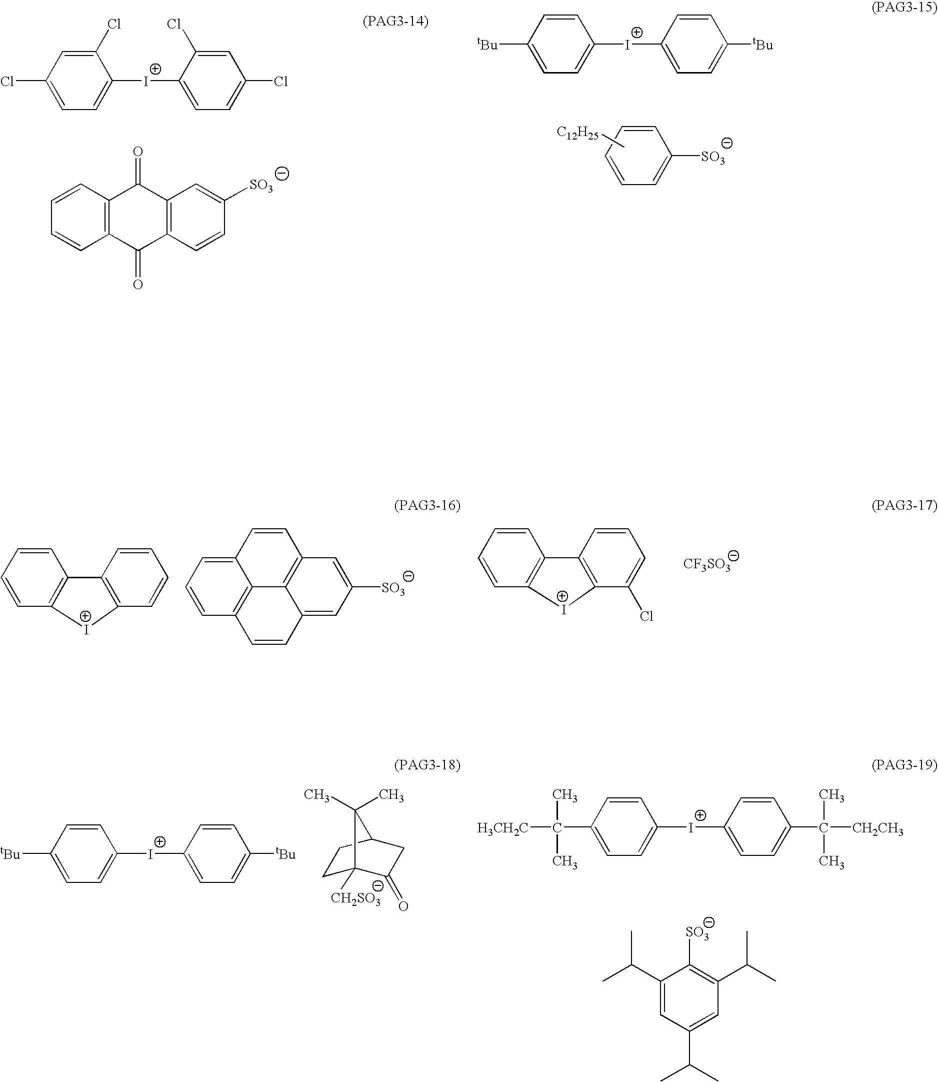

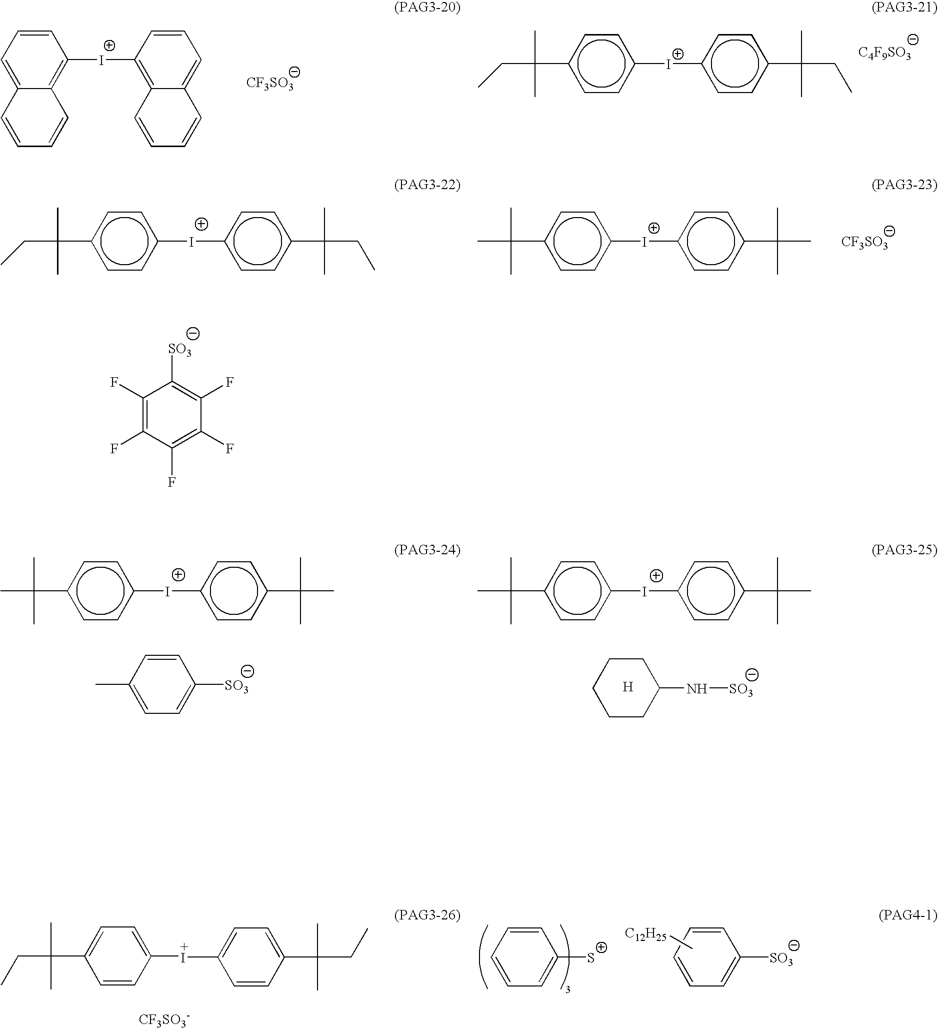

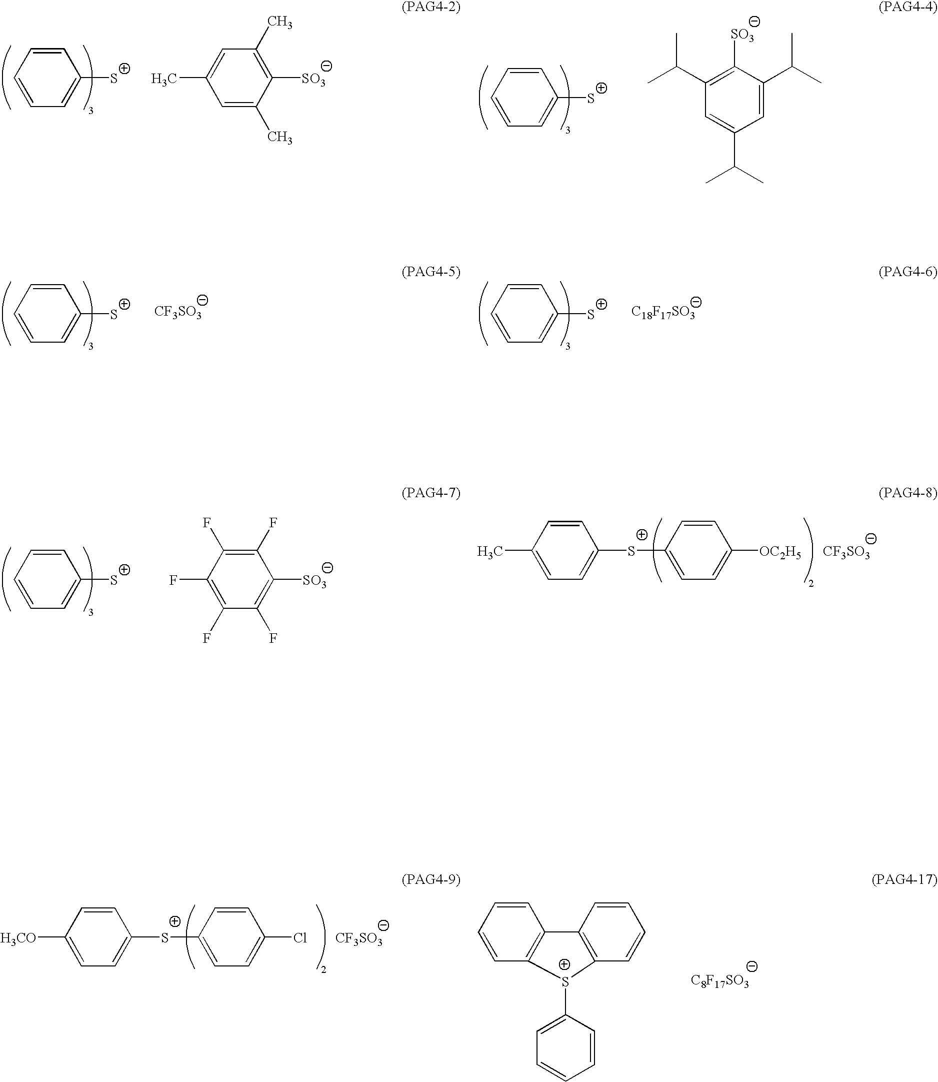

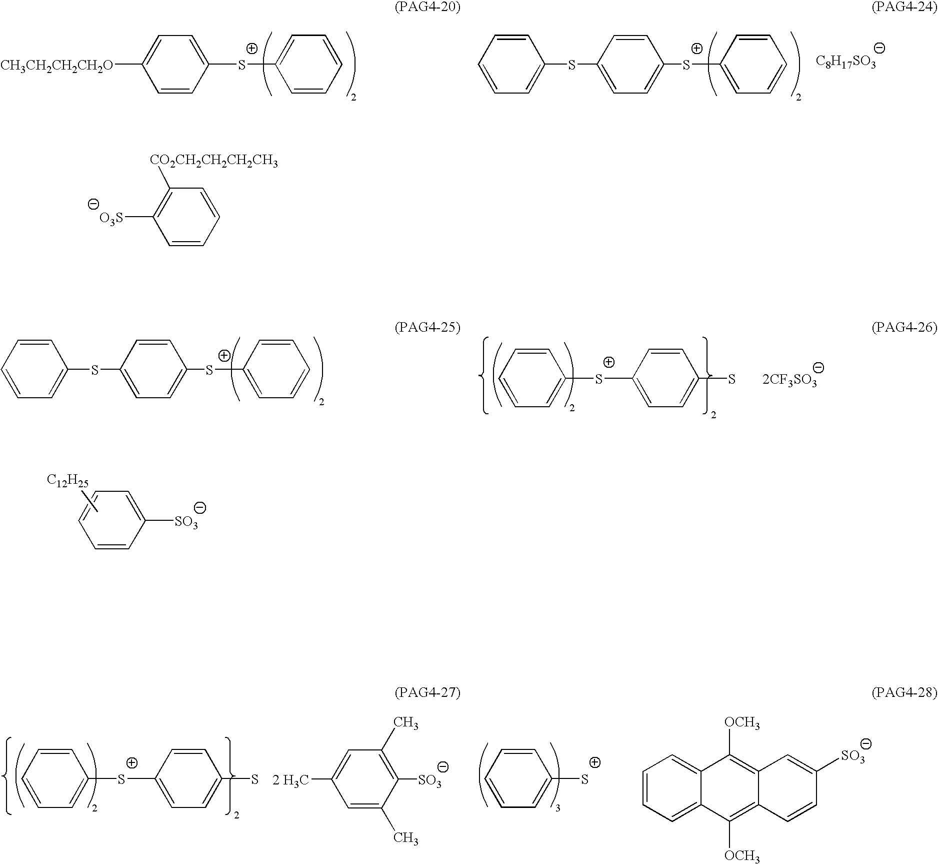

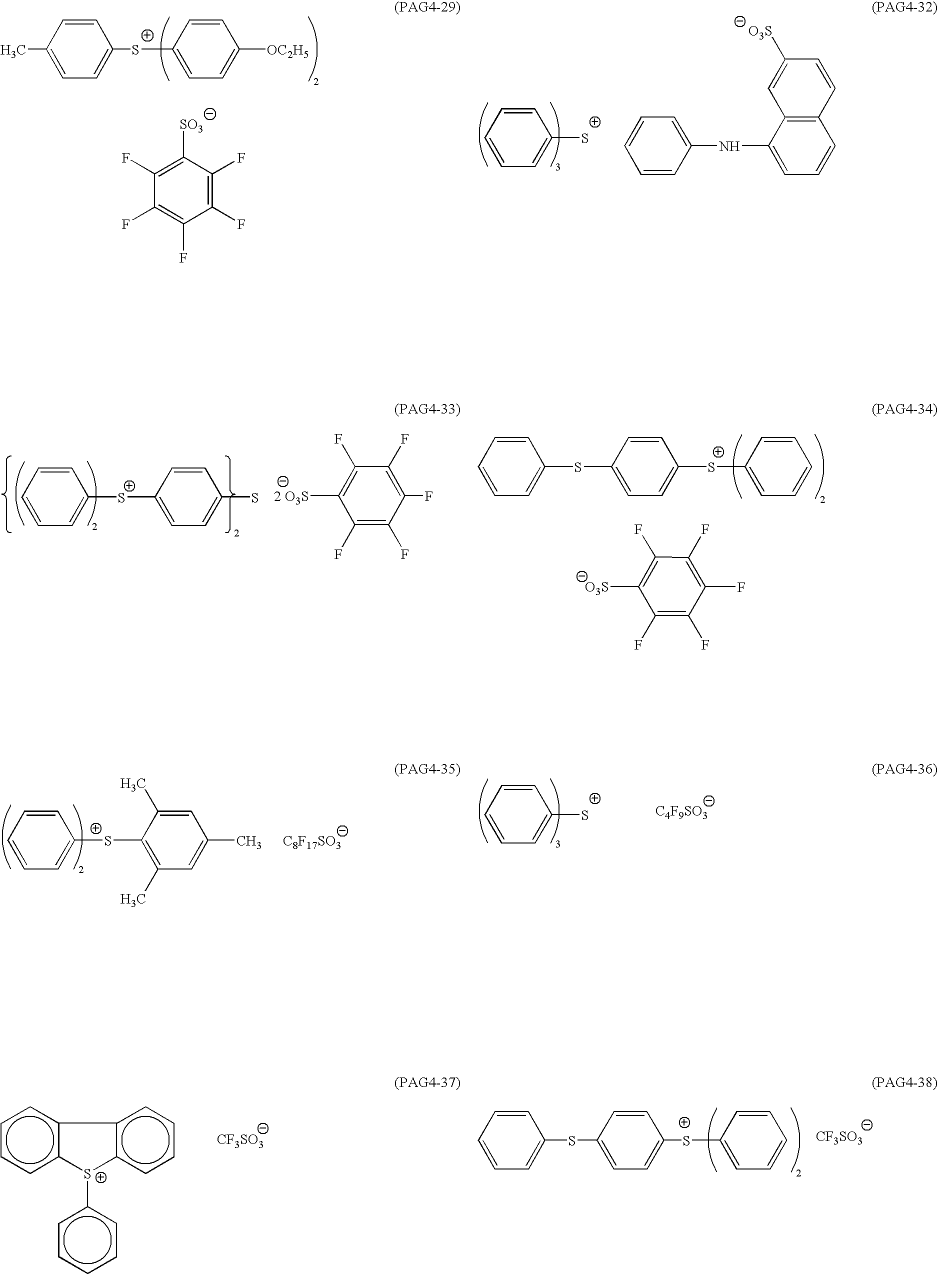

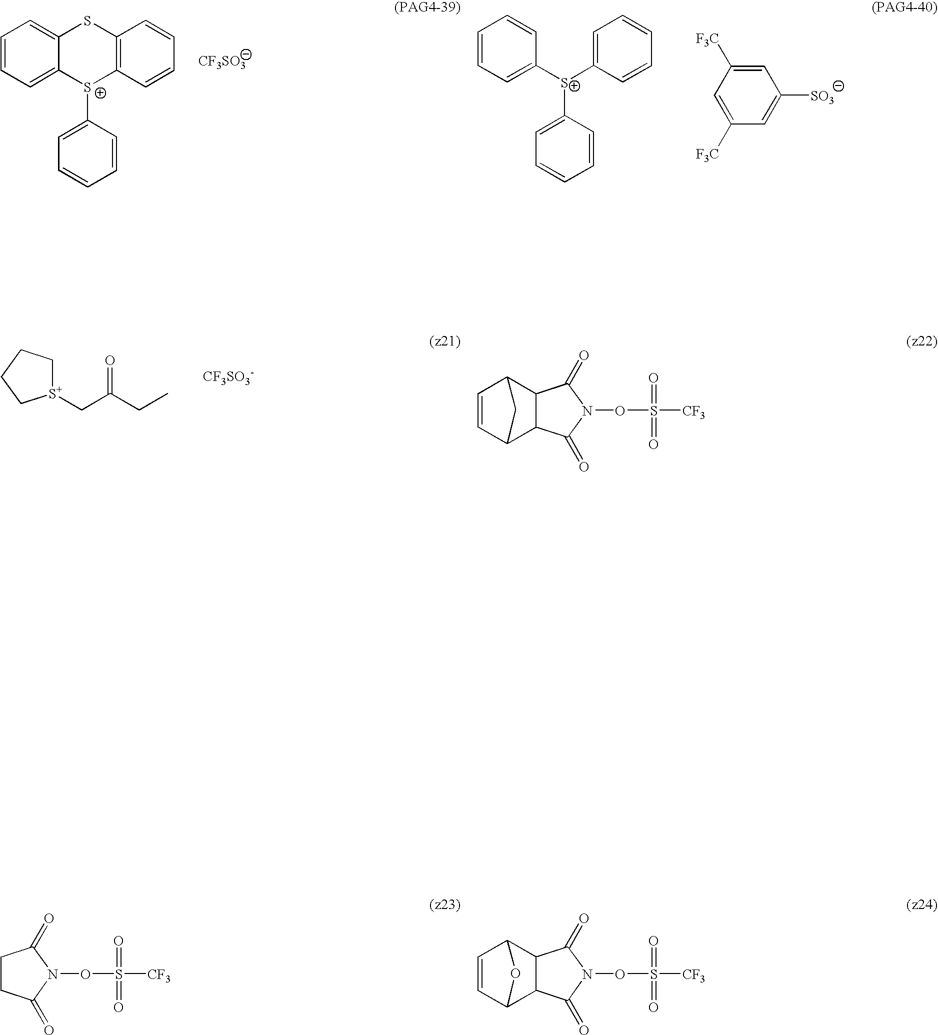

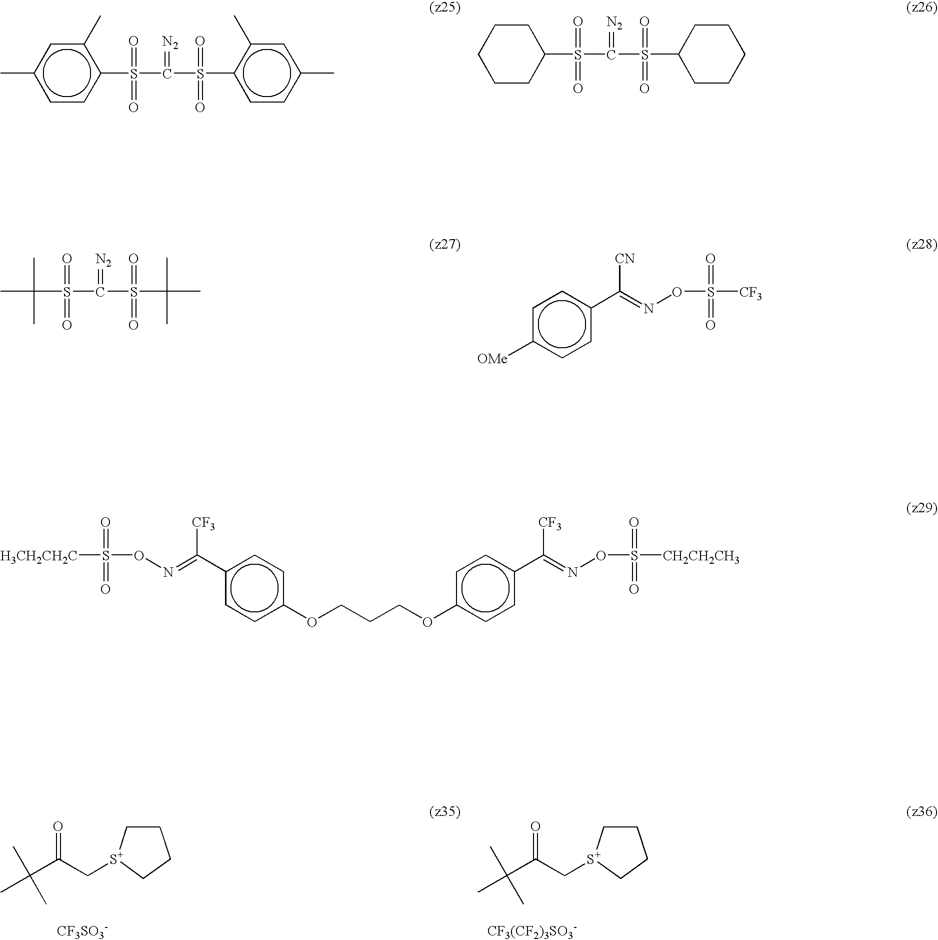

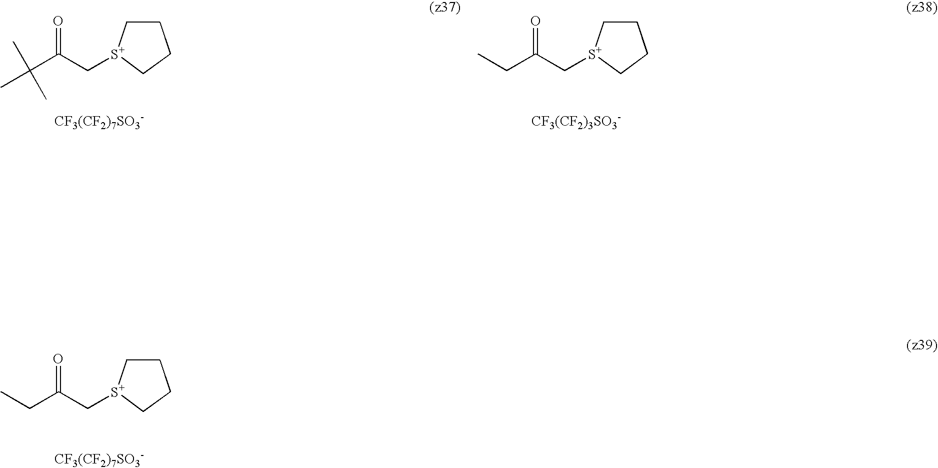

[4] Binder Resin (D)

The resist composition of the invention may be in the form of either positive-working resist composition or negative-working resist composition depending on the selection of binder resin.

[4]-1. In the Case Where the Resist Composition is Used as Negative-Working Resist Composition

The binder resin (hereinafter occasionally referred to as “(D1) an alkali-soluble resin”) to be used in the case where the resist composition of the invention is used as a negative-working resist composition will be described hereinafter.

As binder resins there may be widely used polymers having phenol skeleton such as phenol novolak resin disclosed with reference to negative-working chemically-sensitized resist, polyvinyl phenol resin, copolymer having a structural unit derived from vinylphenol and resin obtained by partly protecting or modifying polyvinyl phenol resin. Preferably, a phenol resin containing a repeating structural unit represented by the following formula (X) is used.

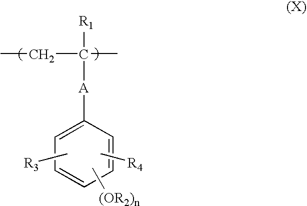

In the formula (X), R₁ represents a hydrogen atom, a halogen atom, a cyano group or an alkyl group which may have substituents.

R₂ represents a hydrogen atom or an alkyl, a cycloalkyl, an aryl, an aralkyl or an acyl group, which may have substituents.

R₃ and R₄ may be the same or different and each represents a hydrogen atom, a halogen atom, a cyano group or an alkyl, a cycloalkyl, an alkenyl, an aralkyl or an aryl group, which may have substituents. When R₃ and R₄ each is a hydrogen atom, it means that R₃ and R₄ form no substituents on the benzene ring in the formula (X).

A represents a single bond, an alkylene, an alkenylene, a cycloalkylene or an arylene group, which may have substituents, —O—, —SO₂—, —O—CO—R₅—, —CO—O—R₆— or —CO—N(R₇)—R₈—.

R₅, R₆ and R₈ each represents a single bond, an alkylene, an alkenylene, a cycloalkylene or an arylene group, which may have substituents or a divalent group formed together by at least one of these groups and at least one selected from the group consisting of ether structure, ester structure, amide structure, urethane structure and ureide structure.

R₇ represents a hydrogen atom or an alkyl, cycloalkyl, aralkyl or aryl group, which may have substituents.

The suffix n represents an integer of from 1 to 3. The plurality of R₂'s may be bonded to each other to form a ring. Alternatively, R₂ may be connected to R₃ or R₄ to form a ring.

The alkyl group represented by R₁ to R₄ and R₇ is preferably a C₁-C₈ alkyl group such as methyl group, ethyl group, propyl group, n-butyl group, sec-butyl group, hexyl group, 2-ethylhexyl group and octyl group.

The cycloalkyl group represented by R₂ to R₄ and R₇ may be monocyclic or polycyclic. The monocyclic cycloalkyl group is preferably a C₃-C₈ cycloalkyl group such as cyclopropyl group, cyclopentyl group and cyclohexyl group. Preferred examples of the polycyclic cycloalkyl group include adamanthyl group, norbornyl group, isoboronyl group, dicyclopentyl group, α-pinel group and tricyclodecanyl group.

The alkenyl group represented by R₃ or R₄ is preferably a C₂-C₈ alkenyl group such as vinyl group, allyl group, butenyl group and cyclohexenyl group.

The aryl group represented by R₂ to R4 and R₇ is preferably a C₆-C₁₅ aryl group such as phenyl group, tolyl group, dimethylphenyl group, 2,4,6-trimethylphenyl group, naphthyl group and anthryl group.

The aralkyl group represented by R₂ to R₄ and R₇ is preferably a C₇-C₁₂ aralkyl group such as benzyl group, phenethyl group and naphthylmethyl group.

The acyl group represented by R₂ is preferably a C₁-C₈ acyl group such as formyl group, acetyl group, propanoyl group, butanoyl group, pivaloyl group and benzoyl group.

The alkylene group represented by A, R₅, R₆ or R₈ is preferably a C₁-C₈ alkylene group such as methylene, ethylene, propylene, butylene, hexylene and octylene groups, which may have substituents.

The alkenylene group represented by A, R₅, R₆ or R₈ is preferably a C₂-C₆ alkenylene group such as ethenylene, propenylene and butenylene groups, which may have substituents.

The cycloalkylene group represented by A, R₅, R₆ or R₈ is preferably a C₅-C₈ cycloalkylene group such as cyclopentylene and cyclohexylene groups, which may have substituents.

The arylene group represented by A, R₅, R₆ or R₈ is preferably a C₆-C₁₂ arylene group such as phenylene group, tolylene group and naphthylene group.

The aforementioned alkyl, cycloalkyl group, aryl group, aralkyl group, acyl group, alkenyl group, alkylene group, alkenylene group, cycloalkylene group and arylene group may have substituents.

Examples of the substituents on these groups include those having active hydrogen such as amino group, amide group, ureide group, urethane group, hydroxyl group and carboxyl group, halogen atom (e.g., fluorine atom, chlorine atom, bromine atom, iodine atom), alkoxy group (e.g., methoxy group, ethoxy group, propoxy group, butoxy group), thioether group, acyl group (e.g., acetyl group, propandyl group, benzoyl group), acyloxy group (e.g., acetoxy group, propanoyloxy group, benzoyloxy group), alkoxycarbonyl group (e.g., methoxycarbonyl group, ethoxycarbonyl group, propoxycarbonyl group), cyano group, and nitro group. Particularly preferred among these substituents are those having active hydrogen such as amino group, hydroxyl group and carboxyl group.

Examples of the ring formed by the plurality of R₂'s or by R₂ and R₃ or R₄ include 4- to 7-membered rings containing oxygen atom such as benzofurane ring, benzodioxonol ring and penzopyran ring.

The binder resin (D) of the invention may be a resin made of only a repeating structural unit represented by the formula (X) but may be copolymerized with other polymerizable monomers for the purpose of improving the properties of negative-working resist composition of the invention.

Examples of the copolymerizable monomers employable herein include compounds having one addition-polymerizable unsaturated bond selected from acrylic acid esters, acrylamides, methacrylic acid esters, methacrylamides, allyl compounds, vinylethers, vinylesters, styrenes and crotonic acid esters other than described above.

Preferred among these compounds are monomers having carboxyl group such as carboxystyrene, N-(carboxyphenyl)acrylmaide and N-(carboxyphenyl)methacrylamide and monomers capable of enhancing alkali solubility such as maleimide.

The content of other polymerizable monomers in the resin of the invention is preferably not greater than 50 mol %, more preferably not greater than 30 mol % based on the total amount of repeating units.

Specific examples of the resin having a repeating unit represented by the formula. (X) will be given below, but the invention is not limited thereto.

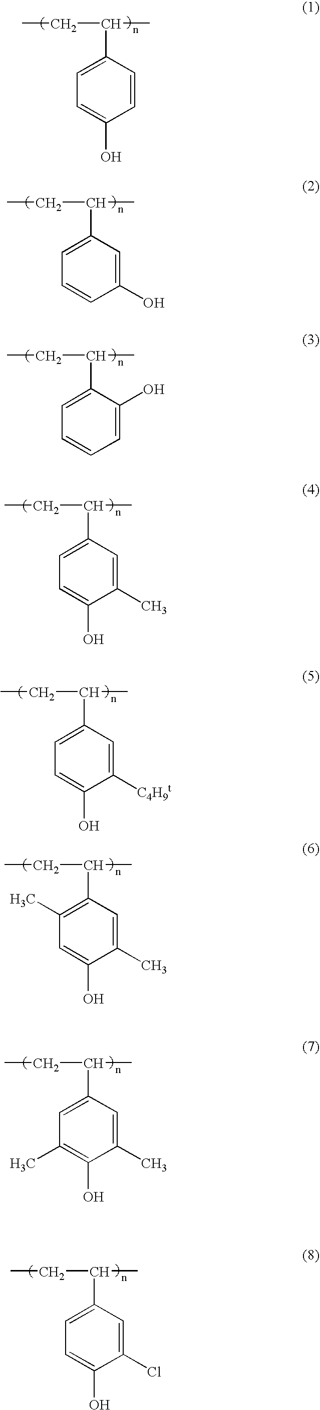

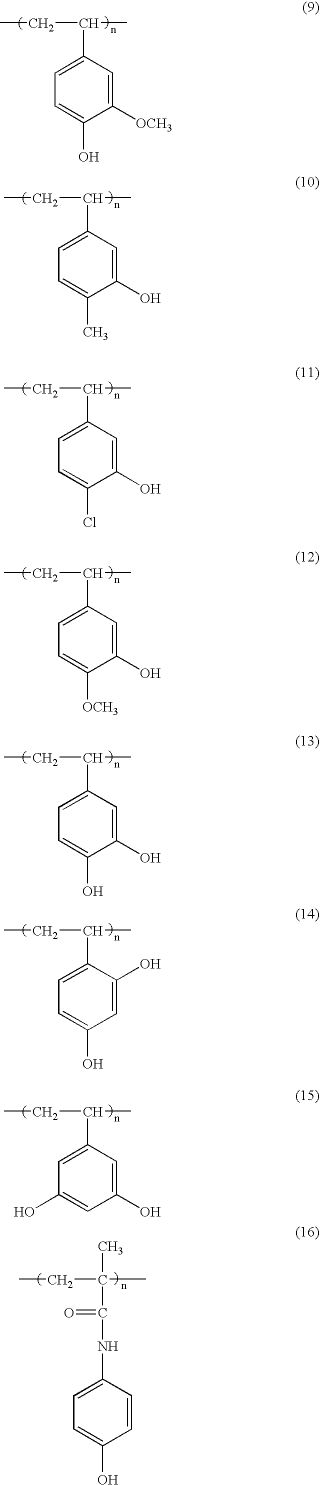

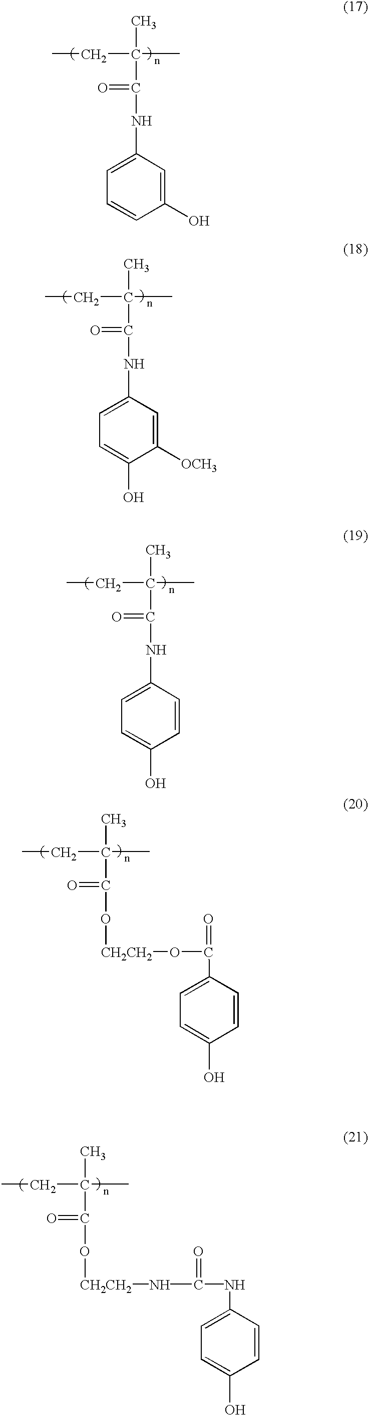

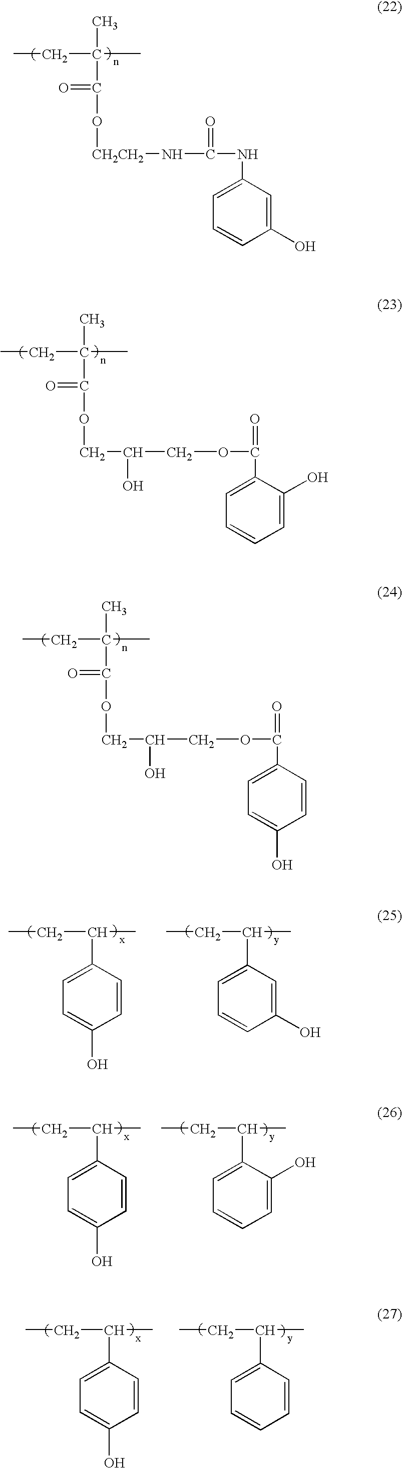

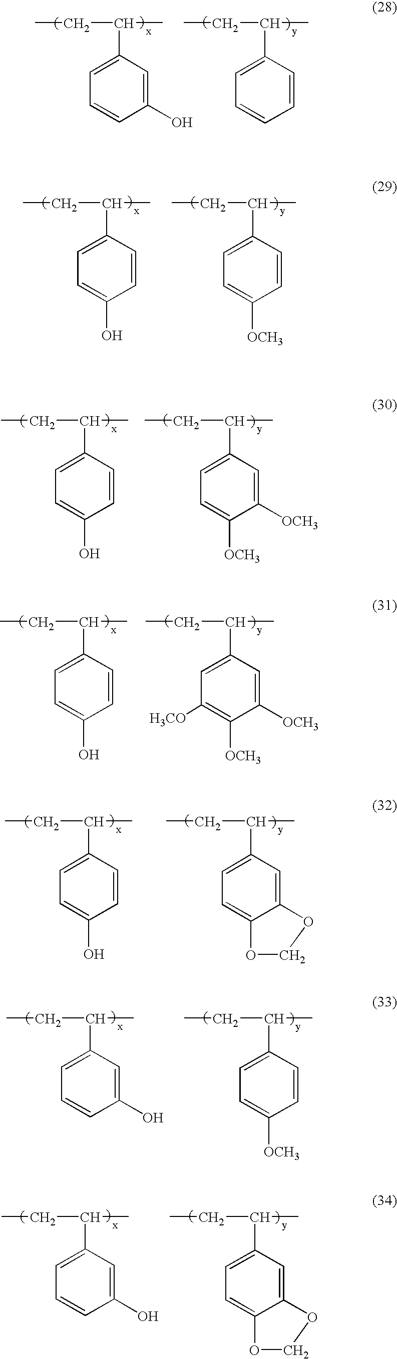

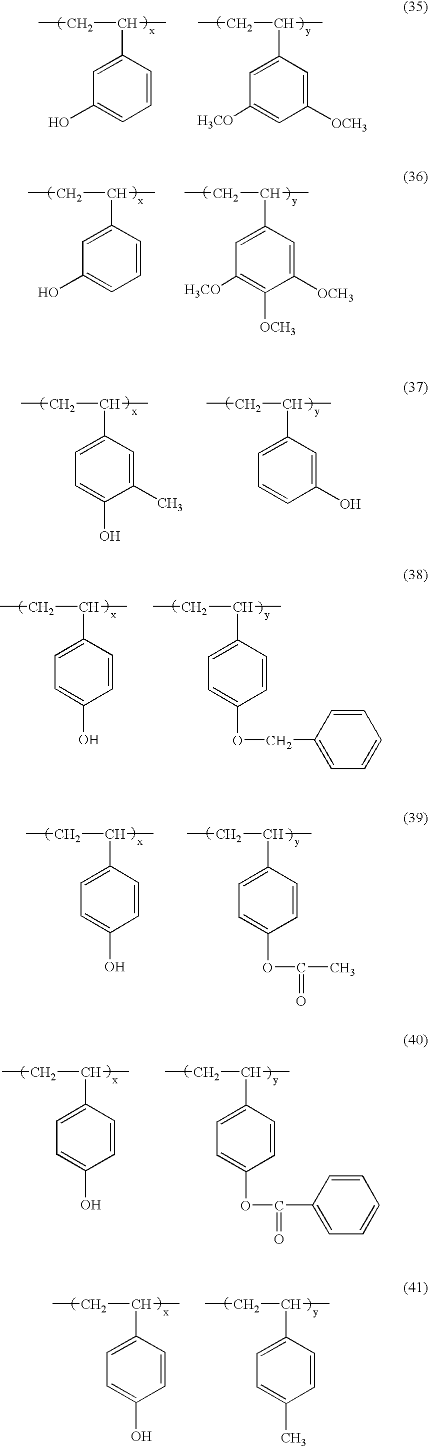

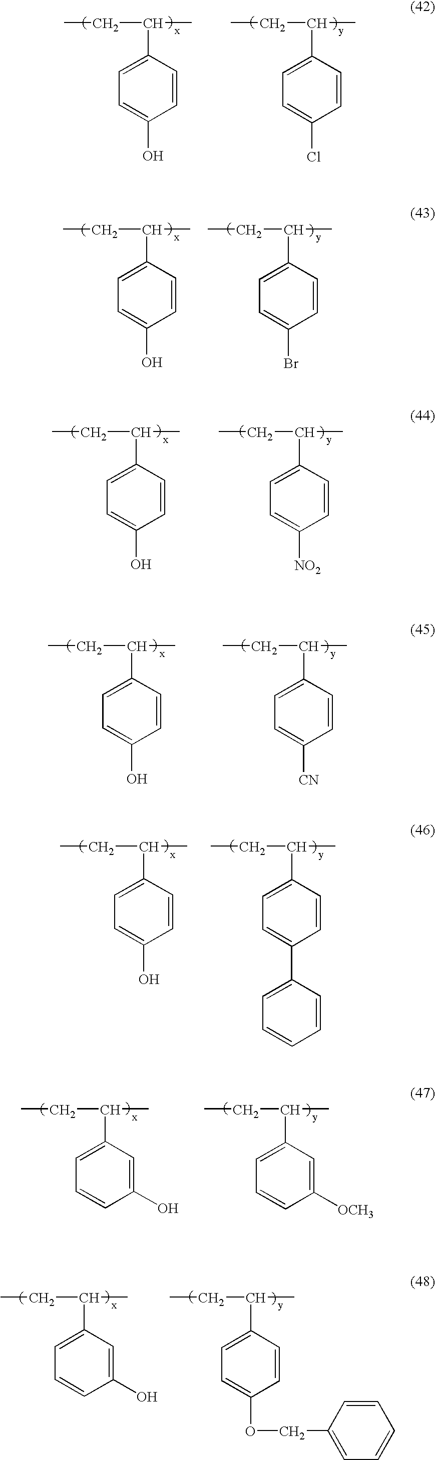

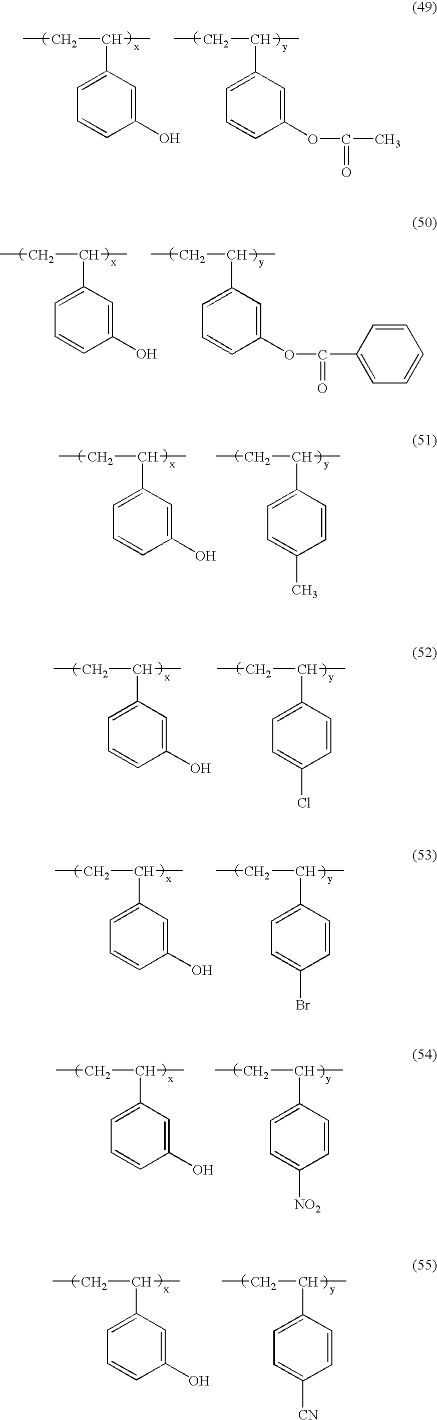

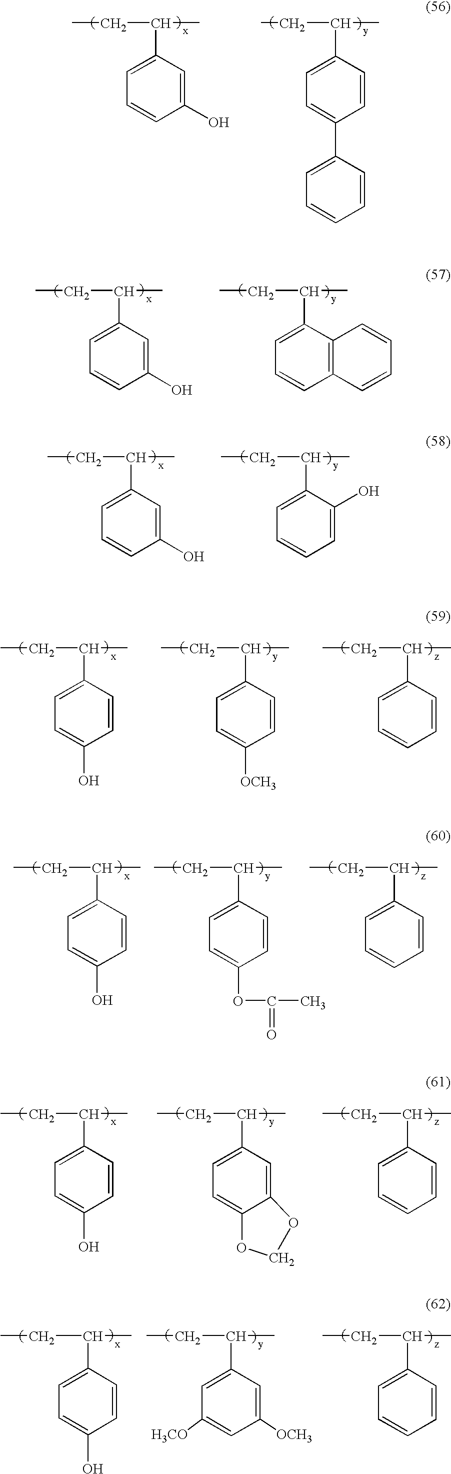

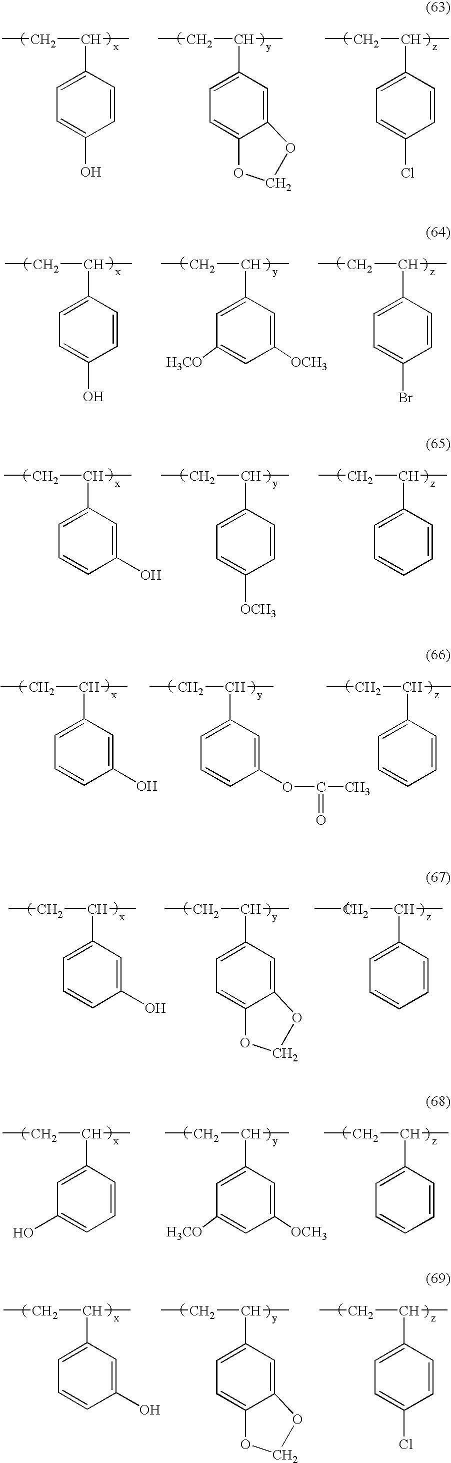

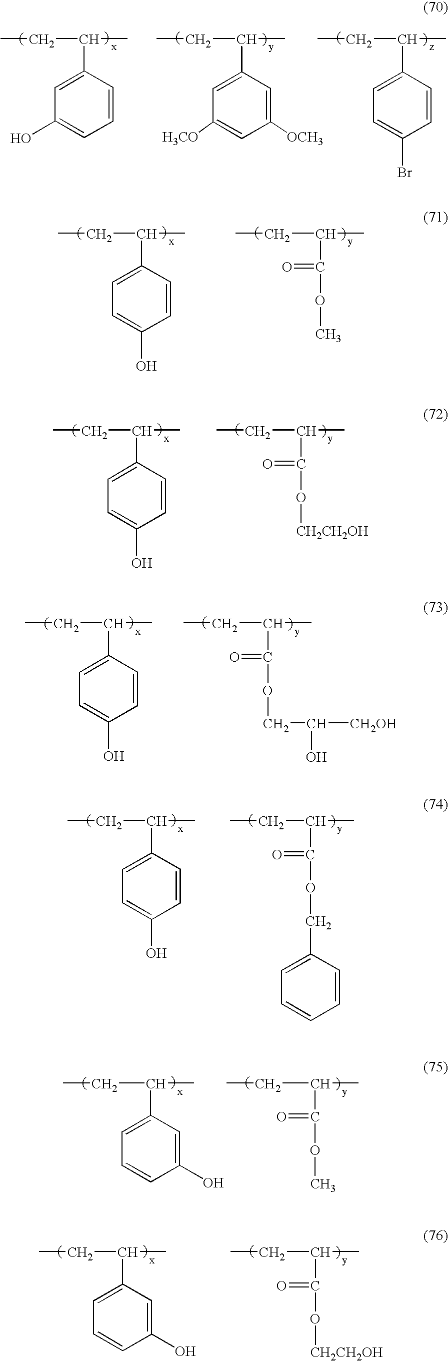

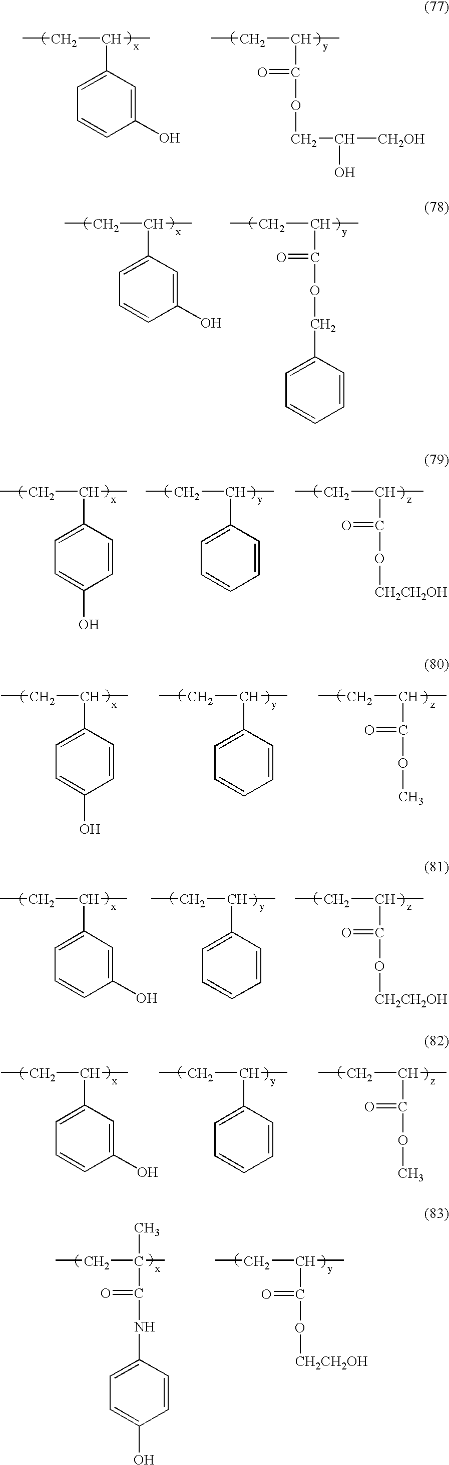

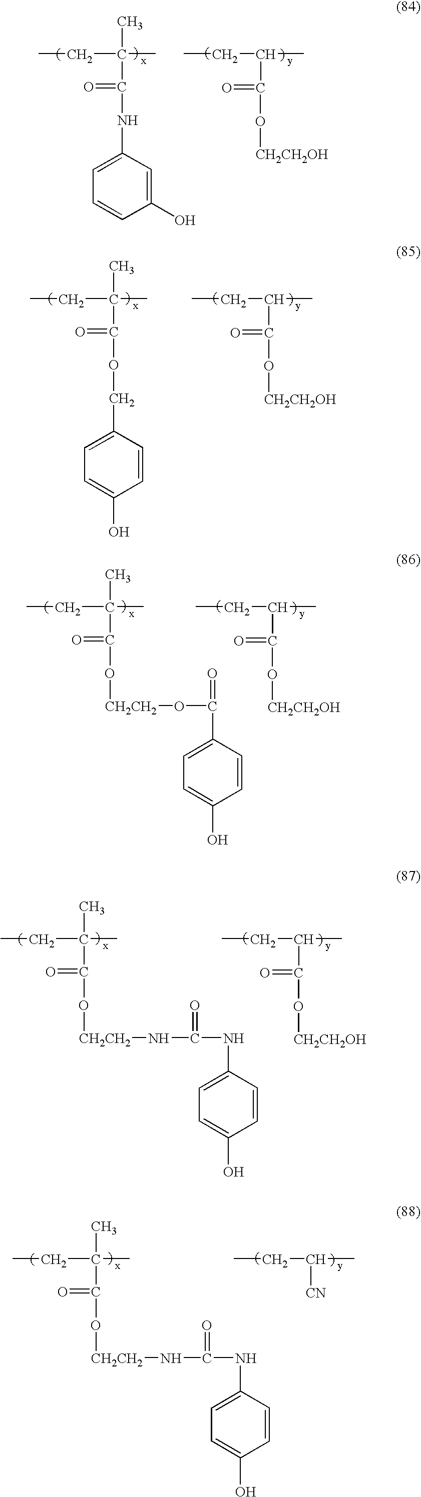

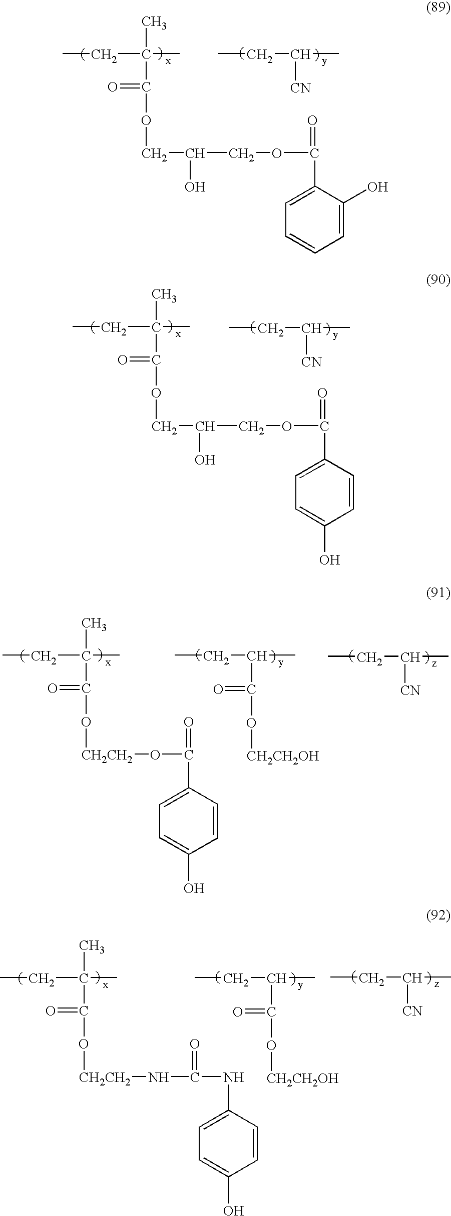

In the aforementioned specific examples, n represents a positive integer. The suffixes x, y and z each represent the molar ratio of resin composition. In the resin comprising two components, x and y are from 10 to 95 and from 5 to 90, preferably from 40 to 90 and from 10 to 60, respectively. In the resin comprising three components, x, y and z are from 10 to 90, from 5 to 85 and from 5 to 85, preferably from 40 to 80, from 10 to 50 and from 10 to 50, respectively.

The foregoing binder resin for negative-working resist composition, preferably a resin having a repeating unit represented by the formula (X), preferably has a molecular weight of from 1,000 to 200,000, more preferably from 3,000 to 50,000 as calculated in terms of weight-average molecular weight. The distribution of molecular weight of the binder resin is from 1 to 10, preferably from 1 to 3, more preferably from 1 to 1.5. The smaller the distribution of molecular weight is, the higher is the resolution, the smoother are the shape of resist and the side wall of resist pattern and the better is roughness resistance.

The content of the repeating structural unit represented by the formula (X) is from 5 to 100 mol %, preferably from 10 to 90 mol % based on the total amount of the resin.

The alkali-soluble polymer containing a structural unit represented by the formula (X) to be used in the invention can be synthesized by any method disclosed in “Macromolecules”, 1995, 28 (11), pp. 3,787to3,789, “Polym. Bull.”, Berlin, 1990, 24 (4), pp. 385 to 389, and JP-A-8-286375. In other words, the desired alkali-soluble polymer can be obtained by a radical polymerization method or living anionic polymerization method.

These resins may be used singly or in admixture thereof.

The weight-average molecular weight as used herein is defined in polystyrene equivalence determined by gel permeation chromatography.

The alkali dissolution rate of the alkali-soluble polymer is preferably not smaller than 20 angstrom/sec, particularly not smaller than 200 angstrom/sec as determined with 0.261 N tetramethylammonium hydroxide (TMAH) at 23° C.

The alkali-soluble polymer of the invention may be used singly or in combination with other alkali-soluble polymers. The proportion of the other alkali-soluble polymers to be used is 100 parts by weight at maximum based on 100 parts by weight of the alkali-soluble polymer of the invention. Examples of the alkali-soluble polymers which can be used in combination with the alkali-soluble polymer of the invention will be given below.

Examples of these alkali-soluble polymers include novolak resin, hydrogenated novolak resin, acetone-pyrogallol resin, styrene-maleic anhydride copolymer, carboxyl group-containing methacrylic resin, and derivatives thereof. However, the invention is not limited to these compounds.

The amount of the binder resin for negative-working to be incorporated is from 30 to 95% by weight, preferably from 40 to 90% by weight, more preferably from 50 to 80% by weight based on the total solid content of the negative-working resist composition.

Further preferred examples of the alkali-soluble polymer which is used as a binder for negative-working resist composition in the invention include one having a repeating unit represented by the following formula (b-2) or (b-3).

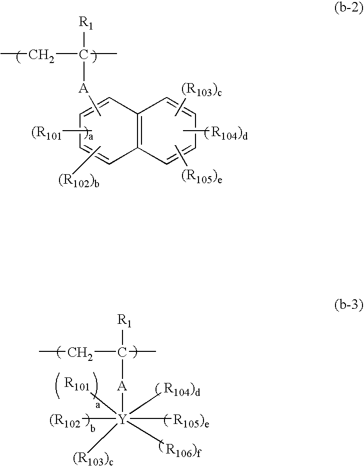

In the formulae (b-2) and (b-3), R₁ is as defined in the formula (X).

A is as defined in the formula (X).

R₁₀₁ to R₁₀₆ each independently represents a hydroxyl group, a carboxyl group, an amino group or an alkyl, cycloalkyl, alkoxy, alkylcarbonyloxy, alkylsulfonyloxy, alkenyl, aryl, aralkyl, N-alkylamino or N-dialkylamino groups which may have substituents, preferably a hydroxyl group, a C₁-C₆ straight-chain or branched alkyl group, a C₁-C₆ alkoxy group, a C₁-C₆alkylcarbonyloxy group or a phenyl group, more preferably a hydroxyl group, a C₁-C₄ straight-chain or branched alkyl group (e.g., methyl group, ethyl group, n-propyl group, n-butyl group, t-butyl group), a C₁-C₃ alkoxy group (e.g., methoxy group, ethoxy group) or a phenyl group. The suffixes a to f each independently represent an integer of from 0 to 3, preferably from 0 to 2.

Examples of the alkyl group and the alkyl moiety in the alkylcarbonyloxy group, alkylsulfonyloxy group, N-alkylamino group and N-dialkylamino group include straight-chain or branched alkyl group. Preferred examples of the alkyl group include methyl group, ethyl group, propyl group, n-butyl group, sec-butyl group, hexyl group, 2-ethylhexyl group, and octyl group. The cycloalkyl group may be either monocyclic or polycyclic. Preferred examples of the monocyclic cycloalkyl group include cyclopropyl group, cyclopentyl group, and cyclohexyl group. Preferred examples of the polycyclic cycloalkyl group include adamanthyl group, norbornyl group, isoboronyl group, dicyclopentyl group, α-pinel group, and tricyclodecanyl group.

Preferred examples of the alkenyl group include vinyl group, allyl group, butenyl group, and cyclohexenyl group.

Preferred examples of the aryl group include phenyl group, tolyl group, dimethylphenyl group, 2,4,6-trimethylphenyl group, naphthyl group, and anthryl group.

Preferred examples of the aralkyl group include benzyl group, phenethyl group, and naphthylmethyl group.

Y represents any structure selected from the group consisting of the following condensed polycyclic aromatic structures.

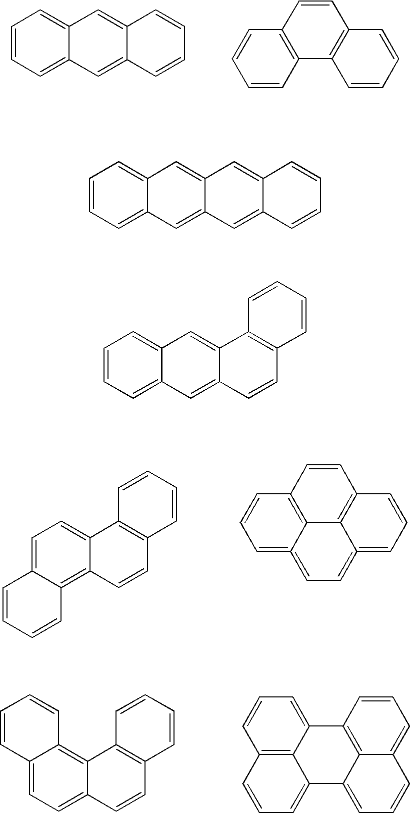

In the condensed polycyclic aromatic structure represented by Y, the bond to the main chain or the substituents may be positioned at any bond on the condensed polycyclic aromatic structure.

The aforementioned alkyl group, cycloalkyl group, aryl group, alkoxy group, alkylcarbonyloxy group, alkylsulfonyloxy group, aralkyl group, alkenyl group, N-alkylamino group and N-dialkylamino group may have substituents.

Examples of the substituents on these groups include those having active hydrogen such as amino group, amide group, ureide group, urethane group, hydroxyl group and carboxyl group, halogen atom (e.g., fluorine atom, chlorine atom, bromine atom, iodine atom), alkoxy group (e.g., methoxy group, ethoxy group, propoxy group, butoxy group), thioether group, acyl group (e.g., acetyl group, propanoyl group, benzoyl group), acyloxy group (e.g., acetoxy group, propanoyloxy group, benzoyloxy group), alkoxycarbonyl group (e.g., methoxycarbonyl group, ethoxycarbonyl group, propoxycarbonyl group), cyano group, and nitro group.

The content of the repeating unit represented by the formula (b-2) and/or (b-3) in the resin of the invention is preferably from 3 to 50 mol %, more preferably from 5 to 40 mol % based on the total amount of repeating units.

Examples of the alkali-soluble polymer having a condensed polycyclic aromatic structure to be used in the invention will be given below, but the invention is not limited thereto.

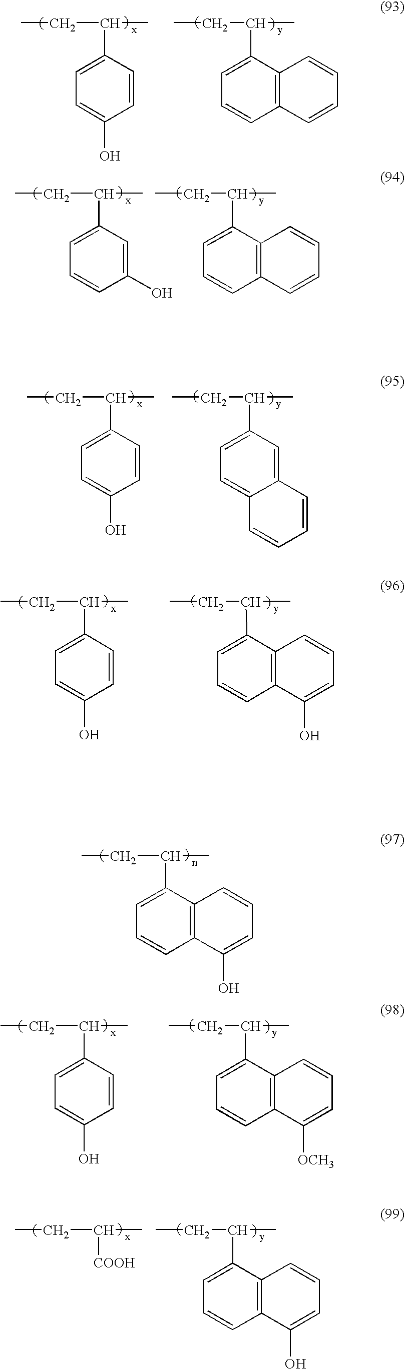

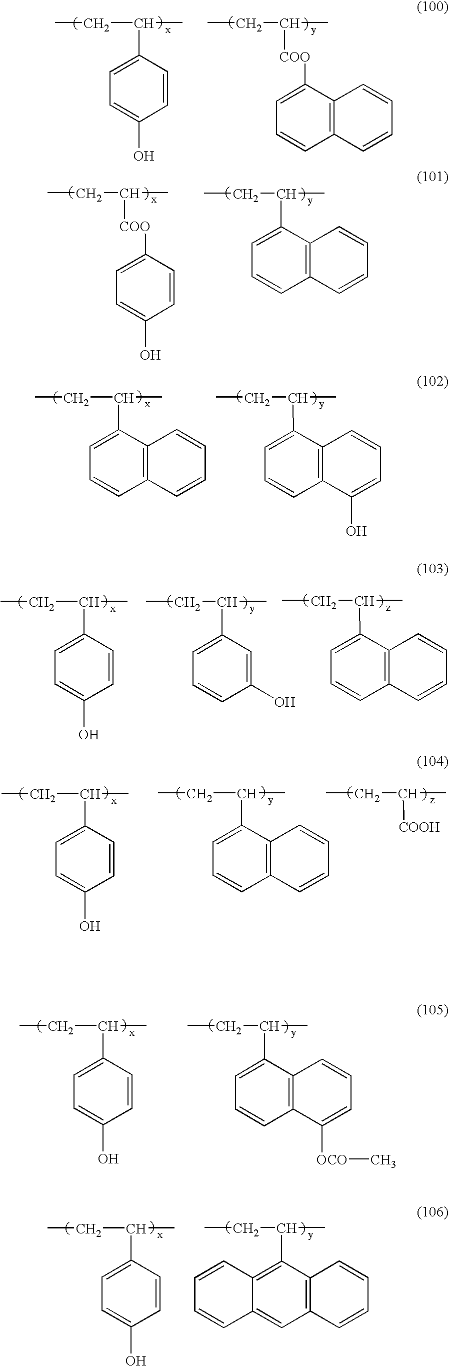

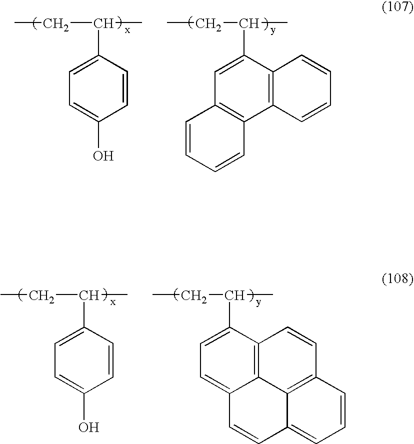

As the binder to be incorporated in negative-working resist composition there is more preferably used a copolymer comprising a repeating unit having a monocyclic aromatic structure and a repeating unit having a polycyclic aromatic structure.

[4]-2. In the Case Where the Resist Composition is Used as Positive-Working Resist Composition

The binder resin to be used in the case where the resist composition of the invention is used as a positive-working resist composition will be described hereinafter.

As the resin capable of increasing its solubility in an alkaline developer by the action of an acid to be incorporated in the positive-working resist composition of the invention there may be used a resin having a group decomposable with acid (hereinafter occasionally referred to as “acid-decomposable group”) in either or both of its main chain and side chain (hereinafter occasionally referred to as “acid-decomposable resin”). Preferred among these resins is the resin having an acid-decomposable group in its side chain.

Preferred examples of the acid-decomposable group include groups obtained by substituting the hydrogen atom in —COOH group and —OH group by a group eliminatable with acid. By the action of an acid, these acid-decomposable groups decompose to form —COOH group or —OH group that increases the solubility of the acid-decomposable resin in an alkaline developer.

Preferred examples of the acid-decomposable group include silylether group, cumylester group, acetal group, tetrahydropyranylether group, enolether group, enolester group, tertiary alkylether group, tertiary alkylester group, and tertiary alkylcarbonate group. Preferred among these acid-decomposable groups are tertiary alkylester group, tertiary alkylcarbonate group, cumylester group, acetal group, and tetrahydropyranylether group.

The matrix resin to which these acid-decomposable groups are connected as side chains is an alkali-soluble resin having —OH or —COOR. For example, alkali-soluble resins described later may be used.

The alkali dissolution rate of these alkali-soluble resins is preferably not smaller than 170 angstrom/sec, particularly not smaller than 330 angstrom/sec as determined at 23° C. in 0.261 N tetramethylammonium hydroxide (TMAH). Examples of alkali-soluble resins which are particularly preferred from these standpoints of view include o-, m-, p-poly(hydroxystyrene) and copolymer thereof, hydrogenated poly (hydroxystyrene), halogen-substituted poly(hydroxystyrene), alkyl-substituted poly(hydroxystyrene), partial O-alkylation or O-acylation product of poly(hydroxystyrene), styrene-hydroxystyrene copolymer, α-methylstyrene-hydroxystyrene copolymer, and hydrogenated novolak resin.

The binder resin for positive-working resist composition to be used in the invention is obtained by reacting an alkali-soluble resin with a precursor of acid-decomposable group or by copolymerizing an alkali-soluble resin having an acid-decomposable group connected thereto with various monomers as disclosed in European Patent No. 254853, JP-A-2-25850, JP-A-3-223860, and JP-A-4-251259.

Specific examples of the binder for positive-working resist composition employable herein will be given below, the invention is not limited thereto.

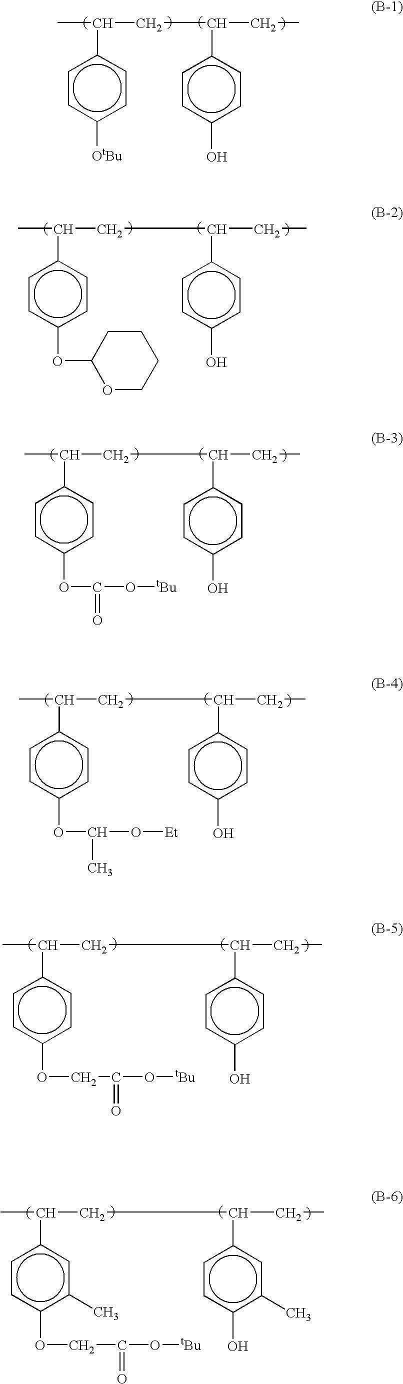

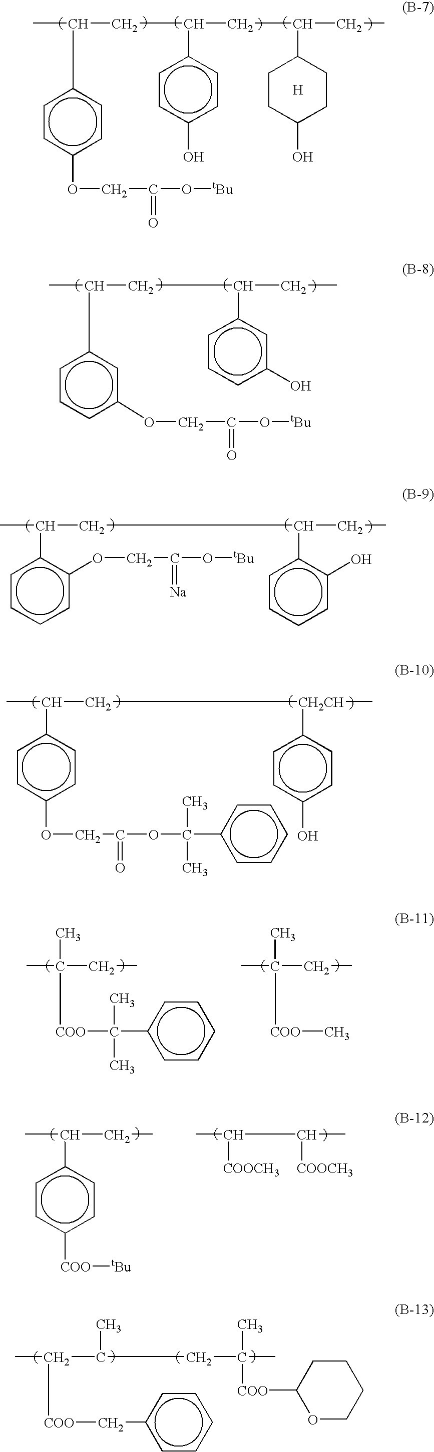

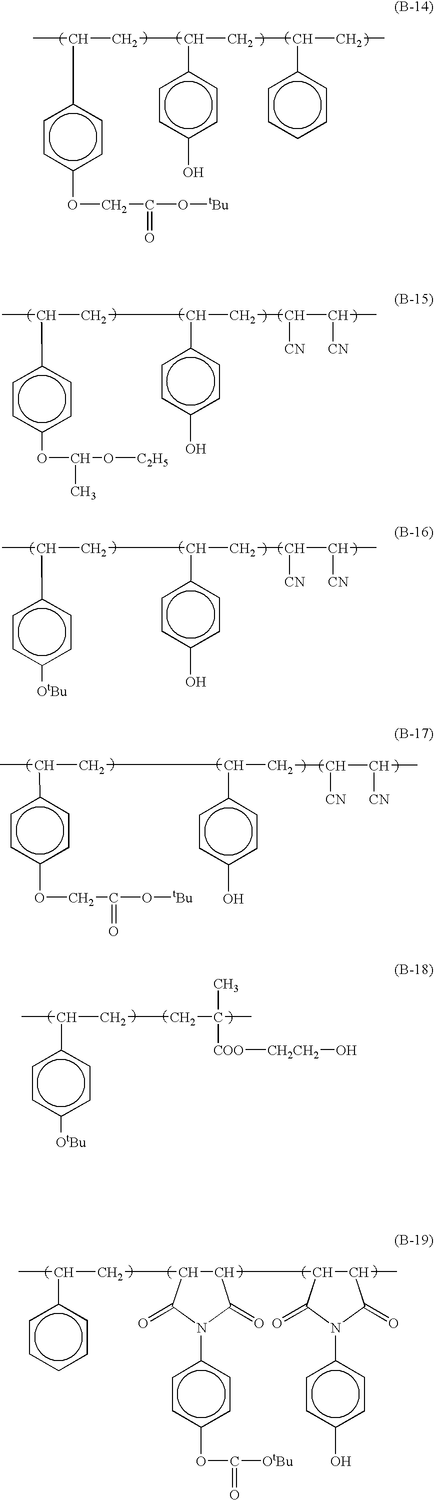

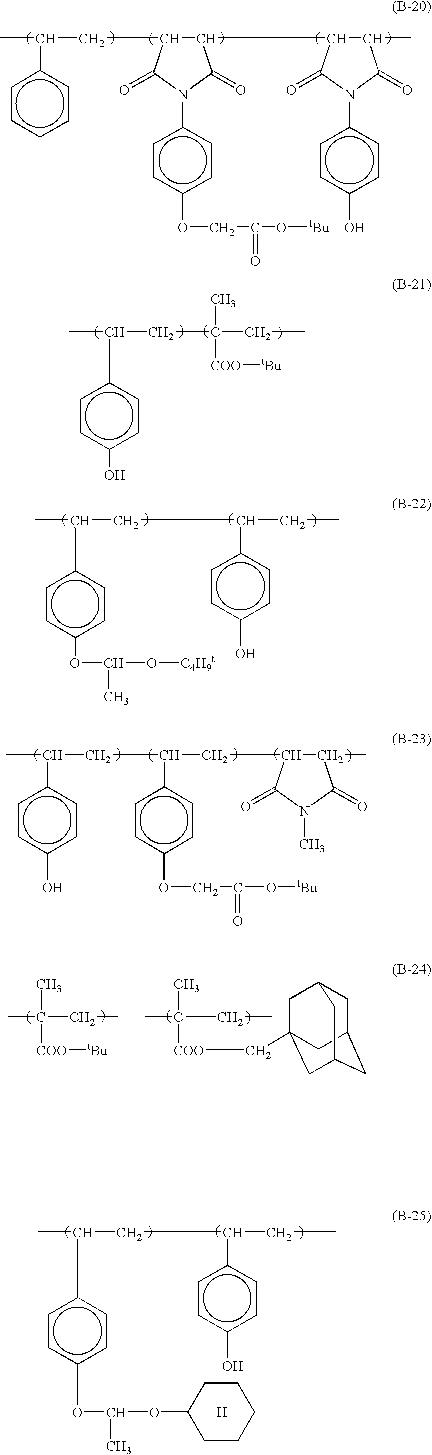

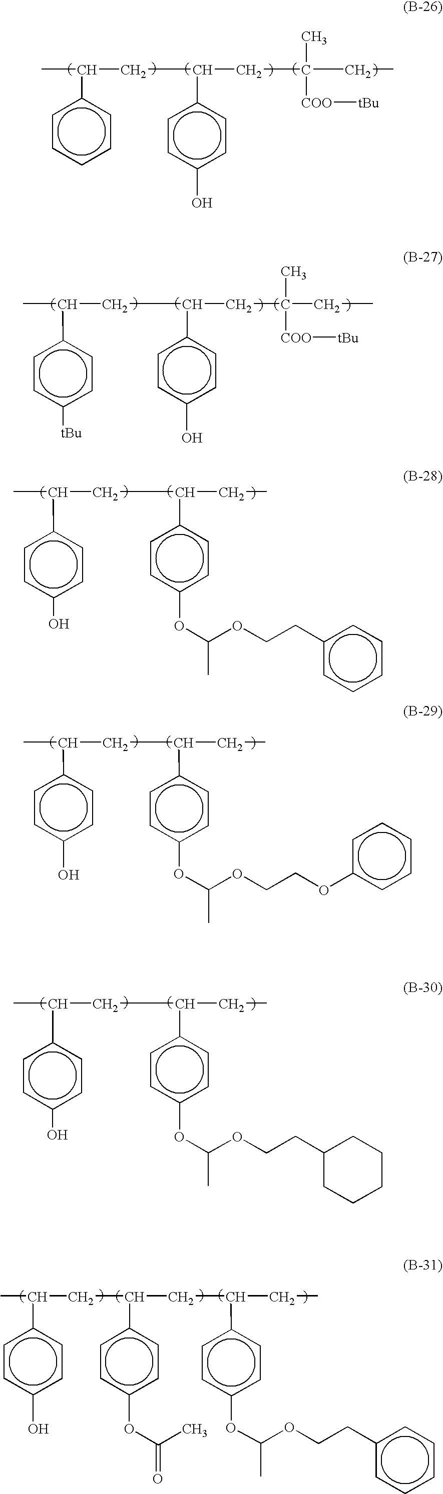

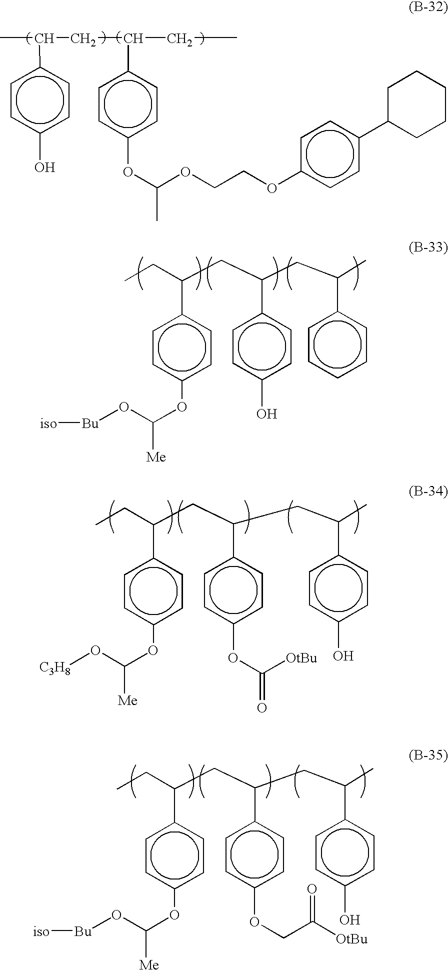

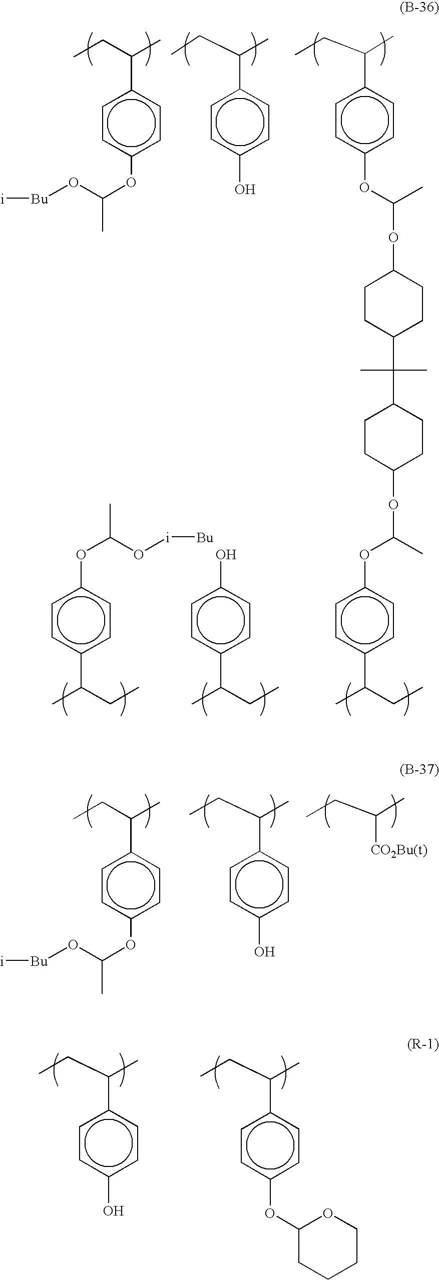

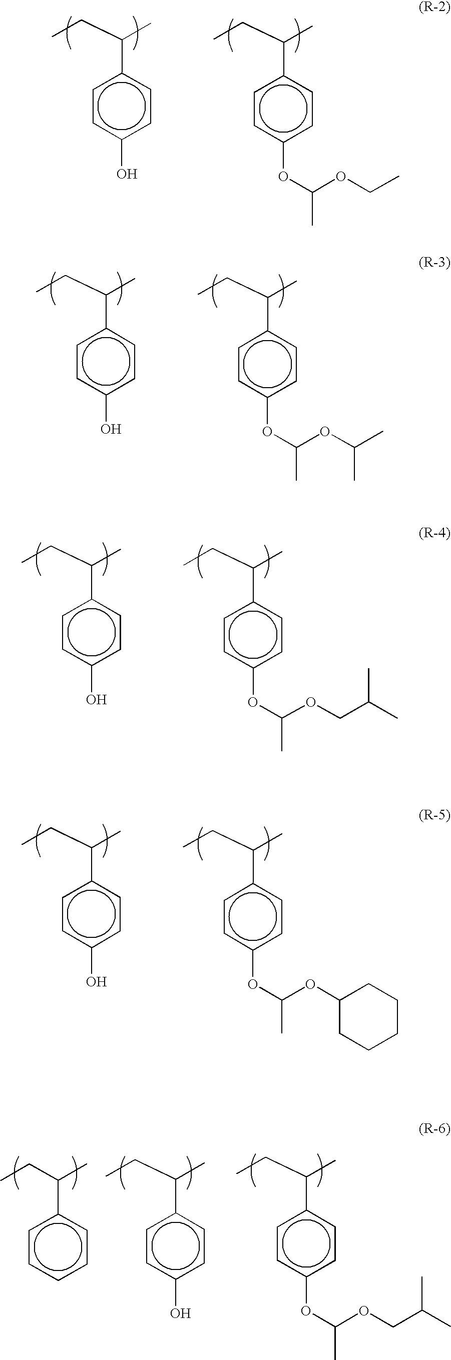

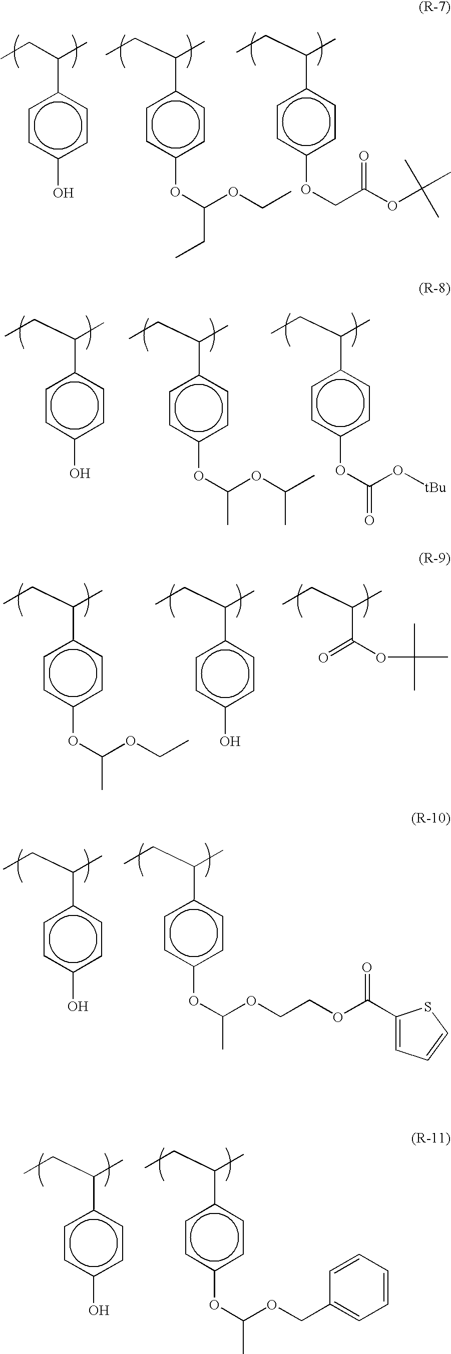

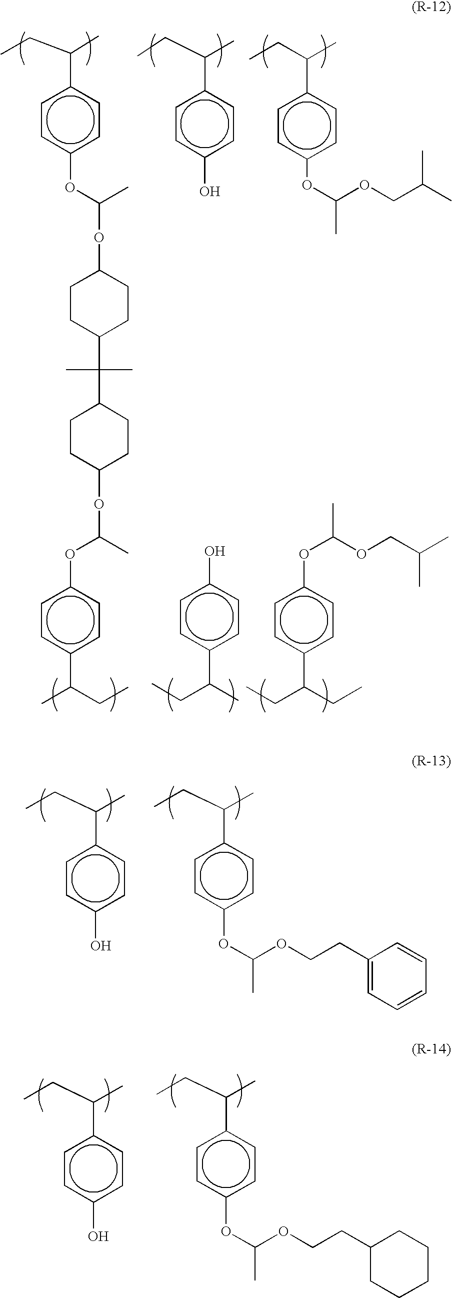

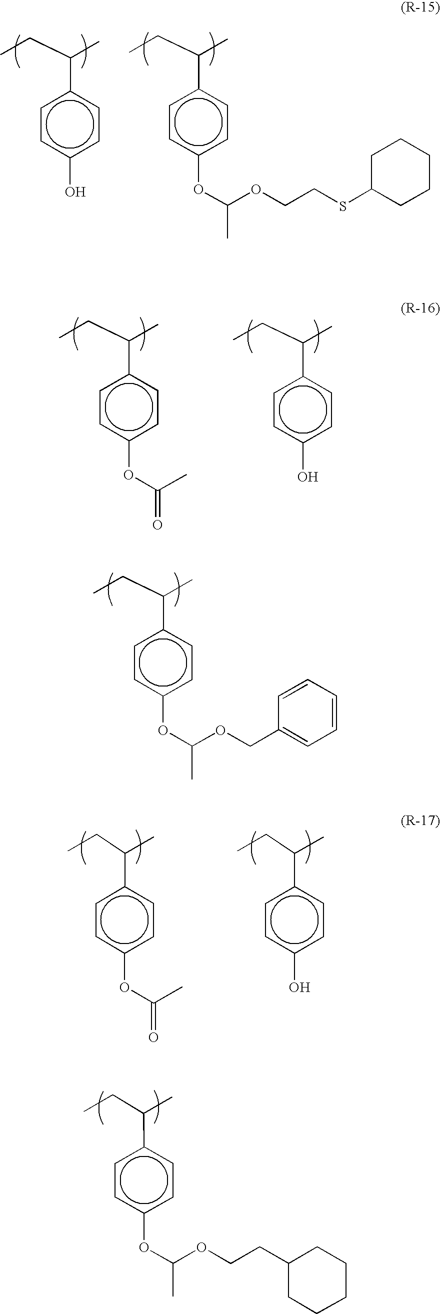

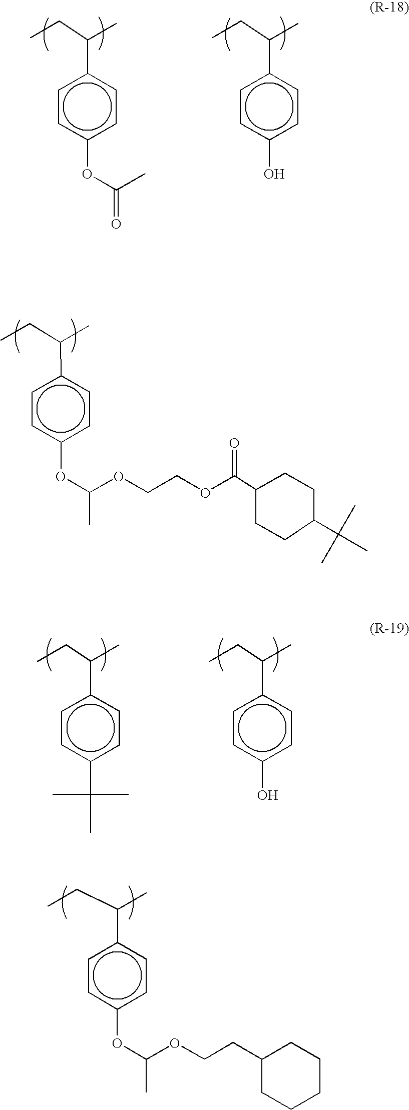

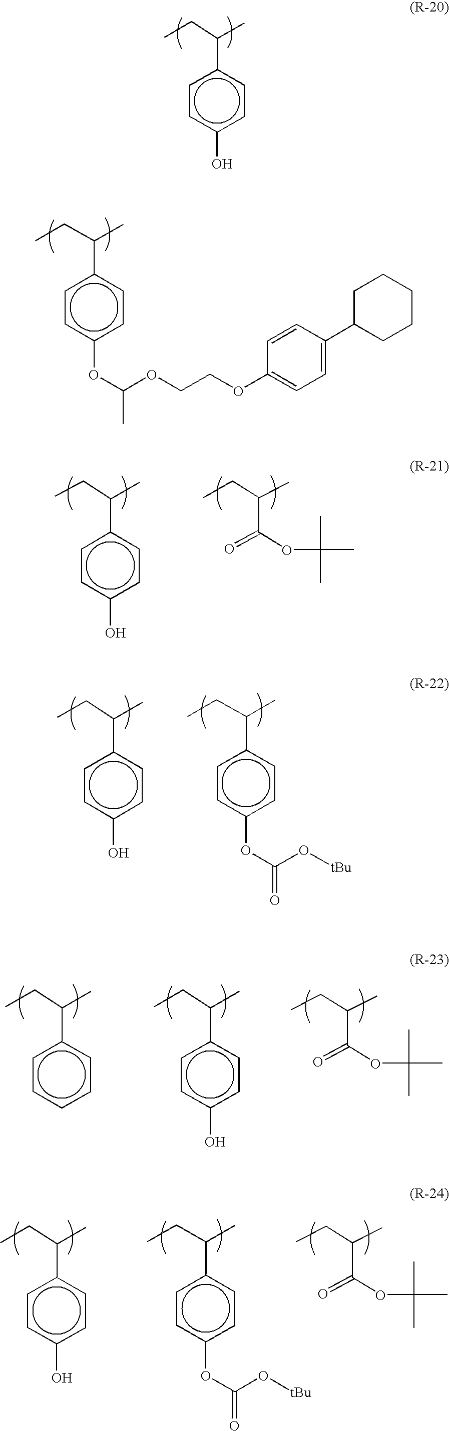

The content of the acid-decomposable group is represented by B/(B+S) where in B represents the number of acid-decomposable groups in the resin and S represents the number of alkali-soluble groups which are not protected by the acid-decomposable group. The content of the acid-decomposable group is preferably from 0.01 to 0.7, more preferably from 0.05 to 0.50, even more preferably from 0.05 to 0.40.

When B/(B+S) is within the above range, it is preferable because film shrinkage, maladhesion to substrate or scum after PEB to disadvantage can be prevented, and a standing wave does not remain on the side wall of pattern to disadvantage.

The weight-average molecular weight (Mw) of the binder resin for positive-working resist composition is preferably from 1,000 to 200,000 from the viewpoint of reduction of film thickness and sensitivity.

The weight-average molecular weight (Mw) of the binder resin for positive-working resist composition is more preferably from 2,000 to 200,000, more preferably from 5,000 to 100,000, even more preferably from 8,000 to 50,000.

The distribution of molecular weight (Mw/Mn) is preferably from 1.0 to 4.0, more preferably from 1.0 to 2.0, particularly from 1.0 to 1.6.

The weight-average molecular weight is defined in polystyrene equivalence determined by gel permeation chromatography.

Two or more binder polymers for positive-working resist composition may be used in combination.

The amount of these acid-decomposable polymers to be incorporated in the positive-working resist composition is properly from 70 to 98% by weight, preferably from 80 to 96% by weight based on the solid content in the resist composition.

[5] Other Components to be Incorporated in the Composition of the Invention

The resist composition of the invention may further comprise a nitrogen-containing basic compound, a dye, a solvent, a surface active agent, a plasticizer, a photo-decomposable basic compound, a photo-base generator, etc. incorporated therein as necessary.

[5]-1 Nitrogen-Containing Basic Compound (Component E)

The desirable nitrogen-containing basic compound which can be used in the invention is a compound having a higher basicity than phenol.

Preferred examples of chemical atmosphere include the following structures (A) to (E). The structures of the formulae (B) to (E) may be a part of the cyclic structure.

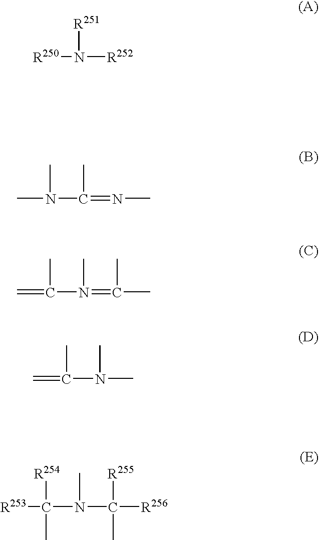

In these formulae, R²⁵⁰, R²⁵¹ and R²⁵² may be the same or different and each represesnt a hydrogen atom, C₁-C₆ alkyl group, C₁-C₆ aminoalkyl group, C₁-C₆ hydroxyalkyl group or C₆-C₂₀ substituted or unsubstituted aryl group. R²⁵¹ and R²⁵² may be bonded to each other to form a ring.

R²⁵³, R²⁵⁴, R²⁵⁵ and R²⁵⁶ may be the same or different and each represent a C₁-C₆ alkyl group.

The nitrogen-containing basic compound is preferably a nitrogen-containing basic compound having two or more nitrogen atoms having different chemical atmospheres per molecule, particularly a compound containing both cyclic structures containing a substituted or unsubstituted amino group and a nitrogen atom or a compound having an alkylamino group.

Specific preferred examples of the nitrogen-containing basic compound include substituted or unsubstituted guanidine, substituted or unsubstituted aminopyridine, substituted or unsubstituted aminoalkylpyridine, substituted or unsubstituted aminopyrrolidine, substituted or unsubstituted indazole and imidazole, substituted or unsubstituted pyrazole, substituted or unsubstituted pyrazine, substituted or unsubstituted pyrimidine, substituted or unsubstituted purine, substituted or unsubstituted imidazoline, substituted or unsubstituted pyrazoline, substituted or unsubstituted piperazine, substituted or unsubstituted aminomorpholine, and substituted or unsubstituted aminoalkylmorpholine. Preferred examples of the substituents on these nitrogen-containing basic compounds include amino group, aminoalkyl group, alkylamino group, aminoaryl group, arylamino group, alkyl group, alkoxy group, acyl group, acyloxy group, aryl group, aryloxy group, nitro group, hydroxyl group, and cyano group.

Particularly preferred Examples of the nitrogen-containing basic compound include guanidine, 1,1-dimethylguanidine, 1,1,3,3-tetramethylguanidine, imidazole, 2-methylimidazole, 4-methylimidazole, N-methylimidazole, 2-phenylimidazole, 4,5-diphenylimidazole, 2,4,5-triphenylimidazole, 2-aminopyridine, 3-aminopyridine, 4-aminopyridine, 2-dimethylaminopyridine,. 4-dimethylaminopyridine, 2-diethylaminopyridine, 2-(aminomethyl) pyridine, 2-amino-3-methylpyridine, 2-amino-4-methylpyridine, 2-amino-5-methylpyridine, 2-amino-6-methylpyridine, 3-aminoethylpyridine, 4-aminoethylpyridine, 3-aminopyrrolidine, piperazine, N-(2-aminoethyl)piperazine, N-(2-aminoethyl)piperidine, 4-amino-2,2,6,6-tetramethylpiperidine, 4-piperidinopiperidine, 2-iminopiperidine, 1-(2-aminoethyl) pyrrolidine, pyrazole, 3-amino-5-methylpyrazole, 5-amino-3-methyl-1-p-tolylpyrazole, pyrazine, 2-(aminomethyl)-5-methyl pyrazine, pyrimidine, 2,4-diaminopyrimidine, 4,6-dihydroxypyrimidine, 2-pyrazoline, 3-pyrazoline, N-aminomorpholine, N-(2-aminoethyl)morpholine, 1,5-diazabicyclo[4.3.0]none-5-ene, and tri-n-butylamine. However, the invention is not limited to these compounds.

These nitrogen-containing basic compounds may be used singly or in combination of two or more thereof.

The molar proportion of the acid generator and the nitrogen-containing basic compound in the composition (acid generator)/(nitrogen-containing basic compound) is preferably from 2.5 to 300. When the molar proportion falls below 2.5, the resulting resin composition can exhibit a lowered sensitivity and hence a deteriorated resolution. On the contrary, when the molar proportion exceeds 300, the resist pattern becomes thicker with time between after exposure and heat treatment and the resolution can be deteriorated. The molar proportion (acid generator)/(nitrogen-containing basic compound) is preferably from 5.0 to 200, more preferably from 7.0 to 150.

[5]-2. Dye

Preferred examples of dyes include oil-based dyes and basic dyes. Specific examples of these dyes include Oil Yellow #101, Oil Yellow #103, Oil Pink #312, Oil Green BG, Oil Blue BOS, Oil Blue #603, Oil Black BY, Oil Black BS, Oil Black T-505 (produced by Orient Chemical Industries, Ltd.), Crystal Violet (CI42555), Methyl Violet (CI42535), Rhodamine B (CI45170B), Malachite Green (CI42000), and Methylene Blue (CI52015).

[5]-3. Solvents

The composition of the invention is applied to a support in the form of solution of the aforementioned various components in a solvent. Examples of the solvent employable herein include ethylene dichloride, cyclohexanone, cyclopentanone, 2-heptanone, γ-butyrolactone, methyl ethyl ketone, ethylene glycol monomethyl ether, ethylene glycol monoethyl ether, 2-methoxyethyl acetate, ethylene glycol monoethyl ether acetate, propylene glycol monomethyl ether, propylene glycol monomethyl ether acetate, toluene, ethyl acetate, methyl lactate, ethyl lactate, methyl methoxypropionate, ethyl ethoxypropionate, methyl pyruvate, ethyl pyruvate, propyl pyruvate, propyl pyruvate, N,N-dimethylformamide, dimethyl sulfoxide, N-methylpyrrolidone, and tetrahydrofurane. These solvents may be used singly or in admixture.

[5]-4. Surface Active Agents

The resist composition of the invention preferably comprises a surface active agents (surfactants) incorporated therein.

The specific examples of surfactants which can be used in the present invention include nonionic surfactants such as polyoxyethylene alkyl ethers (e.g., polyoxyethylene lauryl ether, polyoxyethylene stearyl ether, polyoxyethylene cetyl ether,polyoxyethyleneoleylether), polyoxyethylenealkylaryl ethers (e.g., polyoxyethylene octylphenol ether, polyoxyethylene nonylphenol ether), polyoxyethylene-polyoxypropylene block copolymers, sorbitan fatty acid esters (e.g., sorbitan monolaurate, sorbitan monopalmitate, sorbitan monostearate, sorbitan monooleate, sorbitan trioleate, sorbitan tristearate), and polyoxyethylene sorbitan fatty acid esters (e.g., polyoxyethylene sorbitan monolaurate, polyoxyethylene sorbitan monopalmitate, polyoxyethylene sorbitan monostearate, polyoxyethylene sorbitan trioleate, polyoxyethylene sorbitan tristearate), fluorine-containing surfactants and silicon-containing surfactants, such as Eftop EF301, EF303 and EF352 (produced by Shin-Akita Kasei K.K.), Megafac F171, F173, F176, F189 and R08 (produced by Dainippon ink & Chemicals, Inc.), Florad FC430 and FC431 (produced by Sumitomo 3M, Inc.), Asahi Guard AG710, Surflon S-382, SC101, SC102, SC103, SC104, SC105 and SC106 (produced by Asahi Glass Co., Ltd.), and Troysol S-366 (produced by Troy Chemical Industries, Inc.). In addition, organosiloxane polymer KP-341 (produced by Shin-Etsu Chemical Industry Co., Ltd.), and acrylic acid type or methacrylic acid type (co) polymerization Polyflow No. 75, No. 95 (produced by Kyoeisya Chemical Co., Ltd.) can be used as a surfactant.

The proportion of these surfactants is 2 weight parts or less per 100 weight parts of the solid content in the composition, preferably 1 weight part or less.

These surface active agents may be used singly or in combination.

[5]-5. Plasticizer

Examples of the plasticizer to be incorporated in the resist composition of the invention include compounds described in JP-A-4-212960, JP-A-8-262720, European Patents 735,422, 416,873 and 439,371, and U.S. Pat. No. 5,846,690 such as di(2-ethylhexyl) adipate, n-hexyl benzoate, di-n-octyl phthalate, di-n-butyl phthalate, benzyl-n-butyl phthalate and dihydroabiethyl phthalate.

[5]-6. Photo-Decomposable Basic Compound

The composition of the invention may comprise ammonium salts described in JP-A-7-28247, European Patent 616,258, U.S. Pat. No. 5,525,443, JP-A-9-127700, European Patent 762,207 and U.S. Pat. No. 5,783,354 such as tetramethyl ammonium hydroxide, tetra-n-butyl ammonium hydroxide and betaine incorporated therein, The composition of the invention may also comprise a compound (photo base) capable of reducing basicity upon exposure disclosed in JP-A-5-232706, JP-A-6-11835, JP-A-6-242606, JP-A-6-266100, JP-A-7-333851, JP-A-7-333844, U.S. Pat. No. 5,663,035 and European Patent 677,788 incorporated therein.

[5]-7. Photo-Base Generator

Examples of the photo-base generator which can be incorporated in the composition of the invention include compounds disclosed in JP-A-4-151156, JP-A-4-162040, JP-A-5-197148, JP-A-5-5995, JP-A-6-194834, JP-A-8-146608, JP-A-10-83079, and European Patent 622,682. Specific preferred examples of these compounds include 2-nitrobenzyl carbamate, 2,5-dinitrobenzylcyclohexyl carbamate, N-cyclohexyl-4-methylphenyl sulfonamide, and 1,1-dimethyl-2-phenylethyl-N-isopropyl carbamate. These photo-base generators may be incorporated for the purpose of improving the shape of resist pattern.

The resist composition of the invention is applied to a substrate to form a thin layer. The thickness of the coat layer is preferably from 0.1 μm to 4.0 μm.

In the invention, commercially available inorganic or organic anti-reflection layers may be used as, necessary. An anti-reflection layer may be applied to the upper layer of the resist.

As the anti-reflection layer which can be used as the lower layer of the resist there may be used either an inorganic model of titanium, titanium dioxide, titanium nitride, chromium oxide, carbon and amorphous silicon or an organic model made of an light absorber and a polymer material. The production of the former requires facilities such as vacuum metallizer, CVD device and sputtering device. Examples of the organic anti-reflection layer include those made of condensate of diphenylamine derivative and formaldehyde-modified melamine resin, alkali-soluble resin and light absorber disclosed in JP-B-7-69611, those made of product of reaction of maleic anhydride copolymer with diamine-based light absorber disclosed in U.S. Pat. No. 5,294,680, those containing a resin binder and a methylol melamine-based heat crosslinking agent disclosed in JP-A-6-118631, acrylic resin-based anti-reflection films having carboxylate group, epoxy group and light-absorbing group in the same molecule disclosed in JP-A-6-118656, those made of methylol melamine and benzophenone-based light absorber disclosed in JP-A-8-87115, and those having a low molecular light absorber incorporated in a polyvinyl alcohol resin disclosed in JP-A-8-179509.

As the organic anti-reflection films there may be also used commercially available organic anti-reflection films such as DUV30 Series and EUV-40 Series (produced by Brewer Science Inc.) and AR-2, AR-3 and AR-5 (produced by Ciprey Inc.).

In the production of precision integrated circuit elements, the formation of pattern on the resist layer can be carried out by a process which comprises applying the resist composition of the invention on the substrate (e.g., silicon/silicon dioxide film, glass substrate, metal substrate) directly or with the aforementioned anti-reflection film provided interposed therebetween, irradiating the coated material with excimer laser beam, electron ray or beam from X-ray drawing device, heating the material, developing the material, rinsing the material, and then drying the material. In this manner, a good resist pattern can be formed. As the exposing light source there is preferably used a device using electron ray or X ray as an exposing light source.

As the developer for the resist composition of the invention there may be used an aqueous solution of an alkali such as inorganic alkali (e.g., sodium hydroxide, potassium hydroxide, sodium carbonate, sodium silicate, sodium metasilicate, aqueous ammonia), primary amine (e.g., ethylamine, n-propylamine), secondary amine (e.g., diethylamine, di-n-butylamine), tertiary amine (e.g., triethylamine, methyldiethylamine), alcoholamine (e.g., dimethylethanolamine, triethanolamine), quaternary ammonium salt (e.g., tetramethylammoniumhydroxide, tetraethylammonium hydroxide, choline) and cyclic amine (e.g., pyrrole, piperidine). Alternatively, an aqueous solution of such an alkali having an alcohol such as isopropyl alcohol or a surface active agent such as nonionic surface active agent incorporated therein in a proper amount may be used.

Preferred among these developers are tertiary ammonium salts, more preferably tetramethylammonium hydroxide and choline.

### EXAMPLE

The invention will be further described in the following examples, but the invention is not limited thereto.

### Examples of Negative-Working Resist Composition

### 1. Examples of Synthesis of Constituting Elements

(1) Binder Resin

### Synthesis Example 1 (Synthesis of Resin Example (27))

3.9 g (0.024 mol) of 4-acetoxystyrene and 0.8 g (0.006 mol) of 4-methoxystyrene were dissolved in 30 ml of 1-methoxy-2-propanol. To the solution thus obtained were then added dropwise a solution of 50 mg of 2,2′-azobis(2,4-dimethylvaleronitrile) as a polymerization initiator (trade name: V-65, produced by Wako Pure Chemical Industries, Ltd.), 9.1 g (0.056 mol) of 4-acetoxystyrene and 1.9 g (0.014 mol) of 4-methoxystyrene in 70 ml of 1-methoxy-2-propanol at 70° C. with stirring in a nitrogen stream in 2 hours. After two hours, 50 mg of the polymerization initiator was added. The reaction was further continued for 2 hours. Thereafter, the reaction solution was heated to 90° C. where it was then further stirred for 1 hour. The reaction solution was allowed to cool, and then poured into 1 l of water with vigorous stirring to cause the precipitation of a white resin. The resin thus obtained was dried, and then dissolved in 100 ml of methanol. To the solution was then added 25% tetramethylammonium hydroxide so that the acetoxy group in the resin was hydrolyzed. The solution was then neutralized with an aqueous solution of hydrochloric acid to cause the precipitation of a white resin. The white resin thus precipitated was washed with ion-exchanged water, and then dried under reduced pressure to obtain 11.6 g of the resin (27) of the invention. The resin thus obtained was then measured for molecular weight by GPC. As a result, the resin showed a weight-average molecular weight (Mw: in polystyrene equivalence) of 9,200 and a molecular weight dispersion (Mw/Mn) of 2.2.

Various binder resins were synthesized in the same manner as described above.

(2) Compound (B)

Synthesis of Crosslinking Agent [HM-1]

20 g of 1-[α-methyl-α-(4-hydroxyphenyl)ethyl]-4-[α, α-bis(4-hydroxyphenyl)ethyl]benzene (Trisp-PA, produced by HONSHU CHEMICAL INDUSTRY CO., LTD.) were added to a 10% aqueous solution of potassium hydroxide. The mixture was then stirred to make a solution. Subsequently, to this solution was gradually added 60 ml of a 37% aqueous solution of formalin at room temperature in 1 hour. The mixture was stirred at room temperature for 6 hours, and then put into a diluted aqueous solution of sulfuric acid. The resulting precipitated material was filtered, thoroughly washed with water, and then recrystallized with 30 ml of methanol to obtain 20 g of a phenol derivative having a hydroxymethyl group having the following structure [HM-1] in the form of white powder. The purity of the phenol derivative was 92% (as determined by liquid chromatography).

Synthesis of [MM-1]

20 g of the phenol derivative having a hydroxymethyl group thus obtained [HM-1] was added to 1 l of methanol. The mixture was then heated with stirring to make a solution. Subsequently, to this solution was added 1 ml of concentrated sulfuric acid. The mixture was then heated under reflux for 12 hours. After the termination of the reaction, the reaction solution was then cooled. To the solution was then added 2 g of potassium carbonate. The mixture was then thoroughly concentrated. To the solution was then added 300 ml of ethyl acetate. The solution was washed with water, and then concentrated to dryness to obtain 22 g of a phenol derivative having a methoxymethyl group having the following structure [MM-1] in the form of white solid. The purity of the phenol derivative was 90% (as determined by liquid chromatography).

The following phenol derivatives were synthesized in the same manner as mentioned above.

(3) Acid Generator (C)

Synthesis Example 1 (Synthesis of Acid Generator (A-2))

To 200 ml of methylene chloride was added 17.6 g (80 mmol) of iodosil benzene. The mixture was then stirred. To the resulting suspension was then added dropwise 14 ml (160 mmol) of trifluoromethanesulfonic acid. The mixture was then stirred for 3 hours. To the mixture was then added dropwise 6.24 g (80 mmol) of benzene. The mixture was then stirred for 2 hours. The resulting precipitate was with drawn by filtration, washed with ether, and then dried. Thus, 1,4-bis[phenyl[trifluoromethanesulfonyl]oxy]iodo]benzene was obtained.

31.6 g (40 mmol) of

1,4-bis[phenyl[(trifluoromethanesulfonyl)oxy)iodo]benzene, 360 mg (2 mmol) of copper acetate (II) and 54.4 ml (330 mmol) of diphenyl sulfide were suspended, and then stirred at 200° C. for 30 minutes. The solution was allowed to cool to room temperature, washed with ether, and then dried to obtain an acid generator (A-2).

Acid generators were synthesized in the same manner as mentioned above.

### 2. Example

### Example 1

(1) Preparation and Spreading of Negative-Working Resist Solution

| | |
|---|---|
| Binder resin: Resin (27) | 0.70 g |
| compound (A): a-37 | 0.0025 g |
| Compound (B): Crosslinking agent MM-1 | 0.25 g |
| Compound (C): Acid generator C-1 | 0.04 g |
| Component (E): OE-1 | 0.002 g |
| Surface active agent | 0.001 g |
| Other acid generator: z1 | 0.02 g |

The aforementioned components were dissolved in 8.5 g of propylene glycol monomethyl ether acetate. The solution thus obtained was subjected to precise filtration through a membrane filter having a pore diameter of 0.1 μm to obtain a negative-working resist solution.

The negative-working resist solution thus obtained was spread over a 6 inch wafer using a spin coater Mark 8 produced. by TOKYO ELECTRON LIMITED, and then dried at a temperature of 110° C. over a hot plate for 90 seconds to obtain a resist layer having a thickness of 0.3 μm.

(2) Preparation of Negative-Working Resist Pattern

The resist layer, thus obtained was then irradiated with beam from an electron ray drawing device (HL750, produced by Hitachi, Ltd.; accelerating voltage: 50 KeV). The resist layer thus irradiated was heated to a temperature of 110° C. over a hot plate for 90 seconds, dipped in a 2.38 wt-% tetramethyl ammonium hydroxide (TMAH) for 60 seconds, rinsed with water for 30 seconds, and then dried. The pattern thus obtained was then evaluated for sensitivity, resolution and pattern profile in the following manner.

(2-1) Sensitivity

The shape of the section of the pattern thus obtained was observed under a scanning electron microscope (S-4300, produced by Hitachi, Ltd.). The exposure (dose of electron ray) at which a 0.15 μm pattern (line:space=1:1) is resolved was defined as sensitivity.

(2-2) Resolution

The limited resolving power (allowing line and space to be separated and resolved) at the exposure at which the aforementioned sensitivity is obtained was defined as resolution.

(2-3) Pattern Profile

The shape of the section of 0.15 μm line pattern at the exposure at which the aforementioned sensitivity is obtained was observed under a scanning electron microscope (S-4300, produced by Hitachi, Ltd.). The results were evaluated according to a 5-step criterion (skirted bottom, slightly skirted bottom, rectangular section, slightly rounded top, rounded top).

### Examples 2 to 13

The procedure of preparation of negative-working resist solution and formation of negative-working resist pattern of Example 1 was followed except that the various components set forth in Table 1 were used. The results of evaluation are set forth in Table 2.

### Comparative Examples 1 to 8

The procedure of preparation of negative-working resist solution and formation of negative-working resist pattern of Example 1 was followed except that the acid generator (C) of the invention or the compound (A) of the invention was not used and the various components set forth in Table 1 were used. The results of evaluation are set forth in Table 2.

In Table 2 below, (Epc (C)-Epa (B)) value of the negative-working resist compositions of Examples 1 to 13 and Comparative Examples 1 to 8 are set forth.

TABLE 1

| | | Component | | | | | Surface |
|---|---|---|---|---|---|---|---|
| | | (C)/other | | | | | active |
| | Resin | acid | Component | Component | Component | | agent |
| | 0.70 g | generators | (B) | (A) | (E) | Solvent | 0.001 g |
| Example 1 | (27) Mw = 7500 | C-1 0.04 g | MM-1 | a-37 | OE-1 | S-1 8.5 g | W-1 |
| | x/y = 85/15 Mw/Mn = 1.7 | z1 0.02 g | 0.25 g | 0.0025 g | 0.002 g | | |
| Example 2 | (1) Mw = 11000 | C-5 0.06 g | MM-1 | a-38 | OE-1 | S-1 7.0 g | W-1 |
| | Mw/Mn = 1.4 | | 0.25 g | 0.0025 g | 0.002 g | S-2 1.5 g | |
| Example 3 | (29) Mw = 8000 | C-3 0.03 g | MM-1 | a-27 | OE-1 | S-1 0.5 g | W-1 |
| | x/y = 80/20 Mw/Mn = 2.0 | z4 0.03 g | 0.25 g | 0.0020 g | 0.002 g | | |
| Example 4 | (1) Mw = 6000 | C-7 0.07 g | MM-2 | a-44 | OE-2 | S-1 7.0 g | W-1 |
| | Mw/Mn = 1.5 | | 0.20 g | 0.030 g | 0.002 g | S-2 3.5 g | |
| Example 5 | (93) Mw = 9000 | C-2 0.06 g | MM-1 | a-1 | OE-3 | S-1 8.5 g | — |
| | x/y = 85/15 Mw/Mn = 1.12 | | 0.20 g | 0.050 g | 0.002 g | | |
| Example 6 | (94) Mw = 12000 | C-4 0.04 g | MM-3 | a-47 | OE-3 | S-2 8.5 g | W-2 |
| | x/y = 90/10 Mw/Mn = 2.0 | | 0.25 g | 0.0022 g | 0.002 g | | |
| Example 7 | (96) Mw = 7000 | C-2 0.04 g | MM-4 | a-48 | OE-1 | S-1 7.0 g | W-2 |
| | x/y = 90/10 Mw/Mn = 2.2 | | 0.30 g | 0.0015 g | 0.002 g | S-2 1.5 g | |
| Example 8 | (15) Mw = 12800 | C-3 0.02 g | MM-1 | a-2 | OE-1 | S-1 7.0 g | W-1 |
| | Mw/Mn = 1.8 | | 0.30 g | 0.0025 g | 0.002 g | S-2 1.5 g | |
| Example 9 | (1) Mw = 15000 | C-5 0.06 g | MM-1 | a-36 | OE-2 | S-1 7.0 g | W-1 |
| | Mw/Mn = 1.4 | | 0.25 g | 0.0025 g | 0.002 g | S-2 1.5 g | |
| Example 10 | (2) Mw = 9000 | C-6 0.04 g | MM-4 | a-28 | OE-4 | S-1 7.0 g | W-2 |
| | Mw/Mn = 1.6 | | 0.30 g | 0.0018 g | 0.002 g | S-2 1.5 g | |
| Example 11 | (25) Mw = 7800 | C-1 0.12 g | MM-4 | a-37 | OE-4 | S-1 8.5 g | W-1 |
| | x/y = 90/20 Mw/Mn = 1.9 | | 0.30 g | 0.0009 g | 0.002 g | | |
| Example 12 | (31) Mw = 10500 | C-1 0.02 g | MM-1 | a-37 | — | S-1 2.0 g | W-1 |
| | x/y = 90/10 Mw/Mn = 1.7 | C-6 0.05 g | 0.20 g | 0.0020 g | | S-2 6.5 g | |
| Example 13 | (32) M = 7500 | C-1 0.07 g | MM-3 | a-9 | — | S-1 7.0 g | W-1 |
| | x/y = 95/5 Mw/Mn = 2.0 | | 0.25 g | 0.0022 g | S-2 1.5 g | | |
| Comparative | (39) Mw = 8000 | z1 0.05 g | MM-4 | a-1 | OE-3 | S-1 7.0 g | W-2 |
| Example 1 | x/y = 95/5 Mw/Mn = 1.8 | | 0.30 | 0.0025 g | 0.002 g | S-2 1.5 g | |
| Comparative | (28) Mw = 13500 | z1 0.07 g | MM-4 | a-34 | OE-1 | S-1 8.5 g | W-2 |
| Example 2 | x/y = 90/10 Mw/Mm = 1.5 | | 0.30 g | 0.0025 g | 0.002 g | | |
| Comparative | (60) Mw = 9500 | z10 0.07 g | MM-1 | a-41 | OE-3 | S-1 8.0 g | W-1 |
| Example 3 | x/y/z = 90/5/5 | | 0.20 g | 0.0025 g | 0.002 g | S-2 0.5 g | |
| | Mw/Mm = 2.0 | | | | | | |
| Comparative | (41) Mw = 6000 | C-1 0.05 g | MM-3 | — | OE-1 | S-1 7.0 g | W-1 |
| Example 4 | x/y = 85/15 Mw/Mn = 1.35 | | 0.25 g | | 0.002 g | S-2 1.5 g | |
| Comparative | (95) Mw = 6500 | z1 0.05 g | MM-2 | — | OE-2 | S-1 7.0 g | W-2 |
| Example 5 | x/y = 90/10 Mw/Mn = 1.9 | | 0.20 g | | 0.002 g | S-2 1.5 g | |
| Comparative | (97) Mw = 6800 | C-1 0.03 g | MM-4 | — | — | S-1 8.0 g | W-2 |
| Example 6 | Mw/Mn = 2.2 | z1 0.03 g | 0.30 g | | | S-2 0.5 g | |
| Comparative | (33) Mw = 6800 | C-1 0.05 g | MM-1 | — | — | S-1 7.0 g | W-2 |
| Example 7 | x/y = 90/10 Mw/Mn = 1.6 | | 0.20 g | | | S-2 1.5 g | |
| Comparative | (29) Mw = 8000 | z1 0.05 g | MM-3 | — | — | S-1 8.5 g | — |
| Example 8 | x/y = 80/20 Mw/Mn = 2.0 | | 0.25 g | | | | |

In Table 1, the nitrogen-containing basic compound which is the component (E) indicates the followings (all produced by Tokyo Kasei Kogyo Co., Ltd.).

OE-1: 1,5-Diazabicyclo[4.3.0]none-5-ene;

OE-2: 2,4,5-Triphenylimidazole;

OE-3: 4-Dimethylaminopyridine;

OE-4: Tri-n-butylamine;

The solvent in Table 1 indicates the followings.

S-1: Propylene glycol monomethyl ether acetate;

S-2; Propylene glycol monomethyl ether

The surface active agent in Table 1 indicates the followings;

W-1; Megafac F176 (produced by Dainippon DAINIPPON INK AND CHEMICALS, INCORPORATED);

W-2: Siloxane polymer KP341 (produced by Shin-Etsu Chemical Co., Ltd.)

TABLE 2

| | Epc (C) − | Resolution | Sensitivity | Pattern |
|---|---|---|---|---|
| | Epa (B) | (μm) | (μC/cm²) | profile |
| Example 1 | +0.45 V | 0.065 | 2.2 | Rectangular |
| Example 2 | +0.45 V | 0.060 | 2.0 | Rectangular |
| Example 3 | +0.45 V | 0.065 | 2.2 | Rectangular |
| Example 4 | +0.45 V | 0.065 | 1.5 | Rectangular |
| Example 5 | +0.45 V | 0.060 | 1.5 | Rectangular |
| Example 6 | +0.45 V | 0.065 | 2.4 | Rectangular |
| Example 7 | +0.35 V | 0.060 | 1.2 | Rectangular |
| Example 8 | +0.45 V | 0.065 | 3.0 | Rectangular |
| Example 9 | +0.45 V | 0.065 | 2.0 | Rectangular |
| Example 10 | +0.35 V | 0.065 | 2.1 | Rectangular |
| Example 11 | +0.35 V | 0.065 | 1.8 | Rectangular |
| Example 12 | +0.45 V | 0.065 | 1.6 | Slightly |
| | | | | skirted |
| | | | | bottom |
| Example 13 | +0.45 V | 0.065 | 2.6 | Slightly |
| | | | | skirted |
| | | | | bottom |
| Comparative | −0.51 V | 0.090 | 7.0 | Rectangular |
| Example 1 | | | | |
| Comparative | −0.51 V | 0.095 | 7.2 | Rectangular |
| Exanp 2 | | | | |
| Comparative | −0.30 V | 0.090 | 7.6 | Rectangular |
| Example 3 | | | | |
| Comparative | — | 0.095 | 8.0 | Slightly |
| Example 4 | | | | rounded top |
| Comparative | — | 0.090 | 7.8 | Slightly |
| Example 5 | | | | rounded top |
| Comparative | — | 0.120 | 5.0 | Rounded top + |
| Example 6 | | | | skirted |
| | | | | bottom |
| Comparative | — | 0.115 | 4.9 | Rounded top + |
| Example 7 | | | | skirted |
| | | | | bottom |
| Comparative | — | 0.120 | 4.7 | Rounded top + |
| Example 8 | | | | skirted |
| | | | | bottom |

### Examples of Positive-Working Resist Composition

Synthesis of Binder-Resin (B-1)

10 g of a poly(p-hydroxystyrene) (VP-8000, produced by NIPPON SODA CO., LTD.) was dissolved in 50 ml of pyridine. To the solution was then added drop wise 3.63 g of di-t-butyl bicarbonate with stirring at room temperature.

The mixture was then stirred at room temperature for 3 hours. The solution was then added dropwise to a solution of 20 g of concentrated hydrochloric acid in 1 l of ion-exchanged water. The powder thus precipitated was withdrawn by filtration, washed with water, and then dried to obtain a resin example (B-1). Other resins were synthesized in the same manner as mentioned above.

### Examples 14 to 20 and Comparative Examples 9 to 16

The same components as used in Examples 1 to 13 (compounds (A) and (B), acid generator (C), nitrogen-containing basic compound (E), solvent, surface active agent) were used except that binder resins for positive-working resist composition were used instead of the binder resins for negative-working resist composition used in Examples 1 to 13.

(1) Spreading of Resist Composition

The various components set forth in Table 3 were each dissolved in 8.5 g of solvents to prepare resist composition solutions.

The various sample solutions thus obtained were each subjected to precise filtration through a membrane filter having a pore diameter of 0.1 μm to obtain resist solutions.

These resist solutions were each spread over a 6 inch silicon wafer using a spin coater Mark 8 produced by TOKYO ELECTRON LIMITED, and then baked at a temperature of 110° C. for 90 seconds to obtain a uniform layer having a thickness of 0.30 μm.

(2) Preparation and Evaluation of Resist Pattern

The resist layer thus obtained was then irradiated with beam from an electron ray drawing device (HL750, produced by Hitachi, Ltd.; accelerating voltage: 50 KeV). The resist layer thus irradiated was baked at a temperature of 110° C. for 90 seconds, dipped in a 2.38 wt-% tetramethyl ammonium hydroxide (TMAH) for 60 seconds, rinsed with water for 30 seconds, and then dried. The pattern thus obtained was then evaluated in the following manner.

(2-1) Sensitivity

The shape of the section of the pattern thus obtained was observed under a scanning electron microscope. The minimum radiation energy at which a 0.15 μm pattern (line:space 1:1) is resolved was defined as sensitivity.

(2-2) Resolution

The limited resolving power (allowing line and space to be separated and resolved) at the dose at which the aforementioned sensitivity is obtained was defined as resolution.

(2-3) Pattern Profile

The shape of the section of 0.15 μm line pattern at the dose at which the aforementioned sensitivity is obtained was observed under a scanning electron microscope. The results were evaluated according to a 5-step criterion (skirted bottom, slightly skirted bottom, rectangular section, slightly rounded top, rounded top).

The results of evaluation are set forth in Table 4.

In Table 4 below, (Epc(C)-Epa(B)) value of the negative-working resist compositions of Examples 14 to 20 and Comparative Examples 9 to 16 are set forth.

TABLE 3

| | | Component | | | | | Surface |
|---|---|---|---|---|---|---|---|
| | | (C)/other | | | | | active |
| | Resin | acid | Component | Component | Component | | agent |
| | 0.70 g | generators | (B) | (A) | (E) | Solvent | 0.001 g |
| Example 14 | B-21 Mw = 9000 | C-5 0.05 g | dd-1 | a-37 | OE-1 | S-1 8.5 g | W-1 |
| | x/y = 75/25 | | 0.20 g | 0.0025 g | 0.002 g | | |
| | Mw/Mn = 1.5 | | | | | | |
| Example 15 | B-37 M = 8000 | C-1 0.06 g | dd-4 | a-38 | OE-2 | S-1 7.0 g | W-1 |
| | x/y = 30/70 | | 0.15 g | 0.0025 g | 0.002 g | S-2 1.5 g | |
| | Mw/Mn = 1.9 | | | | | | |
| Example 16 | B-7 | C-3 0.06 g | dd-2 | a-2 | OE-3 | S-1 8.5 g | W-1 |
| | Mw = 8000 | | 0.25 g | 0.0020 g | 0.002 g | | |
| | x/y/z = 18/65/17 | | | | | | |
| | Mw/Mn = 2.0 | | | | | | |
| Example 17 | B-28 Mw = 6000 | C-7 0.07 g | dd-3 | a-44 | OE-1 | S-1 5.0 g | W-1 |
| | x/y = 75/25 | | 0.10 g | 0.030 g | 0.002 g | S-2 3.5 g | |
| | Mw/Mn = 1.15 | | | | | | |
| Example 18 | B-32 | C-2 0.04 g | dd-4 | a-19 | OE-1 | S-1 8.5 g | — |
| | Mw = 12000 | z2 0.02 g | 0.20 g | 0.050 g | 0.002 g | | |
| | x/y/z = 75/10/15 | | | | | | |
| | Mw/Mn = 1.2 | | | | | | |
| Example 19 | B-32 | C-4 0.04 g | dd-2 | a-47 | OE-3 | S-2 8.5 g | W-2 |
| | Mw = 12000 | | 0.04 g | 0.0022 g | 0.002 g | | |
| | x/y = 85/15 | | | | | | |
| | Mw/Mn = 1.12 | | | | | | |
| Example 20 | B-30 | C-2 0.11 g | dd-3 | a-48 | — | S-1 7.0 g | W-2 |
| | Mw = 7000 | | 0.20 g | 0.0025 g | | S-2 1.5 g | |
| | x/y = 80/20 | | | | | | |
| | Mw/Mn = 2.2 | | | | | | |
| Comparative | B-1 Mw = 9000 | z1 0.05 g | dd-1 | a-1 | OE-3 | S-1 7.0 g | W-2 |
| Example 9 | x/y = 25/75 | | 0.20 g | 0.0025 g | 0.002 g | S-2 1.5 g | |
| | Mw/Mn = 1.5 | | | | | | |
| Comparative | B-1 Mw = 9000 | z10 0.07 g | — | a-34 | OE-3 | S-1 8.5 g | W-2 |
| Example 10 | x/y = 25/75 | | | 0.0025 g | 0.002 g | | |
| | Mw/Mn = 1.5 | | | | | | |
| Comparative | B-1 Mw = 9000 | C-1 0.05 g | — | a-41 | OE-1 | S-1 8.0 g | W-1 |
| Example 11 | x/y = 25/75 | | | 0.0025 g | 0.002 g | S-2 0.5 g | |
| | Mw/Mn = 1.5 | | | | | | |
| Comparative | B-1 Mw = 9000 | C-1 0.05 g | dd-1 | — | OE-1 | S-1 7.0 g | W-1 |
| Example 12 | x/y = 25/75 | | 0.20 g | | 0.002 g | S-2 1.5 g | |
| | Mw/Mn = 1.5 | | | | | | |
| Comparative | B-1 Mw = 9000 | C-1 0.05 g | dd-1 | — | OE-1 | S-1 7.0 g | W-2 |
| Example 13 | x/y = 25/75 | | 0.20 g | | 0.002 g | S-2 1.5 g | |
| | Mw/Mn = 1.5 | | | | | | |
| Comparative | B-1 Mw = 9000 | z1 0.05 g | dd-1 | — | OE-4 | S-1 8.0 g | W-2 |
| Example 14 | x/y = 25/75 | | 0.20 g | | 0.002g | S-2 0.5 g | |
| | Mw/Mn = 1.5 | | | | | | |
| Comparative | B-1 M = 9000 | C-1 0.05 g | dd-1 | — | — | S-1 7.0 g | W-2 |
| Example 15 | x/y = 25/75 | | 0.20 g | | | S-2 1.5 g | |
| | Mw/Mn = 1.5 | | | | | | |
| Comparative | B-1 Mw = 9000 | z1 0.05 g | dd-1 | — | — | S-1 8.5 g | — |
| Example 16 | x/y = 25/75 | | 0.20 g | | | | |
| | Mw/Mn = 1.5 | | | | | | |

TABLE 4

| | Epc (C) − | Resolution | Sensitivity | Pattern |
|---|---|---|---|---|
| | Epa (B) | (μm) | (μC/cm²) | profile |
| Example 14 | +0.15 V | 0.075 | 2.4 | Rectangular |
| Example 15 | +0.15 V | 0.070 | 2.2 | Rectangular |
| Example 16 | +0.15 V | 0.070 | 2.6 | Rectangular |
| Example 17 | +0.15 V | 0.070 | 1.4 | Rectangular |
| Example 18 | +0.05 V | 0.075 | 1.2 | Rectangular |
| Example 19 | −0.15 V | 0.070 | 2.6 | Rectangular |
| Example 20 | +0.15 V | 0.070 | 1.6 | Slightly |
| | | | | skirted |
| | | | | bottom |
| Comparative | −0.71 V | 0.095 | 7.2 | Rectangular |
| Example 9 | | | | |
| Comparative | — | 0.095 | 7.2 | Rectangular |
| Example 10 | | | | |
| Comparative | — | 0.095 | 7.5 | Rectangular |
| Example 11 | | | | |
| Comparative | +0.15 V | 0.095 | 7.4 | Slightly |
| Example 12 | | | | rounded top |
| Comparative | +0.15 V | 0.090 | 7.8 | Slightly |
| Example 13 | | | | rounded top |
| Comparative | −0.71 V | 0.090 | 8.0 | Slightly |
| Example 14 | | | | rounded top |
| Comparative | +0.15 V | 0.115 | 4.9 | Rounded top + |
| Example 15 | | | | skirted bottom |
| Comparative | −0.71 V | 0.120 | 4.9 | Rounded top + |
| Example 16 | | | | skirted bottom |

### Examples 21, 22 and Comparative Examples 17 to 19

Resist layers were obtained in the same manner as in Example 14 except that the resist compositions obtained in Examples 14 and 18 and Comparative Examples 9, 12 and 14 were used, respectively. However, the thickness of the resist layer was predetermined to 0.25 μm. The resist layer thus obtained was subjected to plane exposure to EUV ray (wavelength: 13 nm) with the exposure being changed by 0.5 mJ from 0 to 5.0 mJ, and then baked at a temperature of 110° C. for 90 seconds. Thereafter, using a 2.38 wt-% aqueous solution of tetramethyl ammonium hydroxide (TMAH), the dissolution rate was measured at the various exposure values to obtain sensitivity curves. The exposure at which the resist dissolution rate is saturated on this sensitivity curve was defined as sensitivity. The gradient of the linear portion of the sensitivity curve was used to calculate the dissolution contrast (γvalue). The greater γ value is, the better is the dissolution contrast.

The results are set forth in Table 5.

TABLE 5

| | Sensitivity | |
|---|---|---|
| | (mJ/cm²) | γ value |
| Example 21 | 2.0 | 10.5 |
| Example 22 | 2.0 | 9.5 |
| Comparative Example 17 | >5.0 | 9.0 |
| Comparative Example 18 | >5.0 | 4.5 |
| Comparative Example 19 | >5.0 | 5.5 |

As can be seen in Table 5 above, the positive-working resist compositions of the invention exhibit a high sensitivity and contrast and are excellent as compared with the comparative compositions in the evaluation of properties by irradiation with EUV ray.

### Examples 23 to 26

The procedure of preparation of negative-working resist solution ad formation and evaluation of negative-working resist pattern of Example 1 was followed except that the various components set forth in Table 6 were used. The results of evaluation are set forth in Table 7.

In Table 7 below, (Epc (C)-Epa (B)) value of the negative-working resist compositions of Examples 23 to 26 are set forth.

TABLE 6

| | | | | | | | Surface |
|---|---|---|---|---|---|---|---|
| | | Acid | | | | | active |
| | Resin | generators | Component | Component | Component | | agent |
| | 0.70 g | (C) | (B) | (A) | (E) | Solvent | 0.001 g |
| Example 23 | (27) Mw = 7500 | C-8 0.05 g | MM-1 | a-37 | — | S-1 8.5 g | W-1 |
| | x/y = 85/15 | | 0.25 g | 0.0025 g | | | |
| | Mw/Mn = 1.7 | | | | | | |
| Example 24 | (1) | C-9 0.06 g | MM-1 | a-38 | — | S-1 7.0 g | W-1 |
| | Mw = 11000 | | 0.25 g | 0.0025 g | | S-2 1.5 g | |
| | Mw/Mn = 1.4 | | | | | | |
| Example 25 | (29) | C-11 0.06 g | MM-1 | a-41 | — | S-1 8.5 g | W-1 |
| | Mw = 8000 | | 0.25 g | 0.0020 g | | | |
| | x/y = 80/20 | | | | | | |
| | MW/Mn = 2.0 | | | | | | |
| Example 26 | (1) | C-13 0.07 g | MM-2 | a-44 | — | S-1 5.0 g | W-1 |
| | Mw = 6000 | | 0.20 g | 0.030 g | | S-2 3.5 g | |
| | Mw/Mn = 1.5 | | | | | | |

TABLE 7

| | Epc (C) − | Resolution | Sensitivity | Pattern |
|---|---|---|---|---|
| | Epa (B) | (μm) | (μC/cm²) | profile |
| Example 23 | +0.09 V | 0.065 | 3.1 | Rectangular |
| Example 24 | +0.09 V | 0.060 | 3.1 | Rectangular |
| Example 25 | +0.09 V | 0.065 | 3.0 | Rectangular |
| Example 26 | +0.09 V | 0.065 | 3.2 | Rectangular |

As can be seen in Table 7, the negative-working resist compositions of the invention exhibit a high sensitivity and resolution and an excellent pattern profile.

### Examples 27 to 30

The procedure of preparation of positive-working resist solution ad formation and evaluation of positive-working resist pattern of Example 1 was followed except that the various components set forth in Table 8 were used. The results of evaluation are set forth in Table 9.

In Table 9 below, (Epc (C)-Epa (B)) value of the negative-working resist compositions of Examples 27 to 30 are set forth.

TABLE 8

| | | | | | | | Surface |
|---|---|---|---|---|---|---|---|
| | | Acid | | | | | active |
| | Resin | generators | Component | Component | Component | | agent |
| | 0.70 g | (C) | (B) | (A) | (E) | Solvent | 0.001 g |
| Example 27 | B-1 | C-1 0.05 g | dd-1 | a-37 | — | S-1 8.5 g | W-1 |
| | Mw = 9000 | | 0.20 g | 0.0025 g | | | |
| | x/y = 25/75 | | | | | | |
| | Mw/Mn = 1.5 | | | | | | |
| Example 28 | B-3 | C-2 0.06 g | dd-8 | a-38 | — | S-1 7.5 g | W-1 |
| | M = 8000 | | 0.15 g | 0.0025 g | | S-2 1.5 g | |
| | x/y = 30/70 | | | | | | |
| | Mw/Mn = 1.9 | | | | | | |
| Example 29 | B-27 | C-11 0.06 g | e-30 | a-41 | — | S-1 8.5 g | W-1 |
| | Mw = 8000 | | 0.25 g | 0.0020 g | | | |
| | x/y/z = 10/75/15 | | | | | | |
| | Mw/Mn = 2.0 | | | | | | |
| Example 30 | B-28 | C-13 0.07 g | e-51 | a-49 | — | S-1 5.0 g | W-1 |
| | Mw = 6000 | | 0.10 g | 0.030 g | | S-2 3.5 g | |
| | x/y = 75/25 | | | | | | |
| | Mw/Mn = 1.15 | | | | | | |

TABLE 9

| | Epc (C) − | Resolution | Sensitivity | Pattern |
|---|---|---|---|---|
| | Epa (B) | (μm) | (μC/cm²) | profile |
| Example 27 | +0.15 V | 0.075 | 2.7 | Rectangular |
| Example 28 | +0.15 V | 0.070 | 2.6 | Rectangular |
| Example 29 | +0.04 V | 0.070 | 3.4 | Rectangular |
| Example 30 | +0.04 V | 0.070 | 3.5 | Rectangular |

As can be seen in Table 9, the positive-working resist compositions of the invention exhibit a high sensitivity and resolution and an excellent pattern profile.

As mentioned above, the compositions of the invention exhibit good properties regardless of which they are used in the form of negative-working resist composition or positive-working resist composition.

### Examples 2-1 to 2-23 and Comparative Examples 2-1 to 2-7

The procedure of preparation of negative-working resist solution was conducted according to Examples 1-13 and Comparative Examples 1-8, except that the various components set forth in Table 10 were used. Then, sensitivity and resolution were evaluated in the same manner as above. The results of evaluation are set forth in Table 11.

TABLE 10

| | | | | | | | Surface |
|---|---|---|---|---|---|---|---|
| | | Acid | | | | | active |
| | Resin | generators | Component | Component | Component | | agent |
| | 0.70 g | (C) | (B) | (E) | (A) | Solvent | 0.001 g |
| Example 2-1 | (27) Mw = 7500 | A-5 0.05 g | MM-1 | — | a-1 | S-1 8.5 g | W-1 |
| | x/y = 85/15 | | 0.25 g | | 0.002 g | | |
| | Mw/Mn = 1.7 | | | | | | |
| Example 2-2 | (1) | A-5 0.03 g | MM-1 | — | a-2 | S-1 7.5 g | W-1 |
| | Mw= 11000 | PAG4-7 | 0.25 g | | 0.002 g | S-2 1.5 g | |
| | Mw/Mn = 1.4 | 0.02 g | | | | | |
| Example 2-3 | (29) | A-3 0.02 g | MM-1 | OE-1 | a-2 | S-1 8.5 g | W-1 |
| | M = 9200 | | 0.25 g | 0.0007 g | 0.0003 g | | |
| | x/y = 80/20 | | | | | | |
| | Mw/Mn = 2.2 | | | | | | |
| Example 2-4 | (2) | A-4 0.01 g | MM-2 | OE-2 | a-37 | S-1 5.0 g | W-1 |
| | Mw = 6000 | | 0.20 g | 0.0007 g | 0.0005 g | S-2 3.5 g | |
| | Mw/Mn = 1.12 | | | | | | |
| Example 2-5 | (93) Mw = 9000 | A-5 0.01 g | MM-1 | OE-1 | a-49 | S-1 8.5 g | W-1 |
| | x/y = 85/15 | A2-1 0.03 g | 0.20 g | 0.0005 g | 0.0015 g | | |
| | Mw/Mn = 1.12 | | | | | | |
| Example 2-6 | (94) 14w = 12000 | A-3 0.04 g | MM-3 | OE-3 | a-35 | S-2 8.5 g | W-2 |
| | x/y = 90/10 | | 0.25 g | 0.0001 g | 0.0019 g | | |
| | Mw/Mn = 2.0 | | | | | | |
| Example 2-7 | (96) Mw = 7000 | A-1 0.05 g | MM-4 | OE-1 | a-34 | S-1 7.0 g | W-2 |
| | x/y = 90/10 | | 0.30 g | 0.001 g | 0.001 g | S-2 1.5 g | |
| | Mw/Mn = 2.2 | | | | | | |
| Example 2-8 | (15) Mw = 12800 | A-2 0.07 g | MM-1 | OE-1 | a-22 | S-1 7.0 g | W-1 |
| | Mw/Mn = 1.8 | | 0.30 g | 0.0028 g | 0.0002 g | S-2 1.5 g | |
| Example 2-9 | (1) Mw = 15000 | A-9 0.02 g | MM-1 | OE-2 | a-27 | S-1 7.0 g | — |
| | Mw/Mn = 1.4 | | 0.25 g | 0.0009 g | 0.0001 g | S-2 1.5 g | |
| Example 2-10 | (2) Mw = 9000 | A-9 0.04 g | MM-1 | OE-4 | a-41 | S-1 7.0 g | W-2 |
| | Mw/Mn = 1.6 | | 0.25 g | 0.0001 g | 0.0019 g | S-2 1.5 g | |
| Example 2-11 | (25) Mw = 7800 | A-13 0.01 g | MM-1 | OE-4 | a-44 | S-1 8.5 g | W-1 |
| | x/y = 80/20 | A-4 0.01 g | 0.25 g | 0.0015 g | 0.0005 g | | |
| | Mw/Mn = 1.9 | | | | | | |
| Example 2-12 | (31) Mw = 10500 | A-19 0.05 g | CL-1 | — | a-2 | s-1 2.0 g | W-1 |
| | x/y = 90/10 | | 0.25 g | | 0.001 g | S-2 6.5 g | |
| | Mw/Mn = 1.7 | | | | a-37 | | |
| | | | | 0.001 g | | | |
| Example 2-13 | (32) Mw = 7500 | A-4 0.01 g | MM-1 | OE-1 | a-2 0.001 g | S-1 7.0 g | W-1 |
| | x/y = 95/5 | A2-1 0.03 g | 0.25 g | 0.0005 g | a-37 0.001 g | S-2 1.5 g | |
| | Mw/Mn = 2.0 | | | | | | |
| Example 2-14 | (33) Mw = 4500 | A-1 0.05 g | CL-1 | OE-2 | d-47 | S-1 7.0 g | W-2 |
| | x/y = 90/10 | | 0.25 g | 0.0005 g | 0.0015 g | S-2 1.5 g | |
| | Mw/Mn = 1.6 | | | | | | |
| Example 2-15 | (39) Mw = 8000 | A-15 0.04 g | MM-4 | OE-3 | d-20 | S-1 7.0 g | W-2 |
| | x/y = 85/15 | | 0.30 g | 0.0015 g | 0.0005 g | S-2 1.5 g | |
| | Mw/Mn = 1.8 | | | | | | |
| Example 2-16 | (28) Mw = 13500 | A-4 0.04 g | MM-4 | OE-1 | d-1 | S-1 8.5 g | W-2 |
| | x/y = 90/10 | | 0.30 g | 0.001 g | 0.001 g | | |
| | Mw/Mn = 1.5 | | | | | | |
| Example 2-17 | (60) Mw = 9500 | A-1 0.03 g | MM-1 | OE-3 | d-8 | S-1 8.5 g | W-1 |
| | x/y/z = 90/5/5 | | 0.20 g | 0.0002 g | 0.0015 g | S-2 0.5 g | |
| | Mw/Mn = 2.0 | | | | | | |
| Example 2-18 | (41) M = 6000 | A-2 0.10 g | MM-3 | OE-1 | d-9 | S-1 7.0 g | W-1 |
| | x/y = 85/15 | | 0.25 g | 0.001 g | 0.003 g | S-2 1.5 g | |
| | Mw/Mn = 1.35 | | | | | | |
| Example 2-19 | (93) Mw = 9000 | A-1 0.05 g | MM-2 | OE-2 | b-2 | S-1 7.0 g | W-2 |
| | x/y = 85/15 | 0.20 g | 0.0015 g | 0.0005 g | S-2 1.5 g | | |
| | Mw/Mn = 1.6 | | | | | | |
| Example 2-20 | (1) Mw = 15000 | A-5 0.04 g | CL-2 | OE-2 | b-37 | S-1 7.0 g | W-2 |
| | Mw/Mn = 1.4 | PAG4-5 0.002 g | 0.25 g | 0.0017 g | 0.0003 g | S-2 1.5 g | |
| | | PAG4-38 0.001 g | | | | | |
| | | PAG4-39 0.0002 g | | | | | |
| Example 2-21 | (97) | A-2 0.05 g | MM-1 | OE-1 | b-2 | S-1 8.0 g | W-2 |
| | Mw = 6800 | | 0.25 g | 0.001 g | 0.001 g | S-2 0.5 g | |
| | Mw/Mn = 2.2 | | | | | | |
| Example 2-22 | (1) | A-2 0.06 g | MM-1 | OE-1 | c-9 | S-1 7.0 g | W-2 |
| | Mw = 1000 | | 0.25 g | 0.0005 g | 0.002 g | S-2 1.5 g | |
| | Mw/Mn = 1.2 | | | | | | |
| Example 2-23 | (95) Mw = 6500 | A-2 0.05 g | MM-1 | OE-1 | c-18 | S-1 7.0 g | W-2 |
| | x/y = 90/10 | | 0.25 g | 0.0015 g | 0.0005 g | S-2 1.5 g | |
| | Mw/Mn = 1.9 | | | | | | |
| Comparative | (1) | PAG4-5 0.002 g | CL-2 | OE-2 | b-37 | S-1 8.5 g | W-1 |
| Example 2-1 | Mw = 15000 | PAG4-26 0.040 g | 0.25 g | 0.0017 g | 0.0003 g | | |
| | Mw/Mn = 1.4 | PAG4-38 0.001 g | | | | | |
| | | PAG4-39 0.0002 g | | | | | |
| Comparative | (1) | PAG4-5 0.002 g | CL-2 | OE-1 | — | S-1 7.0 g | W-1 |
| Example 2-2 | Mw = 15000 | PAG4-26 0.040 g | 0.25 g | 0.003 g | | S-2 1.5 g | |
| | Mw/Mn = 1.4 | PAG4-38 0.001 g | | | | | |
| | | PAG4-39 0.0002 g | | | | | |
| Comparative | (1) | PAG4-5 0.002 g | CL-2 | — | b-37 | S-1 7.0 g | W-2 |
| Example 2-3 | Mw = 15000 | PAG4-26 0.040 g | 0.25 g | 0.002 g | | S-2 1.5 g | |
| | Mw/Mn = 1.4 | PAG4-38 0.001 g | | | | | |
| | | PAG4-39 0.0002 g | | | | | |
| Comparative | (1) | A-1 0.030 g | MM-1 | — | — | S-1 7.0 g | — |
| Example 2-4 | Mw = 15000 | | 0.25 g | | | S-2 1.5 g | |
| | Mw/Mn = 1.4 | | | | | | |
| Comparative | (25) | A-1 0.030 g | CL-1 | OE-4 | — | S-1 8.5 g | W-1 |
| Example 2-5 | Mw = 7800 | | 0.25 g | 0.002 g | | | |
| | x/y = 80/10 | | | | | | |
| | Mw/Mn = 1.9 | | | | | | |
| Comparative | (95) | A2-33 | MM-1 | OE-2 | b-37 | S-1 7.0 g | W-2 |
| Example 2-6 | Mw = 6500 | 0.040 g | 0.25 g | 0.002 g | 0.0003 g | S-2 1.5 g | |
| | x/y = 90/10 | A2-1 | | | | | |
| | Mw/Mn = 1.9 | 0.010 g | | | | | |
| Comparative | (97) | PAG4-5 | NM-1 | — | b-37 | S-1 8.0 g | W-2 |
| Example 2-7 | Mw = 6800 | 0.002 g | 0.25 g | | 0.02 g | S-2 0.5 g | |
| | Mw/Mn = 2.2 | PAG4-26 | | | | | |
| | | 0.040 g | | | | | |

TABLE 11

| | Sensitivity | Resolution |
|---|---|---|
| | (μC/cm²) | (μm) |
| Example 2-1 | 1.8 | 0.085 |
| Example 2-2 | 1.8 | 0.085 |
| Example 2-3 | 2.2 | 0.075 |
| Example 2-4 | 2.4 | 0.080 |
| Example 2-5 | 2.2 | 0.075 |
| Example 2-6 | 2.0 | 0.075 |
| Example 2-7 | 2.2 | 0.075 |
| Example 2-8 | 2.0 | 0.075 |
| Example 2-9 | 2.4 | 0.080 |
| Example 2-10 | 2.2 | 0.075 |
| Example 2-11 | 2.4 | 0.080 |
| Example 2-12 | 2.0 | 0.075 |
| Example 2-13 | 2.2 | 0.075 |
| Example 2-14 | 2.6 | 0.075 |
| Example 2-15 | 2.6 | 0.075 |
| Example 2-16 | 2.6 | 0.075 |
| Example 2-17 | 2.6 | 0.080 |
| Example 2-18 | 2.6 | 0.090 |
| Example 2-19 | 2.8 | 0.075 |
| Example 2-20 | 2.8 | 0.075 |
| Example 2-21 | 2.8 | 0.075 |
| Example 2-22 | 2.8 | 0.075 |
| Example 2-23 | 2.8 | 0.075 |
| Comparative | 7.6 | 0.090 |
| Example 2-1 | | |
| Comparative | 7.8 | 0.085 |
| Example 2-2 | | |
| Comparative | 7.6 | 0.100 |
| Example 2-3 | | |
| Comparative | 4.8 | 0.135 |
| Example 2-4 | | |
| Comparative | 7.2 | 0.085 |
| Example 2-5 | | |
| Comparative | 7.4 | 0.085 |
| Example 2-6 | | |
| Comparative | 7.0 | 0.115 |
| Example 2-7 | | |

As can-be seen in Table 11 above, the negative-working resist positions according to the invention are excellent in sensitivity resolution and thus have good properties.

### Examples 2-24 to 2-37 and Comparative Examples 2-8 to 2-15

The procedure of preparation of positive-working resist solution was conducted according to Examples 1-13 and Comparative Examples 1-8, except that the various components set forth in Table 12 were used. Then, sensitivity and resolution were evaluated in the same manner as above. The results of evaluation are set forth in Table 13.

TABLE 12

| | | | | | | Surface |
|---|---|---|---|---|---|---|
| | | Acid | | | | active |
| | Resin | generators | Component | Component | | agent |
| | 0.70 g | (C) | (A) | (E) | Solvent | 0.001 g |
| Example 2-24 | R-23 Mw = 7500 | A-1 0.05 g | a-1 | — | S-1 8.5 g | W-1 |
| | x/y/z = 10/70/20 | | 0.002 g | | | |
| | Mw/Mn = 1.21 | | | | | |
| Example 2-25 | R-24 Mw = 9000 | A-5 0.05 g | a-37 | — | S-1 7.5 g | W-1 |
| | x/y/z = 70/25/5 | | 0.002 g | | S-2 1.5 g | |
| | Mw/Mn = 1.51 | | | | | |
| Example 2-26 | R-17 Mw = 8000 | A-5 0.03 g | a-49 | OE-1 | S-1 8.5 g | W-1 |
| | x/y/z = 10/70/20 | A2-1 | 0.0015 g | 0.001 g | | |
| | Mw/Mn = 2.05 | 0.03 g | | | | |
| Example 2-27 | R-13 Mw = 6000 | A-3 0.02 g | a-34 | OE-4 | S-1 5.0 g | W-1 |
| | x/y/z = 75/25 | | 0.0005 g | 0.0005 g | S-2 3.5 g | |
| | Mw/Mn = 1.10 | | | | | |
| Example 2-28 | R-2 Mw = 9000 | A-4 0.04 g | a-27 | OE-3 | S-1 9.5 g | — |
| | x/y = 75/25 | | 0.0001 g | 0.002 g | | |
| | Mw/Mn = 1.23 | | | | | |
| Example 2-29 | R-8 Mw = 12000 | A-5 0.01 g | a-42 | OE-3 | S-2 8.5 g | W-2 |
| | x/y/z = 70/20/10 | 0.0005 g | 0.0001 g | | | |
| | Mw/Mn = 1.13 | | | | | |
| Example 2-30 | R-20 Mw = 7000 | A-3 0.07 g | a-2 0.001 g | OE-1 | S-1 7.0 g | W-2 |
| | x/y = 85/15 | | a-3 0.001 g | 0.001 g | S-2 1.5 g | |
| | Mw/Mn = 2.2 | | | | | |
| Example 2-31 | R-21 Mw = 7000 | A-1 0.02 g | d-47 | OE-1 | S-1 8.5 g | W-2 |
| | x/y = 75/25 | PAG4-4 | 0.0015 g | 0.002 g | | |
| | Mw/Mn =1.13 | 0.04 g | | | | |
| Example 2-32 | R-22 Mw = 4000 | A-2 0.07 g | d-20 | OE-2 | S-1 8.5 g | W-2 |
| | x/y = 70/30 | | 0.0005 g | 0.003 g | | |
| | Mw/Mn = 2.50 | | | | | |
| Example 2-33 | R-14 Mw = 5000 | A-10 | d-1 | OE-1 | S-1 8.5 g | W-2 |
| | x/y = 75/25 | 0.05 g | 0.001 g | 0.001 g | | |
| | Mw/Mn = 1.15 | | | | | |
| Example 2-34 | R-14 Mw = 2500 | A-9 0.04 g | b-2 | OE-1 | S-1 8.5 g | W-2 |
| | x/y = 59/41 | 0.0005 g | 0.0015 g | | | |
| | Mw/Mn = 1.15 | | | | | |
| Example 2-35 | R-17 Mw = 5000 | A-13 0.03 g | b-37 | OE-1 | S-1 8.5 g | W-1 |
| | x/y/z = 10/70/20 | A-4 0.01 g | 0.0003 g | 0.002 g | | |
| | Mw/Mn = 1.25 | | | | | |
| Example 2-36 | R-14 Mw = | A-19 0.05 g | c-9 | OE-1 | S-1 8.5 g | W-2 |
| | 11000 | | 0.001 g | 0.001 g | | |
| | x/y = 91/9 | | | | | |
| | Mw/Mn = 1.30 | | | | | |
| Example 2-37 | R-22 Mw = 8000 | A-5 0.04 g | c-18 | OE-1 | S-1 8.5 g | W-1 |
| | x/y = 86/314 | PAG4-5 | 0.0005 g | 0.002 g | | |
| | Mw/Mn = 2.1 | 0.002 g | | | | |
| | | PAG4-38 | | | | |
| | | 0.001 g | | | | |
| | | PAG4-39 | | | | |
| | | 0.0002 g | | | | |
| Comparative | R-22 Mw = 8000 | PAG4-5 0.002 g | c-18 | OE-1 | S-1 8.5 g | W-1 |
| Example 2-8 | x/y = 86/314 | PAG4-26 | 0.0005 g | 0.002 g | | |
| | Mw/Mn = 2.1 | 0.040 g | | | | |
| | | PAG4-38 | | | | |
| | | 0.001 g | | | | |
| | | PAG4-39 | | | | |
| | | 0.0002 g | | | | |
| Comparative | R-22 Mw = 8000 | PAG4-5 0.002 g | c-18 | OE-1 | S-1 8.5 g | W-1 |
| Example 2-9 | x/y = 86/314 | PAG4-26 | | 0.0025 g | | |
| | Mw/Mn = 2.1 | 0.040 g | | | | |
| | | PAG4-38 | | | | |
| | | 0.001 g | | | | |
| | | PAG4-39 | | | | |
| | | 0.0002 g | | | | |
| Comparative | R-22 Mw = 8000 | PAG4-5 | — | — | S-1 8.5 g | W-2 |
| Example 2-10 | x/y = 86/314 | 0.002 g | | | | |
| | Mw/Mn = 2.1 | PAG4-26 | | | | |
| | | 0.040 g | | | | |
| | | PAG4-38 | | | | |
| | | 0.001 g | | | | |
| | | PAG4-39 | | | | |
| | | 0.0002 g | | | | |
| Comparative | R-22 Mw = 8000 | A-1 | — | OE-1 | S-1 8.5 g | W-1 |
| Example 2-11 | x/y/z = 10/70/20 | 0.040 g | | 0.002 g | | |
| | Mw/Mn = 1.21 | | | | | |
| Comparative | R-23 Mw = 8000 | A2-33 | — | OE-1 | S-1 8.5 g | W-1 |
| Example 2-12 | x/y/z = 10/70/20 | 0.040 g | | 0.002 g | | |
| | Mw/Mn = 1.21 | A2-1 | | | | |
| | | 0.010 g | | | | |
| Comparative | R-23 Mw = 8000 | A2-33 | — | — | S-1 8.5 g | W-1 |
| Example 2-13 | x/y/z = 10/70/20 | 0.040 g | | | | |
| | Mw/Mn = 1.21 | A2-1 | | | | |
| | | 0.010 g | | | | |
| Comparative | R-23 Mw = 8000 | PAG4-5 | — | OE-1 | S-1 8.5 g | W-1 |
| Example 2-14 | x/y/z = 10/70/20 | 0.002 g | | 0.002 g | | |
| | Mw/Mn = 1.21 | PAG4-26 | | | | |
| | | 0.040 g | | | | |
| Comparative | R-23 Mw = 8000 | A2-1 | — | OE-1 | S-1 8.5 g | W-1 |
| Example 2-15 | x/y/z = 10/70/20 | 0.040 g | | 0.002 g | | |
| | Mw/Mn = 1.21 | | | | | |

TABLE 13

| | Sensitivity | Resolution |
|---|---|---|
| | (μC/cm²) | (μm) |
| Example 2-24 | 2.0 | 0.085 |
| Example 2-25 | 2.0 | 0.085 |
| Example 2-26 | 2.4 | 0.070 |
| Example 2-27 | 2.4 | 0.075 |
| Example 2-28 | 2.4 | 0.070 |
| Example 2-29 | 2.6 | 0.075 |
| Example 2-30 | 2.2 | 0.070 |
| Example 2-31 | 2.8 | 0.070 |
| Example 2-32 | 2.8 | 0.070 |
| Example 2-33 | 2.8 | 0.070 |
| Example 2-34 | 3.0 | 0.075 |
| Example 2-35 | 3.0 | 0.070 |
| Example 2-36 | 3.0 | 0.070 |
| Example 2-37 | 3.0 | 0.070 |
| Comparative | 7..4 | 0.090 |
| Example 2-8 | | |
| Comparative | 7.6 | 0.090 |
| Example 2-9 | | |
| Comparative | 5.2 | 0.125 |
| Example 2-10 | | |
| Comparative | 6.8 | 0.090 |
| Example 2-11 | | |
| Comparative | 7.2 | 0.095 |
| Example 2-12 | | |
| Comparative | 5.2 | 0.130 |
| Example 2-13 | | |
| Comparative | 7.4 | 0.095 |
| Example 2-14 | | |
| Comparative | 8.0 | 0.100 |
| Example 2-15 | | |

As can be seen in Tables as above, the positive-working resist compositions of the present invention are excellent in sensitivity and resolution, and have good performance.

In accordance with the invention, a resist composition can be provided which is excellent in sensitivity and resolution as well as pattern profile in relation to pattern formation by irradiation with an actinic ray or radiation.

What is claimed is:

1. A resist composition comprising:
(A) a compound capable of generating an active seed upon irradiation with one of an actinic ray and a radiation,
(B) a compound capable of reacting with the active seed generated from the compound (A) and/or performing electron transfer to generate an active seed different from the active seed generated from the compound (A), and
(C) a compound capable of performing electron transfer from the active seed generated from the compound (B) to generate an acid,
wherein supposing that the ½ wave of the oxidation potential of the active seed generated from the compound (B) is Eₚₐ and the ½ wave of the reduction potential of the active seed generated from the compound (C) is E_{pc}, the relationship; E_{pc}−Eₚₐ>0 is satisfied.

2. The resist composition according to claim 1, wherein the compound (A) contains a structure represented by the following formula (a):
⁻Ra—Rb—COO⁻ (a)
wherein Ra represents a hydrogen atom, a substituted or unsubstituted C₆-C₁₆ aryl group, a substituted or unsubstituted C₁-C₂₀ straight-chain, branched or cyclic alkyl group, —CCO⁻ or —SO₃⁻, and
Rb represents a single bond; —C(═O)—, —NH— or —S(═O)₂—.

3. The resist composition according to claim 1, wherein the compound (A) is at least one selected from the group consisting of compounds represented by the formulae (a) and (I) to (IV) in combination: 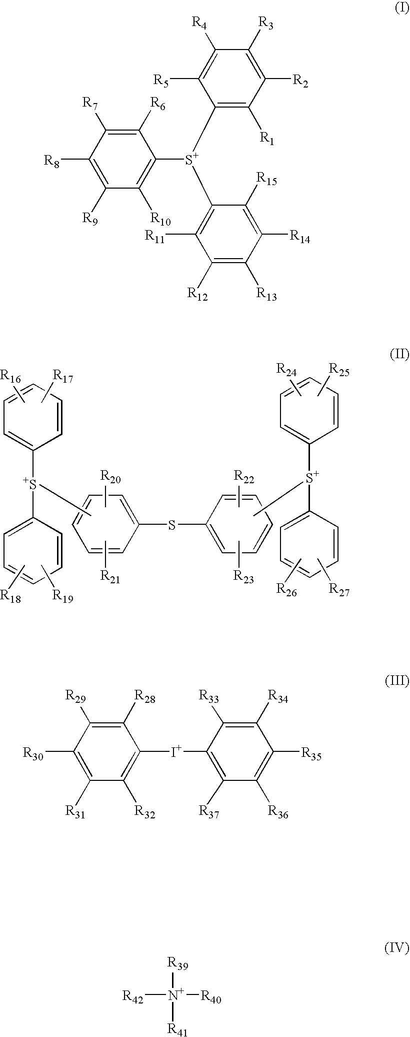
wherein R₁ to R₃₇ each independently represents a hydrogen atom, a straight-chain, branched or cyclic alkyl or alkoxy group, a hydroxyl group, a halogen atom or —S—R₃₈ in which R₃₈ represents a straight-chain, branched or cyclic alkyl or aryl group, with the proviso that two or more of R₁ to R₁₅, R₁₆ to R₂₇ and R₂₈ to R₃₇ may be bonded to each other to form a ring containing one or more selected from the group consisting of a single bond; a carbon atom, an oxygen atom, a sulfur atom and a nitrogen atom, and
R₃₉ to R₄₂ each independently represents a hydrogen atom or a straight-chain, branched or cyclic alkyl or aryl group.

4. The resist composition according to claim 1, wherein the compound (A) is represented by the following formula (V): 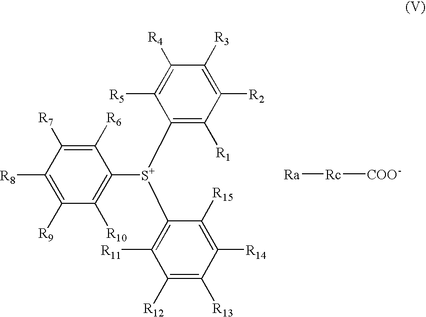
wherein Ra represents a hydrogen atom, a substituted or unsubstituted C₆-C₁₆ aryl group, a substituted or unsubstituted C₁-C₂₀ straight-chain, branched or cyclic alkyl group, —COO⁻ or —SO₃⁻,
Rc represents CH₂, CHRa or C(Ra)₂,
R₁ to R₁₅ each independently represents a hydrogen atom, a straight-chain, branched or cyclic alkyl or alkoxy group, a hydroxyl group, a halogen atom or —S—R₃₈ in which R₃₈ represents a straight-chain, branched or cyclic alkyl or aryl group, with the proviso that two or more of R₁ to R₁₅ may be bonded to each other to form a ring containing one or more selected from the group consisting of a single bond, a carbon atom, an oxygen atom, a sulfur atom and a nitrogen atom.

5. The resist composition according to claim 1, wherein the compound (A) is represented by the following formula (VI) or (VII): 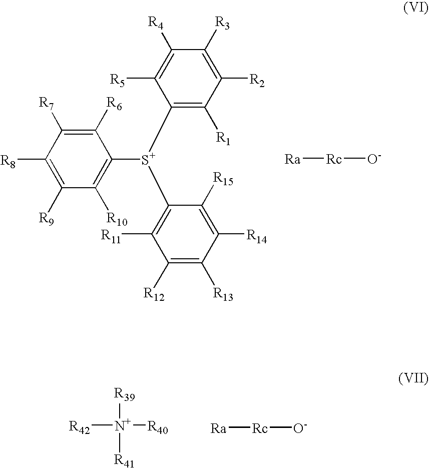
wherein Ra represents a hydrogen atom, a substituted or unsubstituted C₆-C₁₆ aryl group, a substituted or unsubstituted C₁-C₂₀ straight-chain, branched or cyclic alkyl group, —COO⁻ or —SO₃⁻,
Rc represents CH₂, CHRa or C(Ra)₂,
R₁ to R₁₅ each independently represents a hydrogen atom, a straight-chain; branched or cyclic alkyl or alkoxy group, a hydroxyl group, a halogen atom or —S—R₃₈ in which R₃₈ represents a straight-chain, branched or cyclic alkyl or aryl group, with the proviso that two or more of R₁ to R₁₅ may be bonded to each other to form a ring containing one or more selected from the group consisting of a single bond, a carbon atom, an oxygen atom, a sulfur atom and a nitrogen atom, and
R₃₉ to R₄₂ each independently represents a hydrogen atom or a straight-chain, branched or cyclic alkyl or aryl group.

6. The resist composition according to claim 1, wherein E_{pc} of the compound (C) is higher than −1.15 V.

7. The resist composition according to claim 1, wherein the compound (C) is a compound having a partial structure represented by the following formula (VIII) and a counter ion capable of generating an acid upon irradiation with one of an actinic ray and a radiation: 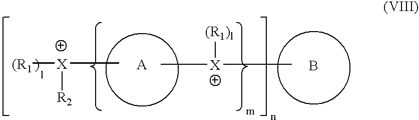
wherein X represents a sulfur atom or an iodine atom, with the proviso that the plurality of X's may be the same or different,
R₁ and R₂ each independently represents an alkyl or an aryl group, with the proviso that the plurality of R₁'s, if any, may be the same or different, the plurality of R₂'s, if any, may be the same or different, and R₁ and R₂, R₁ and A, R₁ and B, R₂ and A, and R₂ and B may be bonded to each other to form a ring,
A and B each independently represents a hydrocarbon structure connecting between X⁺'s, with the proviso that at least one of connections of X₊'s with A or B indicates a structure in which X₊'s connected are in the same conjugation and the plurality of A's, if any, may be the same or different,
l represents 0 or 1, with the proviso that when X is a sulfur atom, the number 1 of R₁'s connected to X⁺ represents 1, and when X is an iodine atom, the number 1 of R₁'s connected to X⁺ represents 0,
m represents an integer of from 0 to 10,
n represents an integer of from 1 to 6, with the proviso that when m is 0, n represents an integer of not smaller than 2.

8. The resist composition according to claim 1, wherein the compound (B) is a phenol derivative containing from 1 to 10 benzene ring atomic groups per molecule and having at least one hydroxymethyl group and at least one alkoxymethyl group per molecule.

9. The resist composition according to claim 1, wherein the compound (B) contains a structure represented by the following formula (b): 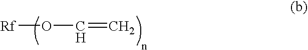
wherein Rf represents a substituted or unsubstituted aryl group, a substituted or unsubstituted straight-chain, branched or alicyclic hydrocarbon group or a combination thereof, which may have a carbonyl group, an oxygen atom or a sulfur atom in the middle portion thereof, and n represents an integer of from 1 to 10.

10. The resist composition according to claim 1, wherein the compound (B) is a cyclic ether compound.

11. The resist composition according to claim 1, further comprising (E) a nitrogen-containing basic compound.

12. The resist composition according to claim 1, wherein the actinic ray or radiation is selected from the group consisting of electron ray, X ray and EUV ray.

13. A negative-working resist composition comprising:
(A) at least one selected from the group consisting of compounds represented by the formulae (a) and (I) to (IV) in combination,
(B) a crosslinking agent capable of carrying out addition reaction with the alkali-soluble resin which is the component (D1) by the action of an acid,
(C) a compound having a partial structure represented by the following formula (VIII) and a counter ion capable of generating an acid upon irradiation with one of an actinic ray and a radiation, and
(D1) an alkali-soluble resin:
Ra—Rb—COO⁻ (a)
wherein Ra represents a hydrogen atom, a substituted or unsubstituted C₆-C₁₆ aryl group, a substituted or unsubstituted C₁-C₂₀ straight-chain, branched or cyclic alkyl group, —COO⁻ or —SO₃⁻, and Rb represents a single bond, —C(═O)—, —NH— or —S(═O)₂—: 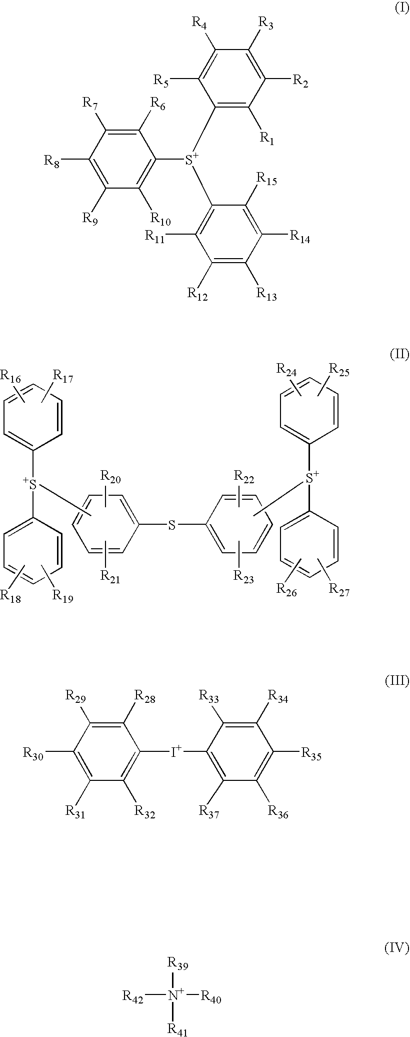
wherein R₁ to R₃₇ each independently represents a hydrogen atom, a straight-chain, branched or cyclic alkyl or alkoxy group, a hydroxyl group, a halogen atom or —S—R₃₈ in which R₃₈ represents a straight-chain, branched or cyclic alkyl or aryl group, with the proviso that two or more of R₁ to R₁₅, R₁₆ to R₂₇ and R₂₈ to R₃₇ may be bonded to each other to form a ring containing one or more selected from the group consisting of a single bond, a carbon atom, an oxygen atom, a sulfur atom and a nitrogen atom, and
R₃₉ to R₄₂ each independently represents a hydrogen atom or a straight-chain, branched or cyclic alkyl or aryl group: 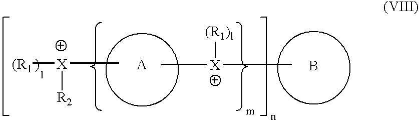
wherein X represents a sulfur atom or an iodine atom, with the proviso that the plurality of X's may be the same or different,
R₁ and R₂ each independently represents an alkyl or an aryl group, with the proviso that the plurality of R₁'s, if any, may be the same or different, the plurality of R₂'s, if any, may be the same or different, and R₁ and R₂, R₁ and A, R₁ and B, R₂ and A, and R₂ and B may be bonded to each other to form a ring,
A and B each independently represents a hydrocarbon structure connecting between X⁺'s, with the proviso that at least one of connections of X⁺'s with A or B indicates a structure in which X⁺'s connected are in the same conjugation and the plurality of A's, if any, may be the same or different,
l represents 0 or 1, with the proviso that when X is a sulfur atom, the number 1 of R¹'s connected to X⁺ represents 1, and when X is an iodine atom, the number 1 of R¹'s connected to X⁺ represents 0,
m represents an integer of from 0 to 10,
n represents an integer of from 1 to 6, with the proviso that when m is 0, n represents an integer of not smaller than 2.

14. A negative-working resist composition comprising:
(A) at least one selected from the group consisting of compounds represented by the formulae (a′) and (I) to (IV) in combination,
(B) a crosslinking agent capable of carrying out addition reaction with the alkali-soluble resin which is the component (D1) by the action of an acid, and
(C) a compound having a partial structure represented by the following formula (VIII) and a counter ion capable of generating an acid upon irradiation with one of an actinic ray and a radiation,
(D1) an alkali-soluble resin;
Ra—O⁻ (a′)
wherein Ra represents a hydrogen atom, a substituted or unsubstituted C₆-C₁₆ aryl group, a substituted or unsubstituted C₁-C₂₀ straight-chain, branched or cyclic alkyl group, —COO⁻ or —SO₃⁻: 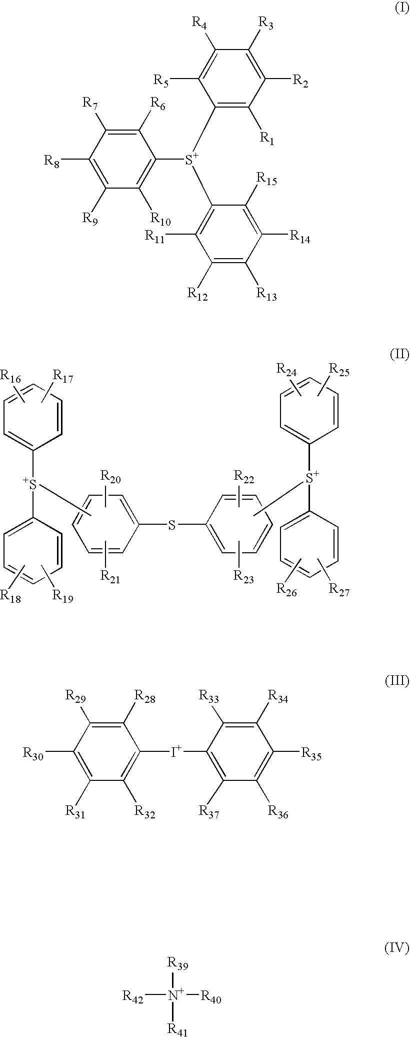
wherein R₁ to R₃₇ each independently represents a hydrogen atom, a straight-chain; branched or cyclic alkyl or alkoxy group, a hydroxyl group, a halogen atom or —S—R₃₈ in which R₃₈ represents a straight-chain, branched or cyclic alkyl or aryl group, with the proviso that two or more of R₁ to R₁₅, R₁₆ to R₂₇ and R₂₈ to R₃₇ may be bonded to each other to form a ring containing one or more selected from the group consisting of a single bond, a carbon atom, an oxygen atom, a sulfur atom and a nitrogen atom, and
R₃₉ to R₄₂ each independently represents a hydrogen atom or a straight-chain, branched or cyclic alkyl or aryl group: 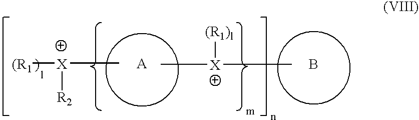
wherein X represents a sulfur atom or an iodine atom, with the proviso that the plurality of X's may be the same or different,
R₁ and R₂ each independently represents an alkyl or an aryl group, with the proviso that the plurality of R₁'s, if any, may be the same or different, the plurality of R₂'s, if any, may be the same or different, and R₁ and R₂, R₁ and A, R₁ and B, R₂ and A, and R₂ and B may be bonded to each other to form a ring,
A and B each independently represents a hydrocarbon structure connecting between X⁺'s, with the proviso that at least one of connections of X⁺'s with A or B indicates a structure in which X⁺'s connected are in the same conjugation and the plurality of A's, if any, may be the same or different,
l represents 0 or 1, with the proviso that when X is a sulfur atom, the number 1 of R¹'s connected to X⁺ represents 1, and when X is an iodine atom, the number 1 of R¹'s connected to X⁺ represents 0,
m represents an integer of from 0 to 10,
n represents an integer of from 1 to 6, with the proviso that when m is 0, n represents an integer of not smaller than 2.

15. The negative-working resist composition according to claim 13, wherein the component (A) is at least one selected from the compounds represented by the formula (a) and the formula (I) or (II) in combination.

16. The positive-working resist composition according to claim 13, further comprising (E) a nitrogen-containing basic compound.

17. A positive-working resist composition comprising:
(A) at least one selected from the group consisting of compounds represented by the formulae (a) and (I) to (IV) in combination,
(C) a compound having a partial structure represented by the following formula (VIII) and a counter ion capable of generating an acid upon irradiation with one of an actinic ray and a radiation, and
(D2) a resin increasing the solubility in an alkali developer by the action of an acid:
Ra—Rb—COO⁻ (a)
wherein Ra represents a hydrogen atom, a substituted or unsubstituted C₆-C₁₆ aryl group, a substituted or unsubstituted C₁-C₂₀ straight-chain, branched or cyclic alkyl group, —COO⁻ or —SO₃⁻, and Rb represents a single bond, —C(═O)—, —NH— or —S(═O)₂—: 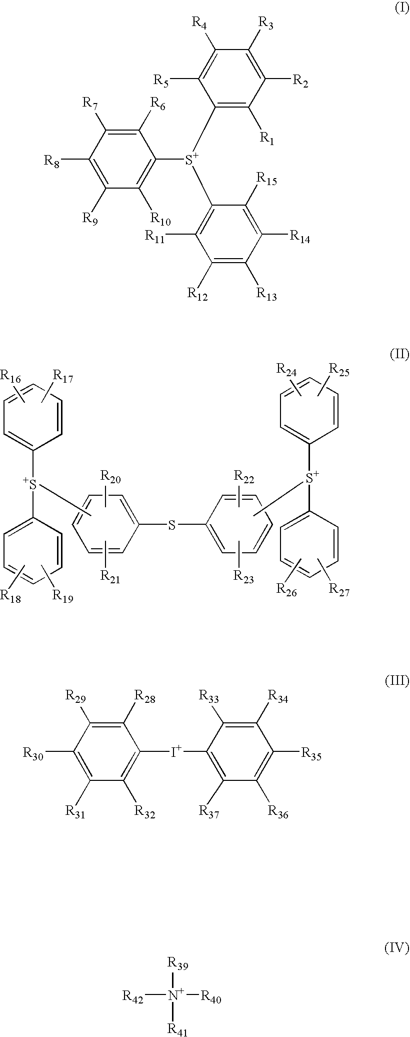
wherein R₁ to R₃₇ each independently represents a hydrogen atom, a straight-chain, branched or cyclic alkyl or alkoxy group, a hydroxyl group, a halogen atom or —S—R₃₈ in which R₃₈ represents a straight-chain, branched or cyclic alkyl or aryl group, with the proviso that two or more of R₁ to R₁₅, R₁₆ to R₂₇ and R₂₈ to R₃₇ may be bonded to each other to form a ring containing one or more selected from the group consisting of a single bond, a carbon atom, an oxygen atom, a sulfur atom and a nitrogen atom, and
R₃₉ to R₄₂ each independently represents a hydrogen atom or a straight-chain, branched or cyclic alkyl or aryl group: 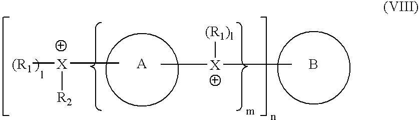
wherein X represents a sulfur atom or an iodine atom, with the proviso that the plurality of X's may be the same or different,
R₁ and R₂ each independently represents an alkyl or an aryl group, with the proviso that the plurality of R₁'s, if any, may be the same or different, the plurality of R₂'s, if any, may be the same or different, and R₁ and R₂, R₁ and A, R₁ and B, R₂ and A, and R₂ and B may be bonded to each other to form a ring,
A and B each independently represents a hydrocarbon structure connecting between X⁺'s, with the proviso that at least one of connections of X⁺'s with A or B indicates a structure in which X⁺'s connected are in the same conjugation and the plurality of A's, if any, may be the same or different,
l represents 0 or 1, with the proviso that when X is a sulfur atom, the number 1 of R¹'s connected to X⁺ represents 1, and when X is an iodine atom, the number 1 of R¹'s connected to X⁺ represents 0,
m represents an integer of from 0 to 10,
n represents an integer of from 1 to 6, with the proviso that when m is 0, n represents an integer of not smaller than 2.

18. A positive-working resist composition comprising:
(A) at least one selected from the group consisting of compounds represented by the formulae (a′) and (I) to (IV) in combination,
(C) a compound having a partial structure represented by the following formula (VIII) and a counter ion capable of generating an acid upon irradiation with one of an actinic ray and a radiation, and
(D2) a resin increasing the solubility in an alkali developer by the action of an acid:
Ra—O⁻ (a′)
wherein Ra represents a hydrogen atom, a substituted or unsubstituted C₆-C₁₆ aryl group, a substituted or unsubstituted C₁-C₂₀ straight-chain, branched or cyclic alkyl group, —COO⁻ or —SO₃⁻: 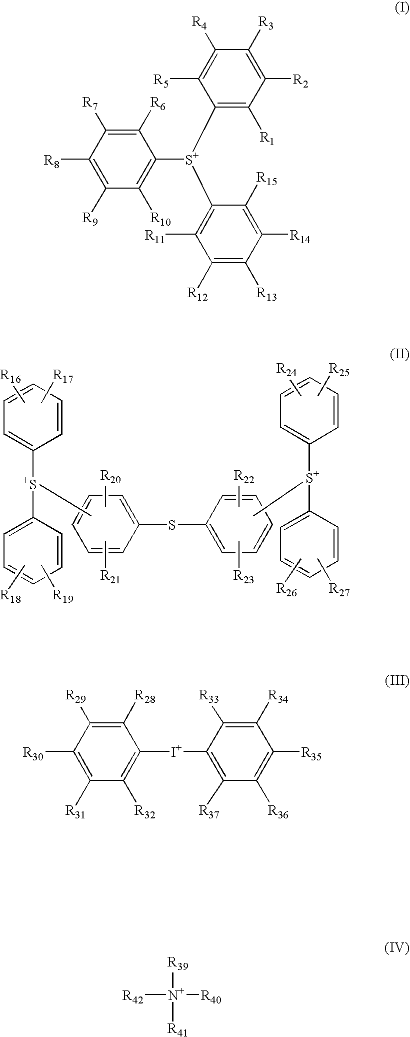
wherein R₁ to R₃₇ each independently represents a hydrogen atom, a straight-chain, branched or cyclic alkyl or alkoxy group, a hydroxyl group, a halogen atom or —S—R₃₈ in which R₃₈ represents a straight-chain, branched or cyclic alkyl or aryl group, with the proviso that two or more of R₁ to R₁₅, R₁₆ to R₂₇ and R₂₈ to R₃₇ may be bonded to each other to form a ring containing one or more selected from the group consisting of a single bond, a carbon atom, an oxygen atom, a sulfur atom and a nitrogen atom, and
R₃₉ to R₄₂ each independently represents a hydrogen atom or a straight-chain, branched or cyclic alkyl or aryl group: 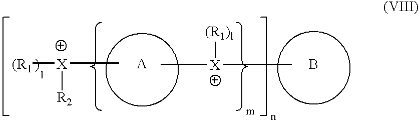
wherein X represents a sulfur atom or an iodine atom, with the proviso that the plurality of X's may be the same or different,
R₁ and R₂ each independently represents an alkyl or an aryl group, with the proviso that the plurality of R₁'s, if any, may be the same or different, the plurality of R₂'s, if any, may be the same or different, and R₁ and R₂, R₁ and A, R₁ and B, R₂ and A, and R₂ and B may be bonded to each other to form a ring,
A and B each independently represents a hydrocarbon structure connecting between X⁺'s, with the proviso that at least one of connections of X⁺'s with A or B indicates a structure in which X⁺'s connected are in the same conjugation and the plurality of A's, if any, may be the same or different,
l represents 0 or 1, with the proviso that when X is a sulfur atom, the number 1 of R¹'s connected to X⁺ represents 1, and when X is an iodine atom, the number 1 of R¹'s connected to X⁺ represents 0,
m represents an integer of from 0 to 10,
n represents an integer of from 1 to 6, with the proviso that when m is 0, n represents an integer of not smaller than 2.

19. The positive-working resist composition according to claim 17, wherein the component (A) is at least one selected from the compounds represented by the formula (a) and the formula (I) or (II) in combination.

20. The positive-working resist composition according to claim 17, further comprising (E) a nitrogen-containing basic compound.

21. The resist composition according to claim 13, wherein the actinic ray or radiation is selected from the group consisting of electron ray, X ray and EUV ray.
